(19) United States
(12) Patent Application Publication
(10) Pub. No.: US 2018/0138283 A1
(43) Pub. Date: May 17, 2018

(54) SEMICONDUCTOR DEVICE

(71) Applicant: Semiconductor Energy Laboratory Co., Ltd., Atsugi-shi (JP)

(72) Inventor: Hajime KIMURA, Atsugi (JP)

(21) Appl. No.: 15/854,388

(22) Filed: Dec. 26, 2017

Related U.S. Application Data
(63) Continuation of application No. 12/711,661, filed on Feb. 24, 2010.

(30) Foreign Application Priority Data
Mar. 5, 2009 (JP) 2009-051779

(51) Int. Cl. H01L 29/49; H01L 29/786; H01L 29/45; H01L 27/12

(52) U.S. Cl. CPC H01L 29/4908; H01L 29/7869; H01L 29/458; H01L 29/45; H01L 27/1288; H01L 27/124; H01L 27/1225

(57) ABSTRACT

It is an object to provide a semiconductor device with low wiring resistance, high transmittance, or a high aperture ratio. A gate electrode, a semiconductor layer, and a source electrode and a drain electrode are formed using a material having a light-transmitting property and a wiring such as a gate wiring or a source wiring is formed using a material whose resistivity is lower than that of the material having a light-transmitting property. Alternatively, the source wiring and/or the gate wiring are/is formed by a stack of a material having a light-transmitting property and a material whose resistivity is lower than that of the material having a light-transmitting property.

### BACKGROUND OF THE INVENTION

### 1. Field of the Invention

The present invention relates to a semiconductor device, a display device, and a light-emitting device, or a manufacturing method thereof. In specific, the present invention relates to a semiconductor device including a circuit having a thin film transistor in which an oxide semiconductor film is used for a channel formation region and a manufacturing method thereof.

### 2. Description of the Related Art

Today, thin film transistors (TFTs) in which silicon layers formed using amorphous silicon or the like are used for channel layers have been widely used as switching elements in display devices typified by liquid crystal display devices. Although the thin film transistor formed using amorphous silicon has low field effect mobility, it has an advantage that a glass substrate can be made large.

Further, in recent years, attention has been drawn to a technique by which a thin film transistor is manufactured using metal oxide having semiconductor characteristics and such a transistor is applied to an electronic device or an optical device. For example, it is known that some metal oxides such as tungsten oxide, tin oxide, indium oxide, and zinc oxide exhibit semiconductor characteristics. A thin film transistor in which a transparent semiconductor layer which is formed using such a metal oxide serves as a channel formation region is disclosed (Patent Documents 1).

In addition, a technique of increasing aperture ratio by formation of a channel layer of a transistor with the use of an oxide semiconductor layer having a light-transmitting property and formation of a gate electrode, a source electrode, and a drain electrode with the use of a transparent conductive film having a light-transmitting property is considered (Patent Document 2).

Since the aperture ratio is increased, light utilization efficiency is increased, whereby reduction in power consumption and in size of display devices can be achieved. On the other hand, from the standpoint of obtaining large display devices or application of the display device to mobile devices, more reduction in power consumption as well as increase in aperture ratio is demanded.

Note that as a method for providing a metal auxiliary wiring for a transparent electrode in an electric optical element, a method by which the metal auxiliary wiring is provided so as to overlap with the upper surface of the transparent electrode or the lower surface of the transparent electrode so that electrical continuity between the metal auxiliary wiring and the transparent electrode is provided has been known (e.g., Patent Document 3).

Note that a structure in which an added capacitor electrode provided for an active matrix substrate is formed using a transparent conductive film such as ITO or SnO₂ and an auxiliary wiring formed using a metal film is provided in contact with the added capacitor electrode in order to reduce the electric resistance of the added capacitor electrode has been known (e.g., Patent Document 4).

Note that it has been known that, as a gate electrode, a source electrode, or a drain electrode in a field effect transistor formed using an amorphous oxide semiconductor film, a transparent electrode formed using indium tin oxide (ITO), indium zinc oxide, ZnO, SnO₂, or the like, a metal electrode formed using Al, Ag, Cr, Ni, Mo, Au, Ti, Ta, or the like, or a metal electrode of an alloy containing any of the above elements can be used; and, by staking two or more of layers formed using the above elements, contact resistance can be reduced and interface strength can be increased (e.g., Patent Document 5).

Note that it has been known that, as a material for a source electrode, a drain electrode, a gate electrode, or an auxiliary capacitor electrode of a transistor formed using the amorphous oxide semiconductor, a metal such as indium (In), aluminum (Al), gold (Au), or silver (Ag) or an oxide material such as indium oxide (In₂O₃), tin oxide (SnO₂), zinc oxide (ZnO), cadmium oxide (CdO), indium cadmium oxide (CdIn₂O₄), cadmium tin oxide (Cd₂SnO₄), or zinc tin oxide (Zn₂SnO₄) can be used; and the same material or different materials can be used for the gate electrode, the source electrode, and the drain electrode (e.g., Patent Documents 6 and 7).

### REFERENCE

### [Patent Document 1] Japanese Published Patent Application No. 2004-103957

### [Patent Document 2] Japanese Published Patent Application No. 2007-81362

[Patent Document 3] Japanese Published Patent Application No. H2-82221
[Patent Document 4] Japanese Published Patent Application No. H2-310536

### [Patent Document 5] Japanese Published Patent Application No. 2008-243928

### [Patent Document 6] Japanese Published Patent Application No. 2007-109918

### [Patent Document 7] Japanese Published Patent Application No. 2007-115807

### SUMMARY OF THE INVENTION

According to one embodiment of the present invention, it is an object to provide a semiconductor device with low wiring resistance. Alternatively, according to one embodiment of the present invention, it is an object to provide a semiconductor device with high transmittance. Alternatively, according to one embodiment of the present invention, it is an object to provide a semiconductor device with a high aperture ratio. Alternatively, according to one embodiment of the present invention, it is an object to provide a semiconductor device with low power consumption. Alternatively, according to one embodiment of the present invention, it is an object to provide a semiconductor device which supplies an accurate voltage. Alternatively, according to one embodiment of the present invention, it is an object to provide a semiconductor device in which voltage drop is suppressed. Alternatively, according to one embodiment of the present invention, it is an object to provide a semiconductor device with improved display quality. Alternatively, according to one embodiment of the present invention, it is an object to provide a semiconductor device with suppressed contact resistance. Alternatively, according to one embodiment of the present invention, it is an object to provide a semiconductor device in which flickers are suppressed. Alternatively, according to one embodiment of the present invention, it is an object to provide a semiconductor device in which the amount of off-current is small. Note that the descriptions of these objects do not disturb the existence of other objects. Note that one embodiment of the present invention does not necessarily solve all the objects listed above.

In order to solve the object, according to one embodiment of the present invention, a gate electrode, a semiconductor layer, a source electrode or drain electrode are formed using a material having a light-transmitting property; and a wiring such as a gate wiring or a source wiring is formed using a material having lower resistivity than the material having a light-transmitting property.

According to one embodiment of the present invention, a semiconductor device which includes a first electrode formed using a first conductive layer having a light-transmitting property; a first wiring electrically connected to the first electrode and formed using a layered structure of the first conductive layer and a second conductive layer whose electrical resistance is lower than that of the first conductive layer; an insulating layer formed over the first electrode and the first wiring; a second electrode formed over the insulating layer and formed using a third conductive layer having a light-transmitting property; a second wiring electrically connected to the second electrode and formed using a layered structure of the third conductive layer and a fourth conductive layer whose electrical resistance is lower than that of the third conductive layer; a third electrode formed using a fifth conductive layer having a light-transmitting property; and a semiconductor layer formed over the insulating layer so as to overlap with the first electrode and over the second electrode and the third electrode is provided.

According to one embodiment of the present invention, a semiconductor device which includes a first electrode formed using a first conductive layer having a light-transmitting property; a first wiring electrically connected to the first electrode and formed using a layered structure of the first conductive layer and a second conductive layer whose resistance is lower than that of the first conductive layer; a second wiring formed using a third conductive layer having a light-transmitting property; an insulating layer formed over the first electrode, the first wiring, and the second wiring; a second electrode formed over the insulating layer and formed using a fourth conductive layer having a light-transmitting property; a third wiring electrically connected to the second electrode and formed using a layered structure of the fourth conductive layer and a fifth conductive layer whose resistance is lower than that of the fourth conductive layer; a third electrode formed using a sixth conductive layer having a light-transmitting property; a seventh conductive layer having a light-transmitting property provided over the second wiring with the insulating layer interposed therebetween; and a semiconductor layer formed over the insulating layer so as to overlap with the first electrode and over the second electrode and the third electrode is provided.

Note that a variety of switches can be used as a switch. For example, an electrical switch, a mechanical switch, or the like can be used. That is, any element can be used as long as it can control a current flow, without a limitation to a certain element. For example, a transistor (e.g., a bipolar transistor or a MOS transistor), a diode (e.g., a PN diode, a PIN diode, a Schottky diode, an MIM (metal insulator metal) diode, an MIS (metal insulator semiconductor) diode, or a diode-connected transistor), or the like can be used as a switch. Alternatively, a logic circuit combining such elements can be used as a switch.

An example of a mechanical switch is a switch formed using MEMS (micro electro mechanical system) technology, such as a digital micromirror device (DMD). Such a switch includes an electrode which can be moved mechanically, and operates by controlling conduction and non-conduction based on movement of the electrode.

In the case of using a transistor as a switch, there is no particular limitation on polarity (a conductivity type) of the transistor because it operates just as a switch. However, a transistor of polarity with smaller off-current is preferably used when off-current is to be suppressed. A transistor provided with an LDD region, a transistor with a multi-gate structure, and the like are given as examples of a transistor with smaller off-current. Further, an n-channel transistor is preferably used when the transistor operates with a potential of a source terminal closer to a potential of a low potential side power supply (e.g., Vss, GND, or 0 V). On the other hand, a p-channel transistor is preferably used when the transistor operates with a potential of a source terminal close to a potential of a high potential side power supply (e.g., Vdd). This is because when the n-channel transistor operates with the potential of the source terminal close to a low potential side power supply or the p-channel transistor operates with the potential of the source terminal close to a high potential side power supply, an absolute value of a gate-source voltage can be increased; thus, the transistor can more precisely operate as a switch. Moreover, this is because reduction in output voltage does not often occur because the transistor does not often perform a source follower operation.

Note that a CMOS switch may be used as a switch by using both N-channel and P-channel transistors. By using a CMOS switch, the switch can easily operate as a switch because current can flow when the P-channel transistor or the N-channel transistor is turned on. For example, even when a voltage of an input signal to a switch is high or low, an appropriate voltage can be outputted. Further, since a voltage amplitude value of a signal for turning on or off the switch can be made small, power consumption can be reduced.

Note that when a transistor is used as a switch, the switch includes an input terminal (one of a source terminal and a drain terminal), an output terminal (the other of the source terminal and the drain terminal), and a terminal for controlling conduction (a gate terminal). On the other hand, when a diode is used as a switch, the switch does not have a terminal for controlling electrical conduction in some cases. Therefore, when a diode is used as a switch, the number of wirings for controlling terminals can be further reduced compared to the case of using a transistor as a switch.

Note that when it is explicitly described that “A and B are connected,” the case where A and B are electrically connected, the case where A and B are functionally connected, and the case where A and B are directly connected are included therein. Here, each of A and B corresponds to an object (e.g., a device, an element, a circuit, a wiring, an electrode, a terminal, a conductive film, or a layer). Accordingly, another connection relation is included without being limited to a predetermined connection relation, for example, the connection relation shown in the drawings and the texts.

For example, in the case where A and B are electrically connected, one or more elements which enable electric connection between A and B (e.g., a switch, a transistor, a capacitor, an inductor, a resistor, and/or a diode) may be connected between A and B. Alternatively, in the case where A and B are functionally connected, one or more circuits which enable functional connection between A and B (e.g., a logic circuit such as an inverter, a NAND circuit, or a NOR circuit; a signal converter circuit such as a DA converter circuit, an AD converter circuit, or a gamma correction circuit; a potential level converter circuit such as a power supply circuit (e.g., a step-up dc-dc converter or a step-down dc-dc converter) or a level shifter circuit for changing a potential level of a signal; a voltage source; a current source; a switching circuit; an amplifier circuit such as a circuit which can increase signal amplitude, the amount of current, or the like, an operational amplifier, a differential amplifier circuit, a source follower circuit, or a buffer circuit; a signal generating circuit; a memory circuit; and/or a control circuit) may be connected between A and B. For example, in the case where a signal output from A is transmitted to B even if another circuit is provided between A and B, A and B are connected functionally.

Note that when it is explicitly described that “A and B are electrically connected”, the case where A and B are electrically connected (i.e., the case where A and B are connected by interposing another element or another circuit therebetween), the case where A and B are functionally connected (i.e., the case where A and B are functionally connected by interposing another circuit therebetween), and the case where A and B are directly connected (i.e., the case where A and B are connected without interposing another element or another circuit therebetween) are included therein. That is, when it is explicitly described that “A and B are electrically connected”, the description is the same as the case where it is explicitly only described that “A and B are connected”.

Note that a display element, a display device which is a device having a display element, a light-emitting element, and a light-emitting device which is a device having a light-emitting element can use various types and can include various elements. For example, a display medium, whose contrast, luminance, reflectivity, transmittance, or the like changes by an electromagnetic action, such as an EL (electro-luminescence) element (e.g., an EL element including organic and inorganic materials, an organic EL element, or an inorganic EL element), an LED (a white LED, a red LED, a green LED, a blue LED, or the like), a transistor (a transistor which emits light depending on current), an electron emitter, a liquid crystal element, electronic ink, an electrophoresis element, a grating light valve (GLV), a plasma display panel (PDP), a digital micromirror device (DMD), a piezoelectric ceramic display, or a carbon nanotube can be included as a display element, a display device, a light-emitting element, or a light-emitting device. Note that display devices using an EL element include an EL display; display devices using an electron emitter include a field emission display (FED), an SED-type flat panel display (SED: Surface-conduction Electron-emitter Display), and the like; display devices using a liquid crystal element include a liquid crystal display (e.g., a transmissive liquid crystal display, a semi-transmissive liquid crystal display, a reflective liquid crystal display, a direct-view liquid crystal display, or a projection liquid crystal display); and display devices using electronic ink include electronic paper.

An EL element is an element including an anode, a cathode, and an EL layer interposed between the anode and the cathode. The EL layer can be, for example, a layer utilizing emission from a singlet exciton (fluorescence) or a triplet exciton (phosphorescence), a layer utilizing emission from a singlet exciton (fluorescence) and emission from a triplet exciton (phosphorescence), a layer including an organic material or an inorganic material, a layer including an organic material and an inorganic material, a layer including a high molecular material or a low molecular material, and a layer including a low molecular material and a high molecular material. Note that the EL element can include a variety of layers as the EL layer without limitation to those described above.

An electron emitter is an element in which electrons are extracted by high electric field concentration on a cathode. For example, the electron emitter can be any one of a Spindt-type, a carbon nanotube (CNT) type, a metal-insulator-metal (MIM) type including a stack of a metal, an insulator, and a metal, a metal-insulator-semiconductor (MIS) type including a stack of a metal, an insulator, and a semiconductor, a MOS type, a silicon type, a thin film diode type, a diamond type, a surface conductive emitter SCD type, a thin film type in which a metal, an insulator, a semiconductor, and a metal are stacked, a HEED type, an EL type, a porous silicon type, a surface-conduction electron-emitter (SCE) type, and the like. Note that various elements can be used as an electron emitter without limitation to those described above.

Note that a liquid crystal element is an element which controls transmission or non-transmission of light by an optical modulation action of liquid crystals and includes a pair of electrodes and liquid crystals. The optical modulation action of liquid crystals is controlled by an electric filed applied to the liquid crystal (including a lateral electric field, a vertical electric field and a diagonal electric field). Note that the following can be used for a liquid crystal element: a nematic liquid crystal, a cholesteric liquid crystal, a smectic liquid crystal, a discotic liquid crystal, a thermotropic liquid crystal, a lyotropic liquid crystal, a low-molecular liquid crystal, a high-molecular liquid crystal, a polymer dispersed liquid crystal (PDLC), a ferroelectric liquid crystal, an anti-ferroelectric liquid crystal, a main-chain liquid crystal, a side-chain high-molecular liquid crystal, a plasma addressed liquid crystal (PALC), a banana-shaped liquid crystal, and the like. In addition, the following can be used as a diving method of a liquid crystal: a TN (twisted nematic) mode, an STN (super twisted nematic) mode, an IPS (in-plane-switching) mode, an FFS (fringe field switching) mode, an MVA (multi-domain vertical alignment) mode, a PVA (patterned vertical alignment) mode, an ASV (advanced super view) mode, an ASM (axially symmetric aligned microcell) mode, an OCB (optically compensated birefringence) mode, an ECB (electrically controlled birefringence) mode, an FLC (ferroelectric liquid crystal) mode, an AFLC (anti-ferroelectric liquid crystal) mode, a PDLC (polymer dispersed liquid crystal) mode, a guest-host mode, a blue phase mode, and the like. Note that this embodiment is not limited to this example, and various kinds of liquid crystal elements can be used.

Electronic paper corresponds to devices that display images by molecules which utilize optical anisotropy, dye molecular orientation, or the like; by particles which utilize electrophoresis, particle movement, particle rotation, phase change, or the like; by moving one end of a film; by using coloring properties or phase change of molecules; by using optical absorption by molecules; and by using self-light emission by bonding electrons and holes. For example, the following can be used for the electronic paper: microcapsule electrophoresis, horizontal electrophoresis, vertical electrophoresis, a spherical twisting ball, a magnetic twisting ball, a columnar twisting ball, a charged toner, electro liquid powder, magnetic electrophoresis, a magnetic thermosensitive type, an electrowetting type, a light-scattering (transparent-opaque change) type, cholesteric liquid crystal and a photoconductive layer, a cholesteric liquid crystal device, bistable nematic liquid crystal, ferroelectric liquid crystal, a liquid crystal dispersed type with a dichroic dye, a movable film, coloring and decoloring properties of a leuco dye, a photochromic material, an electrochromic material, an electrodeposition material, flexible organic EL, and the like. Note that various types of electronic papers can be used without limitation to those described above. By using microcapsule electrophoresis, problems of electrophoresis, that is, aggregation or precipitation of phoresis particles can be solved. Electro liquid powder has advantages such as high-speed response, high reflectivity, wide viewing angle, low power consumption, and memory properties.

Note that a plasma display panel has a structure in which a substrate having a surface provided with an electrode and a substrate having a surface provided with an electrode and a minute groove in which a phosphor layer is formed face each other at a narrow interval and a rare gas is sealed therein. Alternatively, a plasma display can have a structure in which a plasma tube is interposed between film-shaped electrodes. The plasma tube is formed by sealing a discharge gas, RGB fluorescent materials, and the like inside a glass tube. Display can be performed by application of a voltage between the electrodes to generate an ultraviolet ray so that the fluorescent materials emit light. Note that the plasma display panel may be a DC type PDP or an AC type PDP. Note that as a driving method of the plasma display panel, ASW (Address While Sustain) driving, ADS (Address Display Separated) driving in which a subframe is divided into a reset period, an address period, and a sustain period, CLEAR (High-Contrast, Low Energy Address and Reduction of False Contour Sequence) driving, ALIS (Alternate Lighting of Surfaces) method, TERES (Technology of Reciprocal Sustainer) driving, and the like can be used. Note that various types of plasma displays can be used without limitation to those described above.

Electroluminescence, a cold cathode fluorescent lamp, a hot cathode fluorescent lamp, an LED, a laser light source, a mercury lamp, or the like can be used for a light source needed for a display device, such as a liquid crystal display device (a transmissive liquid crystal display, a semi-transmissive liquid crystal display, a reflective liquid crystal display, a direct-view liquid crystal display, and a projection type liquid crystal display), a display device using a grating light valve (GLV), and a display device using a digital micromirror device (DMD). Note that a variety of light sources can be used without limitation to those described above.

Note that as a transistor, various types of transistors can be employed without being limited to a certain type. Therefore, there is no limitation on the kind of transistors to be used. For example, a thin film transistor (TFT) including a non-single-crystal semiconductor film typified by amorphous silicon, polycrystalline silicon, microcrystalline (also referred to as microcrystal, nanocrystal, semi-amorphous) silicon, or the like can be used. In the case of using the TFT, there are various advantages. For example, since the TFT can be formed at a temperature lower than that of the case of using single crystalline silicon, manufacturing cost can be reduced and a manufacturing device can be made larger. Since the manufacturing device can be made larger, the TFT can be formed using a large substrate. Therefore, many display devices can be formed at the same time at low cost. In addition, a substrate having low heat resistance can be used because of low manufacturing temperature. Therefore, the transistor can be formed using a light-transmitting substrate. Accordingly, transmission of light in a display element can be controlled by using the transistor formed using the light-transmitting substrate. Alternatively, part of a film which forms the transistor can transmit light because the film thickness of the transistor is small. Therefore, the aperture ratio can be improved.

Note that by using a catalyst (e.g., nickel) in the case of forming polycrystalline silicon, crystallinity can be further improved, and a transistor having excellent electric characteristics can be formed. Accordingly, a gate driver circuit (e.g., a scan line driver circuit), a source driver circuit (e.g., a signal line driver circuit), and a signal processing circuit (e.g., a signal generation circuit, a gamma correction circuit, or a DA converter circuit) can be formed over one substrate.

Note that by using a catalyst (e.g., nickel) in the case of forming microcrystalline silicon, crystallinity can be further improved and a transistor having excellent electric characteristics can be formed. At this time, crystallinity can be improved just by performing heat treatment without performing laser light irradiation. Thus, part of a source driver circuit (e.g., an analog switch) and a gate driver circuit (e.g., a scan line driver circuit) can be formed over one substrate. Further, when laser irradiation for crystallization is not performed, unevenness of silicon crystallinity can be suppressed. Accordingly, an image with improved image quality can be displayed.

Note also that polycrystalline silicon and microcrystalline silicon can be formed without using a catalyst (e.g., nickel).

Note that it is preferable that the crystallinity of silicon be improved to polycrystalline, microcrystalline, or the like in the whole panel; however, this embodiment is not limited to this example. The crystallinity of silicon may be improved only in part of the panel. Selective increase in crystallinity can be achieved by selective laser irradiation or the like. For example, only a peripheral driver circuit region excluding pixels may be irradiated with laser light. Alternatively, only a region of a gate driver circuit, a source driver circuit, or the like may be irradiated with laser light. Further alternatively, only part of a source driver circuit (e.g., an analog switch) may be irradiated with laser light. As a result, the crystallinity of silicon only in a region in which a circuit needs to operate at high speed can be improved. Since pixel region does not especially need to operate at high speed, the pixel circuit can operate without problems even if the crystallinity is not improved. A region crystallinity of which is improved is small, whereby manufacturing steps can be reduced, the throughput can be increased, and manufacturing costs can be reduced. Since the number of manufacturing devices needed is small, manufacturing costs can be reduced.

In addition, transistors can be formed by using a semiconductor substrate, an SOI substrate, or the like. Therefore, a transistor with few variations in characteristics, sizes, shapes, or the like, with high current supply capability, and with a small size can be formed. When such a transistor is used, power consumption of a circuit can be reduced or a circuit can be highly integrated.

In addition, a transistor including a compound semiconductor or an oxide semiconductor, such as ZnO, a-InGaZnO, SiGe, GaAs, IZO, ITO, SnO, TiO, or AlZnSnO (AZTO) and a thin film transistor or the like obtained by thinning such a compound semiconductor or oxide semiconductor can be used. Therefore, manufacturing temperature can be lowered and for example, such a transistor can be formed at room temperature. Accordingly, the transistor can be formed directly on a substrate having low heat resistance such as a plastic substrate or a film substrate. Note that such a compound semiconductor or an oxide semiconductor can be used for not only a channel portion of the transistor but also other applications. For example, such a compound semiconductor or an oxide semiconductor can be used as a resistor, a pixel electrode, or a light-transmitting electrode. Further, since such an element can be formed at the same time as the transistor, the costs can be reduced.

A transistor or the like formed by using an inkjet method or a printing method can also be used. Accordingly, a transistor can be formed at room temperature, can be formed at a low vacuum, or can be formed using a large substrate. Since the transistor can be formed without using a mask (reticle), the layout of the transistor can be easily changed. Further, since it is not necessary to use a resist, material cost is reduced and the number of steps can be reduced. Furthermore, since a film is formed only where needed, a material is not wasted compared with a manufacturing method in which etching is performed after the film is formed over the entire surface, so that cost can be reduced.

Further, a transistor or the like including an organic semiconductor or a carbon nanotube can be used. Accordingly, such transistors can be formed over a flexible substrate. A semiconductor device using such a substrate can resist a shock.

In addition, various types of transistors can be used. For example, a MOS transistor, a junction transistor, a bipolar transistor, or the like can be employed. When a MOS transistor is used, the size of the transistor can be reduced. Thus, a plurality of transistors can be mounted. When a bipolar transistor is used, large current can flow. Thus, a circuit can be operated at high speed.

Note that a MOS transistor, a bipolar transistor, and the like may be formed over one substrate. Thus, low power consumption, reduction in size, and high-speed operation can be achieved.

Furthermore, various transistors other than the above-described types of transistors can be used.

Note that a transistor can be formed using various types of substrates. The type of a substrate is not limited to a certain type. As the substrate, a single crystal substrate (e.g., a silicon substrate), an SOI substrate, a glass substrate, a quartz substrate, a plastic substrate, a metal substrate, a stainless steel substrate, a substrate including a stainless steel foil, a tungsten substrate, a substrate including a tungsten foil, or a flexible substrate can be used, for example. As a glass substrate, a barium borosilicate glass substrate, an aluminoborosilicate glass substrate, or the like can be used, for example. For a flexible substrate, a flexible synthetic resin such as plastics typified by polyethylene terephthalate (PET), polyethylene naphthalate (PEN), and polyether sulfone (PES), or acrylic can be used, for example. Alternatively, an attachment film (formed using polypropylene, polyester, vinyl, polyvinyl fluoride, polyvinyl chloride, or the like), paper including a fibrous material, a base material film (polyester, polyamide, polyimide, an inorganic vapor deposition film, paper, or the like), or the like can be used. In addition, the transistor may be formed using one substrate, and then transferred to and provided over another substrate. As a substrate to which the transistor is transferred, a single crystalline substrate, an SOI substrate, a glass substrate, a quartz substrate, a plastic substrate, a paper substrate, a cellophane substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupra, rayon, or regenerated polyester), or the like), a leather substrate, a rubber substrate, a stainless steel substrate, a substrate including a stainless steel foil, or the like can be used. Alternatively, a skin (e.g., epidermis or corium) or hypodermal tissue of an animal such as a human may be used as the substrate. Further, the transistor may be formed using a substrate, and the substrate may be thinned by polishing. As the substrate to be polished, a single crystalline substrate, an SOI substrate, a glass substrate, a quartz substrate, a plastic substrate, a stainless steel substrate, a substrate made of a stainless steel foil, or the like can be used. By using such a substrate, transistors with excellent properties or transistors with low power consumption can be formed, a device with high durability or high heat resistance can be formed, or reduction in weight or thinning can be achieved.

Note that a structure of a transistor can be various forms without being limited to a certain structure. For example, a multi-gate structure having two or more gate electrodes may be used. When the multi-gate structure is used, a structure where a plurality of transistors are connected in series is provided because a structure where channel regions are connected in series is provided. With the multi-gate structure, the off-current can be reduced and the withstand voltage of the transistor can be increased (the reliability can be improved). Further, by employing the multi-gate structure, a drain-source current does not change much even if a drain-source voltage changes when the transistor operates in a saturation region; thus, the slope of voltage-current characteristics can be flat. By utilizing the flat slope of the voltage-current characteristics, an ideal current source circuit or an active load having an extremely large resistance value can be realized. Accordingly, a differential circuit or a current mirror circuit which has excellent properties can be provided.

As another example, a structure where gate electrodes are formed above and below a channel may be employed. By employing the structure where gate electrodes are formed above and below the channel, a channel region is enlarged; thus, a current value can be increased. Alternatively, by employing the structure where gate electrodes are formed above and below the channel, a depletion layer is easily formed; thus, an S value can be improved. When the gate electrodes are formed above and below the channel, a structure where a plurality of transistors are connected in parallel is provided.

A structure where a gate electrode is formed above a channel region, a structure where a gate electrode is formed below a channel region, a staggered structure, an inverted staggered structure, a structure where a channel region is divided into a plurality of regions, or a structure where channel regions are connected in parallel or in series can be used. Further alternatively, a source electrode or a drain electrode may overlap with a channel region (or part of it). By using the structure where the source electrode or the drain electrode may overlap with the channel region (or part of it), unstable operation due to electric charge accumulated in part of the channel region can be prevented. Further, an LDD region may be provided. By providing the LDD region, the off-current can be reduced or the withstand voltage of the transistor can be increased (the reliability can be improved). Alternatively, by providing the LDD region, a drain-source current does not change much even if a drain-source voltage changes when a transistor operates in the saturation region, so that a slope of voltage-current characteristics can be flat.

Note that various types of transistors can be used as a transistor and the transistor can be formed using various types of substrates. Accordingly, all the circuits that are necessary to realize a predetermined function can be formed using the same substrate. For example, all the circuits that are necessary to realize the predetermined function can be formed using a glass substrate, a plastic substrate, a single crystal substrate, an SOI substrate, or any other substrate. When all the circuits that are necessary to realize the predetermined function are formed using the same substrate, cost can be reduced by reduction in the number of component parts or reliability can be improved by reduction in the number of connection to circuit components. Alternatively, part of the circuits which are necessary to realize the predetermined function can be formed using one substrate and another part of the circuits which are necessary to realize the predetermined function can be formed using another substrate. That is, not all the circuits that are necessary to realize the predetermined function are required to be formed using the same substrate. For example, part of the circuits which are necessary to realize the predetermined function may be formed by transistors using a glass substrate and another part of the circuits which are necessary to realize the predetermined function may be formed using a single crystal substrate, so that an IC chip formed by a transistor over the single crystal substrate can be connected to the glass substrate by COG (chip on glass) and the IC chip may be provided over the glass substrate. Alternatively, the IC chip can be connected to the glass substrate by TAB (tape automated bonding) or a printed wiring board. When part of the circuits are formed using the same substrate in this manner, cost can be reduced by reduction in the number of component parts or reliability can be improved by reduction in the number of connection to circuit components. Further alternatively, when circuits with high driving voltage and high driving frequency, which consume large power, are formed, for example, over a single crystal semiconductor substrate instead of forming such circuits using the same substrate and an IC chip formed by the circuit is used, increase in power consumption can be prevented.

Note that one pixel corresponds to one component that can control luminance. Therefore, for example, one pixel shows one color element by which brightness is expressed. Accordingly, in the case of a color display device formed of color elements of R (red), G (green), and B (blue), the smallest unit of an image includes three pixels of an R pixel, a G pixel, and a B pixel. Note that the color elements are not limited to three colors, and color elements of more than three colors may be used or a color other than RGB may be used. For example, RGBW (W means white) display is possible by addition of white. Alternatively, RGB plus one or more colors of yellow, cyan, magenta, emerald green, vermilion, and the like can be used. Alternatively, a color which is similar to at least one of R, G, and B may be added to RGB, for example. For example, R, G, B1, and B2 may be used. Although B1 and B2 are both blue, they are different in wavelength. Similarly, R1, R2, G, and B may be used. By using such color elements, display which is closer to the real object can be performed. By using such color elements, power consumption can be reduced. Further, when the brightness of one color element is controlled by using a plurality of regions, one of the regions can correspond to one pixel. Therefore, for example, in the case where area gray scale display is performed or sub-pixels are included, a plurality of regions are provided for one color element to control the brightness, and the plurality of regions expresses gray scale as a whole; however, one of the regions for controlling the brightness can correspond to one pixel. Accordingly, in such a case, one color element is composed of a plurality of pixels. Alternatively, even if a plurality of regions for controlling the brightness is included in one color element, such regions of one color element can collectively correspond to one pixel. Accordingly, in such a case, one color element is composed of one pixel. Alternatively, in the case where the brightness of one color element is controlled by using a plurality of regions, the size of a region which contributes to display differs depending on a pixel in some cases. Alternatively, in the plurality of regions for controlling the brightness which are provided for one color element, the viewing angle may be expanded by supplying signals slightly different from each other to respective pixels. In other words, the potentials of pixel electrodes included in the plurality of regions for one color element can be different from each other. Accordingly, a voltage applied to liquid crystal molecules are varied depending on the pixel electrodes. Therefore, the viewing angle can be widened.

Note that when it is explicitly described as one pixel (for three colors), it corresponds to the case where three pixels of R, G, and B are considered as one pixel. Meanwhile, when it is explicitly described as one pixel (for one color), it corresponds to the case where a plurality of regions provided in each color element are collectively considered as one pixel.

Note that pixels are provided (arranged) in a matrix in some cases. Here, description that pixels are provided (arranged) in matrix includes the case where the pixels are arranged in a straight line or a jagged line in a longitudinal direction or a lateral direction. For example, in the case of performing full color display with three color elements (e.g., RGB), the following cases are included therein: the case where the pixels are arranged in stripes; and the case where dots of the three color elements are arranged in a delta pattern. In addition, the case is also included therein in which dots of the three color elements are provided in Bayer arrangement. Further, the sizes of display regions may be different between respective dots of color elements. Thus, power consumption can be reduced and the life of a display element can be prolonged.

Note that an active matrix method in which an active element is included in a pixel or a passive matrix method in which an active element is not included in a pixel can be used.

In the active matrix method, as an active element (a non-linear element), a variety of active elements (non-linear elements) such as a metal-insulator-metal (MIM) and a thin film diode (TFD) can be used in addition to a transistor. Since such an element has a small number of manufacturing steps, manufacturing costs can be reduced or the yield can be improved. Further, since the size of the element is small, an aperture ratio can be increased, and reduction in power consumption and high luminance can be achieved.

As a method other than the active matrix method, the passive matrix method in which an active element (a non-linear element) is not used can also be used. Since an active element (a non-linear element) is not used, the manufacturing steps are fewer, so that manufacturing costs can be reduced or the yield can be improved. Further, since an active element (a non-linear element) is not used, the aperture ratio can be improved, so that power consumption can be reduced and high luminance can be achieved.

Note that a transistor is an element having at least three terminals of a gate, a drain, and a source. The transistor has a channel region between a drain region and a source region, and current can flow through the drain region, the channel region, and the source region. Here, since the source and the drain of the transistor may change depending on the structure, the operating condition, and the like of the transistor, it is difficult to define which is a source or a drain. Therefore, a region functioning as source and drain is not called the source or the drain in some cases. In such a case, for example, one of the source and the drain may be referred to as a first terminal and the other thereof may be referred to as a second terminal. Alternatively, one of the source and the drain may be referred to as a first electrode and the other thereof may be referred to as a second electrode. Further alternatively, one of the source and the drain may be referred to as a first region and the other thereof may be called a second region.

Note that a transistor may be an element including at least three terminals of a base, an emitter and a collector. In this case also, the emitter and the collector may be similarly denoted as a first terminal and a second terminal.

A gate corresponds to the whole or part of a gate electrode and a gate wiring (also called a gate line, a gate signal line, a scan line, a scan signal line, or the like). A gate electrode corresponds to part of a conductive film that overlaps with a semiconductor which forms a channel region with a gate insulating film interposed therebetween. Note that in some cases, part of the gate electrode overlaps with an LDD (lightly doped drain) region or a source region (or a drain region) with the gate insulating film interposed therebetween. A gate wiring corresponds to a wiring for connecting gate electrodes of transistors, a wiring for connecting gate electrodes in pixels, or a wiring for connecting a gate electrode to another wiring.

However, there is a portion (a region, a conductive film, a wiring, or the like) which functions as both a gate electrode and a gate wiring. Such a portion (a region, a conductive film, a wiring, or the like) may be called either a gate electrode or a gate wiring. That is, there is a region where a gate electrode and a gate wiring cannot be clearly distinguished from each other. For example, in the case where a channel region overlaps with part of an extended gate wiring, the overlapped portion (region, conductive film, wiring, or the like) functions as both a gate wiring and a gate electrode. Accordingly, such a portion (a region, a conductive film, a wiring, or the like) may be called either a gate electrode or a gate wiring.

Note that a portion (a region, a conductive film, a wiring, or the like) which is formed of the same material as a gate electrode and forms the same island as the gate electrode to be connected to the gate electrode may also be called a gate electrode. Similarly, a portion (a region, a conductive film, a wiring, or the like) which is formed of the same material as a gate wiring and forms the same island as the gate wiring to be connected to the gate wiring may also be called a gate wiring. In a strict sense, such a portion (a region, a conductive film, a wiring, or the like) does not overlap with a channel region or does not have a function of connecting the gate electrode to another gate electrode in some cases. However, there is a portion (a region, a conductive film, a wiring, or the like) which is formed of the same material as a gate electrode or a gate wiring and forms the same island as the gate electrode or the gate wiring to be connected to the gate electrode or the gate wiring in relation to a specification in manufacturing and the like. Thus, such a portion (a region, a conductive film, a wiring, or the like) may also be called either a gate electrode or a gate wiring.

In a multi-gate transistor, for example, a gate electrode is often connected to another gate electrode by using a conductive film which is formed of the same material as the gate electrodes. Since such a portion (a region, a conductive film, a wiring, or the like) is a portion (a region, a conductive film, a wiring, or the like) for connecting the gate electrode to another gate electrode, it may be called a gate wiring. Alternatively, it may be called a gate electrode because a multi-gate transistor can be considered as one transistor. That is, a portion (a region, a conductive film, a wiring, or the like) which is formed of the same material as a gate electrode or a gate wiring and forms the same island as the gate electrode or the gate wiring to be connected to the gate electrode or the gate wiring may be called either a gate electrode or a gate wiring. In addition, for example, part of a conductive film which connects a gate electrode to a gate wiring and is formed of a material different from that of the gate electrode and the gate wiring may also be called either a gate electrode or a gate wiring.

Note that a gate terminal corresponds to part of a portion (a region, a conductive film, a wiring, or the like) of a gate electrode or a portion (a region, a conductive film, a wiring, or the like) which is electrically connected to the gate electrode.

When a wiring is called a gate wiring, a gate line, a gate signal line, a scan line, a scan signal line, or the like, there is the case where a gate of a transistor is not connected to the wiring. In this case, the gate wiring, the gate line, the gate signal line, the scan line, or the scan signal line corresponds to a wiring formed in the same layer as the gate of the transistor, a wiring formed of the same material as the gate of the transistor, or a wiring formed at the same time as the gate of the transistor in some cases. As examples, a wiring for holding capacitance, a power supply line, a reference potential supply line, and the like can be given.

A source corresponds to the whole or part of a source region, a source electrode, and a source wiring (also called a source line, a source signal line, a data line, a data signal line, or the like). A source region corresponds to a semiconductor region containing a large amount of p-type impurities (e.g., boron or gallium) or n-type impurities (e.g., phosphorus or arsenic). Therefore, a region containing a small amount of p-type impurities or n-type impurities, a so-called LDD (lightly doped drain) region is not included in the source region. A source electrode corresponds to a conductive layer that is formed of a material different from that of a source region and electrically connected to the source region. However, there is the case where a source electrode and a source region are collectively called a source electrode. A source wiring is a wiring for connecting source electrodes of transistors, a wiring for connecting source electrodes in pixels, or a wiring for connecting a source electrode to another wiring.

However, there is a portion (a region, a conductive film, a wiring, or the like) functioning as both a source electrode and a source wiring. Such a portion (a region, a conductive film, a wiring, or the like) may be called either a source electrode or a source wiring. That is, there is a region where a source electrode and a source wiring cannot be clearly distinguished from each other. For example, in the case where a source region overlaps with part of an extended source wiring, the overlapped portion (region, conductive film, wiring, or the like) functions as both a source wiring and a source electrode. Accordingly, such a portion (a region, a conductive film, a wiring, or the like) may be called either a source electrode or a source wiring.

Note that a portion (a region, a conductive film, a wiring, or the like) which is formed of the same material as a source electrode and forms the same island as the source electrode to be connected to the source electrode, or a portion (a region, a conductive film, a wiring, or the like) which connects a source electrode to another source electrode may also be called a source electrode. Further, a portion which overlaps with a source region may be called a source electrode. Similarly, a region which is formed of the same material as a source wiring and forms the same island as the source wiring to be connected to the source wiring may also be called a source wiring. In a strict sense, such a portion (a region, a conductive film, a wiring, or the like) does not have a function of connecting the source electrode to another source electrode in some cases. However, there is a portion (a region, a conductive film, a wiring, or the like) which is formed of the same material as a source electrode or a source wiring and forms the same island as the source electrode or the source wiring to be connected to the source electrode or the source wiring in relation to a specification in manufacturing and the like. Thus, such a portion (a region, a conductive film, a wiring, or the like) may also be called either a source electrode or a source wiring.

In addition, for example, part of a conductive film which connects a source electrode to a source wiring and is formed of a material different from that of the source electrode or the source wiring may be called either a source electrode or a source wiring.

Note that a source terminal corresponds to part of a source region, a source electrode, or a portion (a region, a conductive film, a wiring, or the like) which is electrically connected to the source electrode.

When a wiring is called a source wiring, a source line, a source signal line, a data line, a data signal line, or the like, there is the case where a source (a drain) of a transistor is not connected to the wiring. In this case, the source wiring, the source line, the source signal line, the data line, or the data signal line corresponds to a wiring formed in the same layer as the source (the drain) of the transistor, a wiring formed of the same material of the source (the drain) of the transistor, or a wiring formed at the same time as the source (the drain) of the transistor in some cases. As examples, a wiring for holding capacitance, a power supply line, a reference potential supply line, and the like can be given.

Note that the case of a drain is similar to that of the source.

Note that a semiconductor device corresponds to a device having a circuit including a semiconductor element (e.g., a transistor, a diode, or a thyristor). The semiconductor device may also include all devices that can function by utilizing semiconductor characteristics. Alternatively, the semiconductor device corresponds to a device having a semiconductor material.

Note that a display device corresponds to a device having a display element. Note that the display device may include a plurality of pixels each having a display element. Note that the display device may also include a peripheral driver circuit for driving the plurality of pixels. Note that the peripheral driver circuit for driving the plurality of pixels may be formed over the same substrate as the plurality of pixels. Note that the display device may also include a peripheral driver circuit provided over a substrate by wire bonding or bump bonding, namely, an IC chip connected by chip on glass (COG) or an IC chip connected by TAB or the like. Further, the display device may also include a flexible printed circuit (FPC) to which an IC chip, a resistor, a capacitor, an inductor, a transistor, or the like is attached. Note also that the display device includes a printed wiring board (PWB) which is connected through a flexible printed circuit (FPC) and to which an IC chip, a resistor element, a capacitor, an inductor, a transistor, or the like is attached. The display device may also include an optical sheet such as a polarizing plate or a retardation plate. Note that the display device may also include a lighting device, a housing, an audio input and output device, a light sensor, or the like.

Note that a lighting device may include a backlight unit, a light guide plate, a prism sheet, a diffusion sheet, a reflective sheet, a light source (e.g., an LED or a cold cathode fluorescent lamp), a cooling device (e.g., a water cooling device or an air cooling device), or the like.

In addition, a light-emitting device corresponds to a device having a light-emitting element or the like. When a light-emitting element is used as a display element, a light-emitting device is a typical example of a display device.

Note that a reflective device corresponds to a device having a light-reflecting element, a light-diffraction element, a light-reflecting electrode, or the like.

A liquid crystal display device corresponds to a display device including a liquid crystal element. Liquid crystal display devices include a direct-view liquid crystal display, a projection liquid crystal display, a transmissive liquid crystal display, a reflective liquid crystal display, a semi-transmissive liquid crystal display, and the like.

Note also that a driving device corresponds to a device having a semiconductor element, an electric circuit, an electronic circuit and/or the like. For example, a transistor which controls input of a signal from a source signal line to a pixel (also referred to as a selection transistor, a switching transistor, or the like), a transistor which supplies voltage or current to a pixel electrode, a transistor which supplies voltage or current to a light-emitting element, and the like are examples of the driving device. A circuit which supplies a signal to a gate signal line (also referred to as a gate driver, a gate line driver circuit, or the like), a circuit which supplies a signal to a source signal line (also referred to as a source driver, a source line driver circuit, or the like) are also examples of the driving device.

Note that a display device, a semiconductor device, a lighting device, a cooling device, a light-emitting device, a reflective device, a driving device, and the like are provided together in some cases. For example, a display device includes a semiconductor device and a light-emitting device in some cases. Alternatively, a semiconductor device includes a display device and a driving device in some cases.

Note that when it is explicitly described that “B is formed on A” or “B is formed over A”, it does not necessarily mean that B is formed in direct contact with A. The description includes the case where A and B are not in direct contact with each other, i.e., the case where another object is interposed between A and B. Here, each of A and B corresponds to an object (e.g., a device, an element, a circuit, a wiring, an electrode, a terminal, a conductive film, or a layer).

Therefore, for example, when it is explicitly described that “a layer B is formed on (or over) a layer A”, it includes both the case where the layer B is formed in direct contact with the layer A, and the case where another layer (e.g., a layer C or a layer D) is formed in direct contact with the layer A and the layer B is formed in direct contact with the layer C or D. Note that another layer (e.g., a layer C or a layer D) may be a single layer or a plurality of layers.

Similarly, when it is explicitly described that B is formed above A, it does not necessarily mean that B is formed in direct contact with A, and another object may be interposed therebetween. Accordingly, the case where a layer B is formed above a layer A includes the case where the layer B is formed in direct contact with the layer A and the case where another layer (such as a layer C and a layer D) is formed in direct contact with the layer A and the layer B is formed in direct contact with the layer C or the D. Note that another layer (e.g., a layer C or a layer D) may be a single layer or a plurality of layers.

Note that when it is explicitly described that B is formed over, on, or above A, B may be formed diagonally above A.

Note that the same can be said when it is explicitly described that B is formed below or under A.

Explicit singular forms preferably mean singular forms. However, without being limited thereto, such singular forms can include plural forms. Similarly, explicit plural forms preferably mean plural forms. However, without being limited thereto, such plural forms can include singular forms.

Note that the size, the thickness of layers, or regions in diagrams are sometimes exaggerated for simplicity. Therefore, embodiments of the present invention are not limited to such scales.

Note that diagrams are perspective views of ideal examples, and embodiments of the present invention are not limited to the shape or the value illustrated in the diagrams. For example, the following can be included: variation in shape due to a manufacturing technique or dimensional deviation; or variation in signal, voltage, or current due to noise or difference in timing.

Note that a technical term is used in order to describe a particular embodiment or example or the like in many cases, and is not limited to this.

Note that terms which are not defined (including terms used for science and technology, such as technical terms or academic parlance) can be used as the terms which have meaning equal to general meaning that an ordinary person skilled in the art understands. It is preferable that terms defined by dictionaries or the like be construed as consistent meaning with the background of related art.

Note that terms such as “first”, “second”, “third”, and the like are used for distinguishing various elements, members, regions, layers, and areas from others. Therefore, the terms such as “first”, “second”, “third”, and the like do not limit the number of the elements, members, regions, layers, areas, or the like. Further, for example, “first” can be replaced with “second”, “third”, or the like.

Terms for describing spatial arrangement, such as “over”, “above”, “under”, “below”, “laterally”, “right”, “left”, “obliquely”, “back”, and “front”, are often used for briefly showing, with reference to a diagram, a relation between an element and another element or between some characteristics and other characteristics. Note that embodiments of the present invention are not limited thereto, and such terms for describing spatial arrangement can indicate not only the direction illustrated in a diagram but also another direction. For example, when it is explicitly described that “B is over A”, it does not necessarily mean that B is placed over A. Since a device in a diagram can be inverted or rotated by 180°, the case where B is placed under A can be included. Accordingly, “over” can refer to the direction described by “under” in addition to the direction described by “over”. Note that embodiments of the present invention are not limited thereto, and “over” can refer to other directions described by “laterally”, “right”, “left”, “obliquely”, “back”, and “front” in addition to the directions described by “over” and “under” because a device in a diagram can be rotated in a variety of directions.

According to an embodiment of the invention disclosed, a light-transmitting transistor or a light-transmitting capacitor can be formed. Therefore, even if a transistor or a capacitor is provided in a pixel, the aperture ratio can be high because light can be transmitted also in a portion where the transistor or the capacitor is formed. Further, since a wiring for connecting the transistor and an element (e.g., another transistor) or a wiring for connecting a capacitor element and an element (e.g., another capacitor element) can be formed by using a material with low resistivity and high conductivity, the distortion of the waveform of a signal and a voltage drop due to wiring resistance can be reduced.

### BRIEF DESCRIPTION OF THE DRAWINGS

FIG. 1 is a top view illustrating a semiconductor device.

FIGS. 2A and 2B are cross-sectional views each illustrating a semiconductor device.

FIGS. 3A to 3E are diagrams illustrating a method for manufacturing a semiconductor device.

FIGS. 4A to 4D are diagrams illustrating the method for manufacturing the semiconductor device.

FIGS. 5A to 5C are diagrams illustrating the method for manufacturing the semiconductor device.

FIGS. 6A-1, 6A-2, 6B-1, and 6B-2 are diagrams illustrating multi-tone masks.

FIGS. 7A to 7C are diagrams illustrating a method for manufacturing a semiconductor device.

FIGS. 8A to 8C are diagrams illustrating the method for manufacturing the semiconductor device.

FIGS. 9A to 9C are diagrams illustrating the method for manufacturing the semiconductor device.

FIGS. 10A to 10C are diagrams illustrating the method for manufacturing the semiconductor device.

FIG. 11 is a top view illustrating a semiconductor device.

FIGS. 12A and 12B are cross-sectional views each illustrating a semiconductor device.

FIG. 13A is a top view illustrating a semiconductor device and FIG. 13B is a cross-sectional view illustrating the semiconductor device.

FIG. 14A is a top view illustrating a semiconductor device and FIG. 14B is a cross-sectional view illustrating the semiconductor device.

FIG. 15A is a top view illustrating a semiconductor device and FIG. 15B is a cross-sectional view illustrating the semiconductor device.

FIG. 16A is a top view illustrating a semiconductor device and FIG. 16B is a cross-sectional view illustrating the semiconductor device.

FIG. 17 is a top view illustrating a semiconductor device.

FIG. 18 is a top view illustrating a semiconductor device.

FIGS. 19A and 19B are cross-sectional views illustrating a semiconductor device.

FIG. 20 is a cross-sectional view illustrating a semiconductor device.

FIG. 21 is a top view illustrating a semiconductor device.

FIGS. 22A and 22B are diagrams each illustrating a semiconductor device.

FIGS. 23A and 23B are diagrams each illustrating a semiconductor device.

FIGS. 24A1, 24A2, and 24B are diagrams each illustrating a semiconductor device.

FIG. 25 is a diagram illustrating a semiconductor device.

FIG. 26 is a diagram illustrating a semiconductor device.

FIGS. 27A and 27B are diagrams each illustrating a semiconductor device.

FIGS. 28A to 28C are cross-sectional views each illustrating a semiconductor device.

FIGS. 29A and 29B are diagrams illustrating a semiconductor device.

FIGS. 30A and 30B are diagrams each illustrating an electronic appliance.

FIG. 31 is a diagram illustrating an electronic appliance.

FIGS. 32A and 32B are diagrams each illustrating an electronic appliance.

FIGS. 33A and 33B are diagrams each illustrating an electronic appliance.

FIGS. 34A and 34B are diagrams each illustrating an electronic appliance.

FIGS. 35A and 35B are cross-sectional views each illustrating a semiconductor device.

FIGS. 36A and 36B are diagrams illustrating a method for manufacturing a semiconductor device.

FIG. 37 is a top view illustrating a semiconductor device.

FIG. 38 is a top view illustrating a semiconductor device.

FIG. 39 is a top view illustrating a semiconductor device.

FIG. 40 is a top view illustrating a semiconductor device.

FIGS. 41A to 41G are diagrams each illustrating a semiconductor device.

FIGS. 42A to 42D are diagrams each illustrating a semiconductor device.

FIGS. 43A to 43F are diagrams each illustrating a semiconductor device.

FIGS. 44A to 44C are diagrams each illustrating a semiconductor device.

FIGS. 45A and 45B are diagrams illustrating a semiconductor device.

FIGS. 46A and 46B are diagrams each illustrating a semiconductor device.

FIGS. 47A and 47B are diagrams illustrating a semiconductor device.

FIG. 48A to 48D are diagrams each illustrating a semiconductor device.

### DETAILED DESCRIPTION OF THE INVENTION

The embodiments will be described with reference to the accompanying drawings. Note that the present invention is not limited to the following description of the embodiments. It will be readily appreciated by those skilled in the art that modes and details of the present invention can be changed in various ways without departing from the spirit and scope of the present invention. In structures of the invention described below, the same reference numeral is given to the same parts or parts having similar functions, and repeated description thereof is omitted.

Note that what is described (or part thereof) in one embodiment can be applied to, combined with, or exchanged with another content in the same embodiment and/or what is described (or part thereof) in another embodiment or other embodiments.

Note that in each embodiment, a content described in the embodiment is a content described with reference to a variety of diagrams or a content described with a paragraph disclosed in this specification.

In addition, by combining a diagram (or part thereof) described in one embodiment with another part of the diagram, a different diagram (or part thereof) described in the same embodiment, and/or a diagram (or part thereof) described in one or a plurality of different embodiments, much more diagrams can be formed.

Note that in a diagram or a text described in one embodiment, part of the diagram or the text is taken out, and one embodiment of the invention can be constituted. Thus, in the case where a diagram or a text related to a certain portion is described, the context taken out from part of the diagram or the text is also disclosed as one embodiment of the invention, and one embodiment of the invention can be constituted. Therefore, for example, in a diagram (e.g., a cross-sectional view, a plan view, a circuit diagram, a block diagram, a flow chart, a process diagram, a perspective view, a cubic diagram, a layout diagram, a timing chart, a structure diagram, a schematic view, a graph, a list, a ray diagram, a vector diagram, a phase diagram, a waveform chart, a photograph, or a chemical formula) or a text in which one or more active elements (e.g., transistors or diodes), wirings, passive elements (e.g., capacitors or resistors), conductive layers, insulating layers, semiconductor layers, organic materials, inorganic materials, components, substrates, modules, devices, solids, liquids, gases, operating methods, manufacturing methods, or the like are described, part of the diagram or the text is taken out, and one embodiment of the invention can be constituted.

### Embodiment 1

In this embodiment, a semiconductor device and a manufacturing method thereof are described with reference to the drawings.

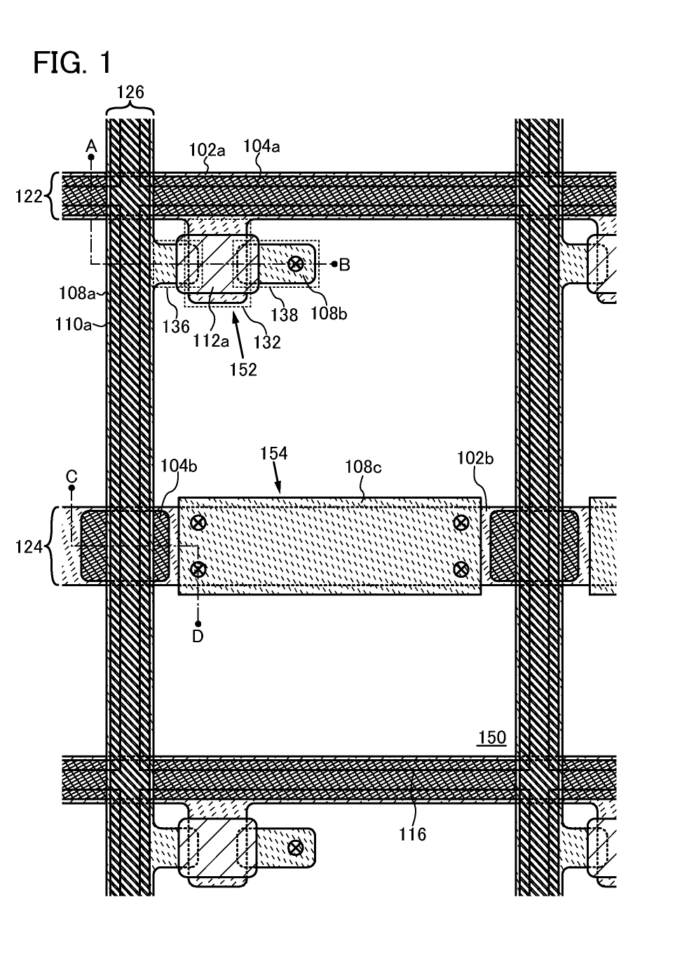

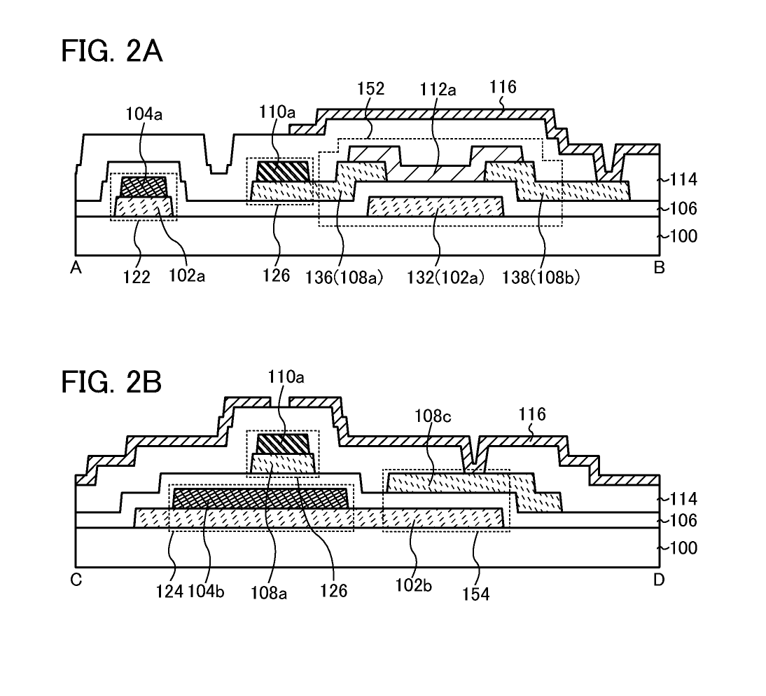

FIG. 1 and FIGS. 2A and 2B each show one example of a structure of a semiconductor device in this embodiment. Note that FIG. 1 is a top view, FIG. 2A is a cross-sectional view of FIG. 1 along line A-B, and FIG. 2B is a cross-sectional view of FIG. 1 along line C-D.

The semiconductor device shown in FIG. 1 includes a pixel portion 150 provided with a transistor 152 and a storage capacitor portion 154, a wiring 122, a wiring 124, and a wiring 126. Note that in FIG. 1, the pixel portion 150 is a region surrounded by a plurality of wirings 122 and a plurality of wirings 126.

Note that the wiring 122 can function as a gate wiring. The wiring 124 can function as a capacitor wiring or a common wiring. The wiring 126 can function as a source wiring. However, this embodiment is not limited to this example.

A transistor 152 includes an electrode 132 provided over a substrate 100, an insulating layer 106 provided over the electrode 132, an electrode 136 and an electrode 138 provided over the insulating layer 106, and a semiconductor layer 112a provided over the insulating layer 106 so as to overlap with the electrode 132 and over the electrode 136 and the electrode 138 (see FIG. 2A).

Note that the electrode 132 can function as a gate electrode. The insulating layer 106 can function as a gate insulating layer. The electrode 136 and the electrode 138 can each function as a source electrode or a drain electrode. The semiconductor layer 112a can be formed using an oxide semiconductor. However, this embodiment is not limited to this example.

The electrode 132 is formed using a conductive layer 102a having a light-transmitting property and is electrically connected to the wiring 122. The wiring 122 is formed using a layered structure of the conductive layer 102a and a conductive layer 104a. In addition, the conductive layer 102a included in the electrode 132 and the conductive layer 102a included in the wiring 122 are formed in the same island. Since the electrode 132 and the wiring 122 are provided by using the conductive layer 102a in the same island, fine electrical connection between the electrode 132 and the wiring 122 can be obtained. In addition, since the electrode 132 and the wiring 122 are provided by using the conductive layer 102a in the same island, the number of masks in manufacturing steps can be reduced and reduction in cost can be achieved. Note that a base insulating layer can be provided between the substrate 100 and the electrode 132.

The conductive layer 102a can be formed using a material having a light-transmitting property, such as indium tin oxide (ITO). In addition, the conductive layer 104a may be formed using a material having lower resistivity than the conductive layer 102a. For example, a single layer or stacked layers of a metal material selected from the group of aluminum (Al), tungsten (W), titanium (Ti), tantalum (Ta), molybdenum (Mo), nickel (Ni), platinum (Pt), copper (Cu), gold (Au), silver (Ag), manganese (Mn), neodymium (Nd), niobium (Nb), cerium (Ce), and chromium (Cr), an alloy material containing the metal material as its main component, or a nitride containing any of the above metal materials as its component can be used. In general, since these metal materials have a light-shielding property, in the structure shown in FIG. 1, a part where the electrode 132 is formed has a light-transmitting property and a part where the wiring 122 is formed has a light-shielding property as compared to the part where the electrode 132 is formed.

In addition, the conductive layer 104a is preferably formed thicker than the conductive layer 102a. In the case where the conductive layer 104a is formed thick, wiring resistance can be reduced. In addition, in the case where the conductive layer 102a is formed thin, transmittance can be increased. However, this embodiment is not limited to this example.

Note that although FIG. 1 and FIGS. 2A and 2B show the case where the layered structure in which the conductive layer 104a is stacked over the conductive layer 102a is used as the wiring 122, the conductive layer 102a may be stacked over the conductive layer 104a.

The electrode 136 is formed using a conductive layer 108a having a light-transmitting property and is electrically connected to the wiring 126. The wiring 126 is formed using a layered structure of the conductive layer 108a and the conductive layer 110a. In addition, the conductive layer 108a included in the electrode 136 and the conductive layer 108a included in the wiring 126 are formed in the same island. Since the electrode 136 and the wiring 126 are formed using the conductive layer 108a in the same island, fine electrical connection between the electrode 136 and the wiring 126 can be obtained.

In addition, the electrode 138 is formed using a conductive layer 108b having a light-transmitting property. The electrode 136 and the electrode 138 can be formed using the same material.

The conductive layer 108a and the conductive layer 108b can be formed using a material having a light-transmitting property, such as indium tin oxide. In addition, the conductive layer 110a may be formed using a material having lower resistance than the conductive layer 108a; for example, a single layer or stacked layers of a metal material such as aluminum (Al), tungsten (W), titanium (Ti), tantalum (Ta), molybdenum (Mo), nickel (Ni), platinum (Pt), copper (Cu), gold (Au), silver (Ag), manganese (Mn), neodymium (Nd), niobium (Nb), cerium (Ce), or chromium (Cr), an alloy material containing any of the above metal materials as its main component, or nitride containing any of the above metal materials as its component can be formed. In general, since metal materials have a light-shielding property, in FIG. 1, a part where the electrode 136 is formed has a light-transmitting property and a part where the wiring 126 is formed has a light-shielding property as compared to the part where the electrode 136 is formed.

In addition, it is preferable that the conductive layer 110a be formed thicker than the conductive layer 108a and the conductive layer 108b. In the case where the conductive layer 110a is formed thick, wiring resistance can be reduced. In addition, in the case where the conductive layer 108a or the conductive layer 108b is formed thin, transmittance can be increased. However, this embodiment is not limited to this example.

The wiring 124 is preferably formed using the conductive layer 102b having a light-transmitting property. In addition, as shown in FIG. 1 and FIGS. 2A and 2B, in a region (and its peripheral region) where the wiring 124 and the wiring 126 overlap with each other, the wiring 124 can be formed using a layered structure of the conductive layer 102b and the conductive layer 104b whose resistance is lower than that of the conductive layer 102b. By formation of the wiring 124 as shown in FIG. 1 and FIGS. 2A and 2B, increase in the aperture ratio of the pixel portion 150 and reduction in the wiring resistance of the wiring 124 can be achieved, and power consumption can be reduced. It is needless to say that the wiring 124 can be formed using only the conductive layer 102b having a light-transmitting property or the conductive layer 104b.

A storage capacitor portion 154 includes the insulating layer 106 which is used as a dielectric, the conductive layer 102b having a light-transmitting property and a conductive layer 108c having a light-transmitting property which are used as electrodes. In addition, the conductive layer 108c is electrically connected to a conductive layer 116. The conductive layer 108c and the conductive layer 116 can be electrically connected to each other through a contact hole formed in an insulating layer 114 which functions as an interlayer film. Note that the conductive layer 116 can function as a pixel electrode.

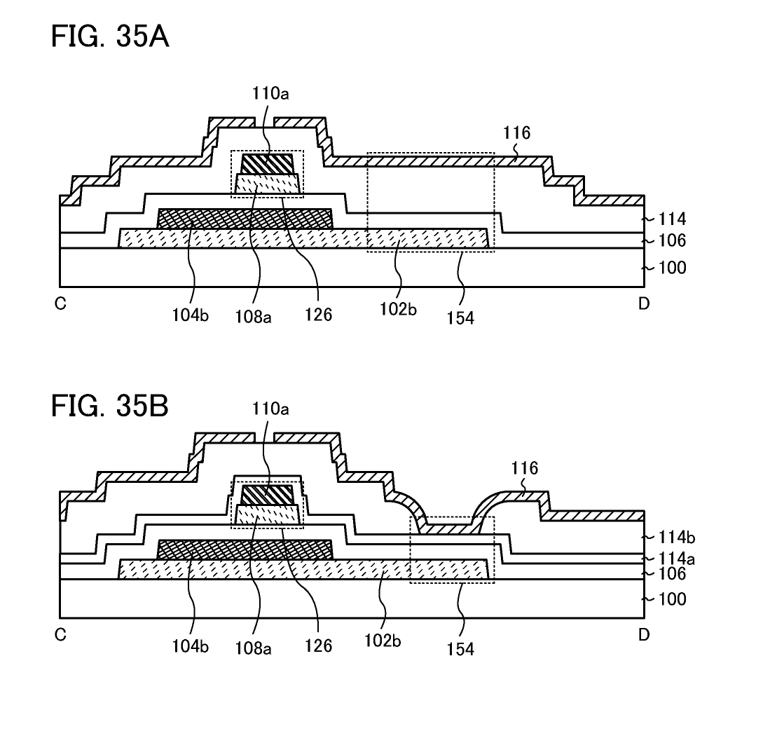

In addition, the storage capacitor portion 154 may include the insulating layer 106 and the insulating layer 114, which are used as dielectrics, and the conductive layer 102b and the conductive layer 116, which are used as electrodes (see FIG. 35A). Alternatively, the storage capacitor portion 154 may have the following structure: in FIG. 35A, an insulating layer 114a formed using an inorganic material (silicon nitride or the like) and an insulating layer 114b formed using an organic material are sequentially stacked to form the insulating layer 114; the insulating layer 114b formed using the organic material is removed from the storage capacitor portion 154; and the storage capacitor portion 154 includes the insulating layer 106 and the insulating layer 114a, which are used as dielectrics, and the conductive layer 102b and the conductive layer 116, which are used as electrodes (see FIG. 35B).

As shown in FIG. 1 and FIGS. 2A and 2B, since the storage capacitor portion 154 is formed using the material having a light-transmitting property, light can pass through a region where the storage capacitor portion 154 is formed. Therefore, the aperture ratio of the pixel portion 150 can be increased.

In addition, since an electrode for the storage capacitor portion 154 is formed using the conductive layer having a light-transmitting property, the storage capacitor portion 154 can be formed large without decreasing the aperture ratio. By formation of the large storage capacitor portion 154, even when the transistor 152 is off, the potential holding characteristics of the conductive layer 116 are improved, whereby display quality is improved. Moreover, feedthrough potential can be low. Since the feedthrough potential is low, accurate voltage can be applied, whereby flickers can be reduced. In addition, since resistance to noise is increased, crosstalk can be reduced.

The conductive layer 116 is electrically connected to the electrode 138 and the conductive layer 108c.

In this manner, since the electrode 132, the semiconductor layer 112a, the electrode 136, the electrode 138, and the storage capacitor portion 154 are formed using the material having a light-transmitting property, light can pass through a region where the transistor 152 is formed and a region where the storage capacitor portion 154 is formed, whereby the aperture ratio of the pixel portion 150 can be increased. In addition, since part of each of the wiring 122, the wiring 126, and the wiring 124 is formed using a conductive layer of a metal material having low resistivity, wiring resistance can be reduced. As a result, distortion of waveform can be suppressed. Further, power consumption can be reduced.

In general, a gate wiring and a gate electrode are formed in the same island and a source wiring and a source electrode are formed in the same island. Therefore, in the case where the gate electrode or the source electrode and drain electrode are formed using a material having a light-transmitting property, wirings such as a gate wiring and a source wiring are formed using the material having a light-transmitting property. However, since a material having a light-transmitting property, such as indium tin oxide, indium zinc oxide, and indium tin zinc oxide have lower conductivity as compared to a material having a light-shielding property and reflectivity, for example, a metal material such as aluminum, molybdenum, titanium, tungsten, neodymium, copper, and silver, it is difficult to adequately reduce wiring resistance. For example, in the case where a large display device is manufactured, wiring resistance easily becomes very high because a wiring is long. In that case, as described above, since the electrode 132, the semiconductor layer 112a, the electrode 136, the electrode 138, and the storage capacitor portion 154 are formed using the material having a light-transmitting property and part of each of the wiring 122, the wiring 126, and the wiring 124 is formed using a conductive layer of a metal material having low resistivity, such a problem can be solved.

In addition, by formation of the conductive layer 104a which is included in the gate wiring and the conductive layer 110a which is included in the source wiring with the use of a metal material having a light-shielding property, wiring resistance can be suppressed and a region between adjacent pixel portions can be shielded from light. In other words, with the gate wiring provided in a row direction and the source wiring provided in a column direction, the space between the pixels can be shielded from light without using a black matrix. It is needless to say that light may be more effectively shielded by separately providing a black matrix.

Note that the structure shown in FIG. 1 and FIGS. 2A and 2B does not necessarily include the storage capacitor portion 154. In that case, the wiring 124 is not necessary.

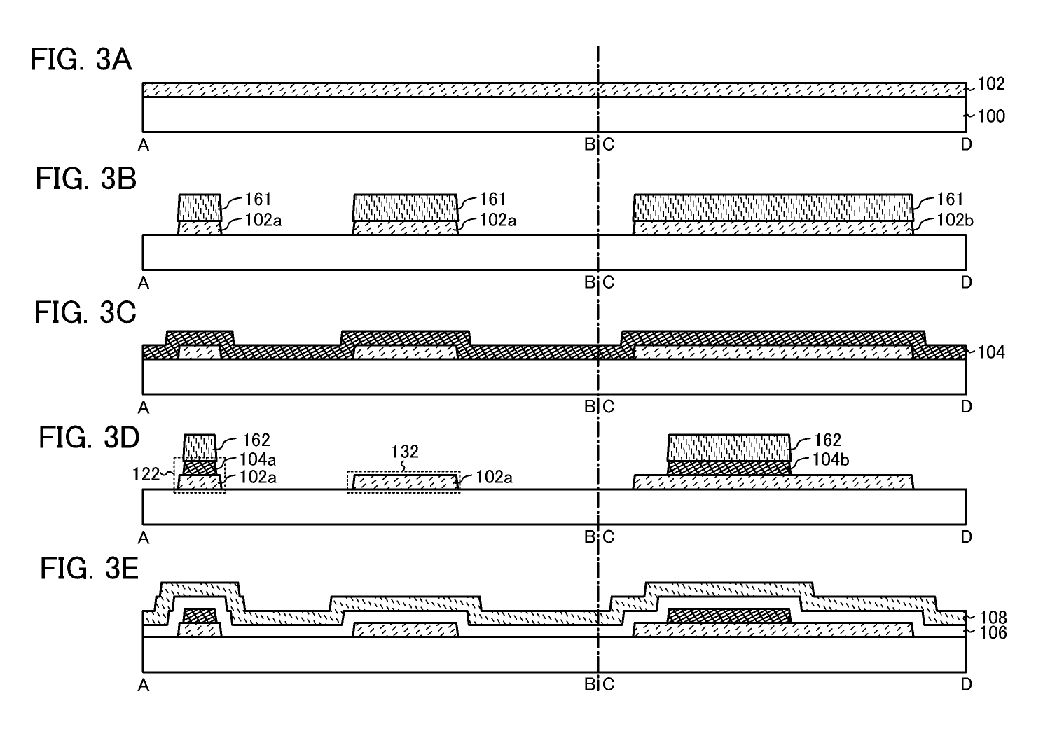

Next, an example of manufacturing the semiconductor device shown in FIG. 1 and FIGS. 2A and 2B is described with reference to FIGS. 3A to 3E, 4A to 4D, and 5A to 5C.

First, the conductive layer 102 is formed over the substrate 100 (see FIG. 3A). A base insulating film may be formed between the substrate 100 and the conductive film 102.

As the substrate 100, for example, a glass substrate can be used. Besides, as the substrate 100, an insulating substrate formed of an insulator such as a ceramic substrate, a quartz substrate, or a sapphire substrate, a semiconductor substrate formed using a semiconductor material such as silicon, whose surface is covered with an insulating material, a conductive substrate formed using a conductor such as metal or stainless steel, whose surface is covered with an insulating material can be used. In addition, a plastic substrate can be used as long as it can withstand heat treatment in a manufacturing process.

The conductive film 102 can be formed using a material having a light-transmitting property. As a material having a light-transmitting property, for example, indium tin oxide (ITO), indium tin oxide containing silicon oxide (ITSO), organic indium, organic tin, zinc oxide (ZnO), or the like can be used. Further, indium zinc oxide (IZO) containing zinc oxide, ZnO doped with gallium (Ga), tin oxide (SnO₂), indium oxide containing tungsten oxide, indium zinc oxide containing tungsten oxide, indium oxide containing titanium oxide, indium tin oxide containing titanium oxide, or the like may be used. Such a material can be used to form the conductive film 102 with a single-layer structure or a layered structure by sputtering. However, in the case of the layered structure, it is preferable that the light transmittance be adequately high.

Next, resist masks 161 are formed over the conductive film 102 and the conductive film 102 is etched with the resist masks 161. Accordingly, the conductive layers 102a and the conductive layer 102b in an island shape are formed (see FIG. 3B).

The conductive layers 102a function as parts of the wiring 122 and the electrode 132. In addition, the conductive layer 102b functions as part of the wiring 124.

Next, the conductive film 104 is formed over the substrate 100, the conductive layer 102a, and the conductive layer 102b (see FIG. 3C).

The conductive film 104 can be formed to have a single-layer structure or a layered structure using a metal material such as aluminum (Al), tungsten (W), titanium (Ti), tantalum (Ta), molybdenum (Mo), nickel (Ni), platinum (Pt), copper (Cu), gold (Au), silver (Ag), manganese (Mn), or neodymium (Nd), niobium (Nb), cerium, (Ce), chromium (Cr), an alloy material containing any of the above metal materials as its main component, or a nitride containing any of the above metal materials as its component. Specifically, the conductive film 104 is preferably formed using a low-resistance conductive material such as aluminum.

In the case where the conductive film 104 is formed over the conductive layers 102a and 102b, the conductive film 104 reacts with each of the conductive layers 102a and 102b in some cases. For example, in the case where ITO is used as the conductive layers 102a and 102b and aluminum is used as the conductive film 104, a chemical reaction occurs in some cases. Therefore, in order to avoid a chemical reaction, a material with a high melting point is preferably provided between the conductive film 104 and the conductive layers 102a and 102b. For example, molybdenum, titanium, tungsten, tantalum, chromium, or the like can be given as the material with a high melting point. Also, it is preferable to form the conductive film 104 with a multi-layer film by using a material with high conductivity over a film formed using the material with a high melting point. As the material with high conductivity, aluminum, copper, silver, or the like can be given. For example, in the case where the conductive film 104 is formed to have a layered structure, a stacked layer of molybdenum as a first layer, aluminum as a second layer, and molybdenum as a third layer, or a stacked layer of molybdenum as a first layer, aluminum containing a small amount of neodymium as a second layer, and molybdenum as a third layer can be used. With such a structure, the formation of hillock can be prevented.

Next, resist masks 162 are formed over the conductive film 104 and the conductive film 104 is etched with the resist masks 162. Accordingly, the conductive layer 104a and the conductive layer 104b in an island shape are formed (see FIG. 3D).

At that time, the conductive film 104 formed over the conductive layer 102a which functions as the electrode 132 and part of the conductive film 104, which is formed in a region included in the pixel portion, of the wiring 124 are removed.

The conductive layer 104a functions as part of the wiring 122. In addition, the conductive layer 104b functions as part of the wiring 124.

In addition, although FIG. 3D shows the case where the conductive layer 104a is formed to have a width which is smaller than that of the conductive layer 102a, and the conductive layer 104b is formed to have a width which is smaller than that of the conductive layer 102b, this embodiment is not limited to this example. The width of the conductive layer 104a may be larger than that of the conductive layer 102a so that the conductive layer 104a is formed so as to cover the conductive layer 102a, or the width of the conductive layer 104b may be larger than that of the conductive layer 102b so that the conductive layer 104b is formed so as to cover the conductive layer 102b.

Next, the insulating layer 106 is formed so as to cover the conductive layer 102a, the conductive layer 102b, the conductive layer 104a, and the conductive layer 104b. Then, the conductive film 108 is formed over the insulating layer 106 (see FIG. 3E).

The gate insulating film 106 can be formed to have a single-layer structure of a silicon oxide film, a silicon oxynitride film, a silicon nitride film, a silicon nitride oxide film, an aluminum oxide film, an aluminum nitride film, an aluminum oxynitride film, an aluminum nitride oxide film, or a tantalum oxide film or a layered structure of any of the above films. The insulating film 106 can be formed to have a thickness of greater than or equal to 50 nm and less than or equal to 250 nm by a sputtering method or the like. For example, as the insulating layer 106, a silicon oxide film can be formed to a thickness of 100 nm by a sputtering method or a CVD method. Alternatively, an aluminum oxide film can be formed to a thickness of 100 nm by a sputtering method.

The conductive film 108 can be formed using a material having a light-transmitting property. As a material having a light-transmitting property, indium tin oxide (ITO), indium tin oxide containing silicon oxide (ITSO), organic indium, organic tin, zinc oxide (ZnO), or the like can be used. Further, indium zinc oxide (IZO) containing zinc oxide, zinc oxide doped with gallium (Ga), tin oxide (SnO₂), indium oxide containing tungsten oxide, indium zinc oxide containing tungsten oxide, indium oxide containing titanium oxide, indium tin oxide containing titanium oxide, or the like may be used. Such a material can be used to form the conductive film 108 with a single-layer structure or a layered structure by sputtering. However, in the case of the layered structure, it is preferable that the light transmittance of each of a plurality of films be adequately high.

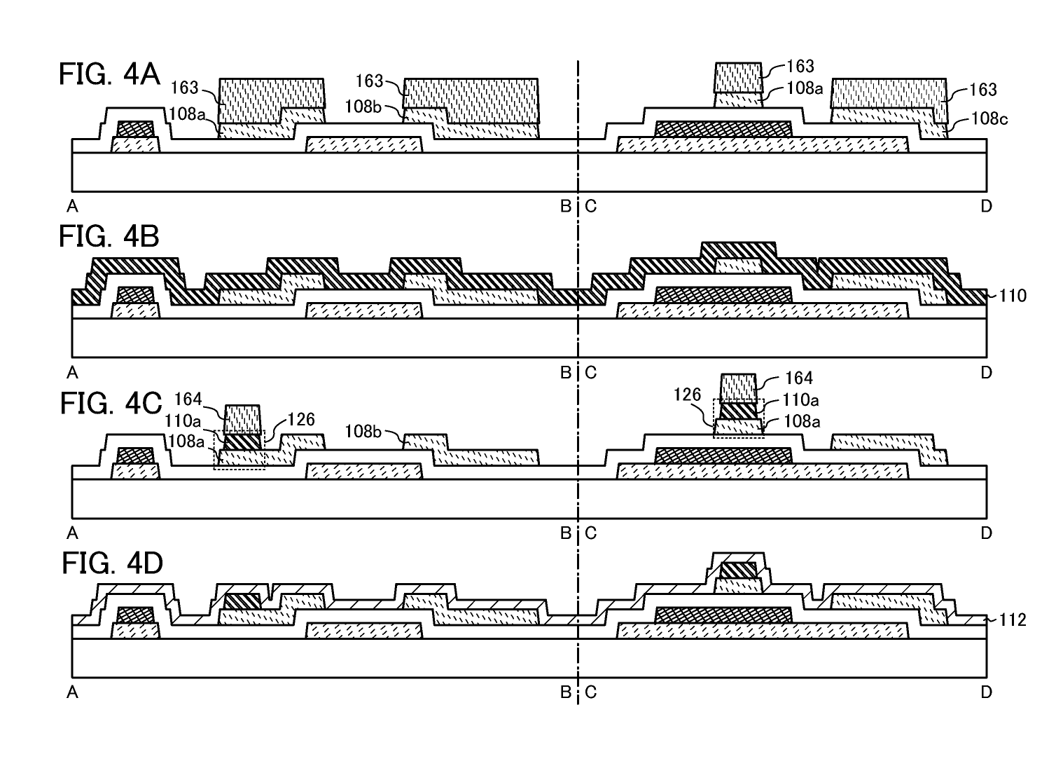

Next, resist masks 163 are formed over the conductive film 108 and the conductive film 108 is etched with the resist masks 163. Accordingly, the conductive layer 108a, the conductive layer 108b, and the conductive layer 108c in an island shape are formed (see FIG. 4A).

The conductive layer 108a functions as part of the wiring 126 and the electrode 136. In addition, the conductive layer 108b functions as the wiring 138. In addition, the conductive layer 108c functions as one electrode of the storage capacitor portion 154.

In addition, an end portion of the conductive layer 108b is preferably tapered. This is because the tapered end portion prevents disconnection in a semiconductor layer which is formed over the conductive layer 108b later.

Next, a conductive film 110 is formed so as to cover the conductive layers 108a to 108c (see FIG. 4B).

The conductive film 110 can be formed to have a single-layer structure or a layered structure using a metal material such as aluminum (Al), tungsten (W), titanium (Ti), tantalum (Ta), molybdenum (Mo), nickel (Ni), platinum (Pt), copper (Cu), gold (Au), silver (Ag), manganese (Mn), or neodymium (Nd), an alloy material containing any of the above metal materials as its main component, or a nitride containing any of the above metal materials as its component. The conductive film 110 is preferably formed using a low-resistant conductive material such as aluminum.

In the case where the conductive film 110 is formed over the conductive layers 108a to 108c, the conductive film 110 reacts with each of the conductive layers 108a to 108c in some cases. For example, in the case where ITO is used as the conductive layers 108a to 108c and aluminum is used as the conductive film 110, a chemical reaction occurs in some cases. Therefore, in order to avoid a chemical reaction, a material with a high melting point is preferably provided between each of the conductive layers 108a to 108c and the conductive film 110. For example, molybdenum, titanium, tungsten, tantalum, chromium, or the like can be given as the material with a high melting point. Also, it is preferable to form the conductive film 110 into a multi-layer film by using a material with high conductivity over a film formed using the material with a high melting point. As the material with high conductivity, aluminum, copper, silver, or the like can be given. For example, in the case where the conductive film 110 is formed to have a layered structure, a stacked layer of molybdenum as a first layer, aluminum as a second layer, and molybdenum as a third layer, or a stacked layer of molybdenum as a first layer, aluminum containing a small amount of neodymium as a second layer, and molybdenum as a third layer can be used. With such a structure, the formation of hillock can be prevented.

Next, resist masks 164 are formed over the conductive film 110 and the conductive film 110 is etched with the resist masks 164. Accordingly, the conductive layers 110a in an island shape are formed (see FIG. 4C).

Specifically, etching is performed so as to leave the conductive film 110 over the conductive layer 108a. In that case, the conductive film 110 formed over part of the conductive layer 108a, which functions as the electrode 136, is removed. That is, the conductive layer 110a functions as the part of the wiring 126.

Next, a semiconductor film 112 having a light-transmitting property is formed so as to cover the conductive layers 108a and 108b, the insulating layer 106, and the like (see FIG. 4D).

For the semiconductor film 112, for example, an oxide semiconductor containing In, M, or Zn can be used. Here, M represents one or a plurality of metal elements selected from Ga, Fe, Ni, Mn, and Co. In addition, if Ga is employed as M, the thin film is referred to as an In—Ga—Zn—O-based non-single-crystal film. Moreover, in the oxide semiconductor, in some cases, a transition metal element such as Fe or Ni or an oxide of the transition metal is contained as an impurity element in addition to a metal element contained as M. Further, the semiconductor film 112 may contain an insulating impurity. As the impurity, insulating oxide typified by silicon oxide, germanium oxide, aluminum oxide, or the like; insulating nitride typified by silicon nitride, aluminum nitride, or the like; or insulating oxynitride such as silicon oxynitride or aluminum oxynitride is applied. The insulating oxide or the insulating nitride is added to the oxide semiconductor at a concentration at which electrical conductivity of the oxide semiconductor does not deteriorate. Insulating impurity is contained in the oxide semiconductor, whereby crystallization of the oxide semiconductor can be suppressed. By containing such an insulating impurity, the oxide semiconductor becomes difficult to crystallize; thus, characteristics of the thin film transistor can be stabilized.

Since the In—Ga—Zn—O-based oxide semiconductor contains the impurity such as silicon oxide, crystallization of the oxide semiconductor or generation of microcrystal grains can be prevented even when the oxide semiconductor is subjected to heat treatment at 300 to 600° C. In a manufacturing process of the thin film transistor in which an In—Ga—Zn—O-based oxide semiconductor layer is a channel formation region, an S value (a subthreshold swing value) or an electrical field effect mobility can be improved by heat treatment. Even in such a case, the thin film transistor can be prevented from being normally-on. Further, even if heat stress or bias stress is added to the thin film transistor, a change in threshold voltage can be prevented.

As the oxide semiconductor which is applied to the channel formation region of the thin film transistor, any of the following oxide semiconductors can be applied in addition to the above: an In—Sn—Zn—O-based oxide semiconductor, an In—Al—Zn—O-based oxide semiconductor, an Sn—Ga—Zn—O-based oxide semiconductor, an Al—Ga—Zn—O-based oxide semiconductor, an Sn—Al—Zn—O-based oxide semiconductor, an In—Zn—O-based oxide semiconductor, an Sn—Zn—O-based oxide semiconductor, an Al—Zn—O-based oxide semiconductor, an In—O-based oxide semiconductor, an Sn—O-based oxide semiconductor, and a Zn—O-based oxide semiconductor. In other words, by addition of an impurity which suppresses crystallization to keep an amorphous state to these oxide semiconductors, characteristics of the thin film transistor can be stabilized. The impurity is insulating oxide typified by silicon oxide, germanium oxide, aluminum oxide, or the like; insulating nitride typified by silicon nitride, aluminum nitride, or the like; or insulating oxynitride such as silicon oxynitride or aluminum oxynitride.

For example, the semiconductor film 112 can be formed by a sputtering method using an oxide semiconductor target including In, Ga, and Zn (In₂O₃:Ga₂O₃:ZnO=1:1:1). The condition of sputtering can be set as follows: the distance between the substrate 100 and the target is 30 to 500 mm, the pressure is 0.1 to 2.0 Pa, the direct current (DC) power supply is 0.25 to 5.0 kW (when a target with a diameter of 8 inch is used), and an atmosphere is an argon atmosphere, an oxygen atmosphere, or a mixture atmosphere of argon and oxygen, for example. The semiconductor film 112 may have a thickness of approximately 5 to 200 nm.

As the above sputtering method, an RF sputtering method using a high frequency power supply as a power supply for sputtering, a DC sputtering method, a pulsed DC sputtering method in which a DC bias is applied in a pulse manner, or the like can be employed. The RF sputtering is mainly used in the case of forming an insulating film, and the DC sputtering is mainly used in the case of forming a metal film.

Alternatively, a multi-target sputtering apparatus in which a plurality of targets which are formed of different materials from each other may be used. In a multi-target sputtering apparatus, a stack of different films can be formed in one chamber, or one film can be formed by sputtering using plural kinds of materials at the same time in one chamber. Alternatively, a method using a magnetron sputtering apparatus in which a magnetic field generating system is provided inside the chamber (a magnetron sputtering method), an ECR sputtering method in which plasma generated by using a micro wave is used, or the like may be employed. Further alternatively, a reactive sputtering method in which a target substance and a sputtering gas component are chemically reacted with each other to form a compound thereof at the time of film formation, a bias sputtering method in which a voltage is applied also to the substrate at the time of film formation, or the like may be employed.

Note that a semiconductor material used for a channel layer of the transistor 152 is not limited to an oxide semiconductor. For example, a silicon layer (an amorphous silicon layer, a microcrystalline silicon layer, a polycrystalline silicon layer, or a single crystal silicon layer) can be used as the channel layer of the transistor 152. Other than above, for the channel layer of the transistor 152, an organic semiconductor material having a light-transmitting property, a compound semiconductor such as a carbon nanotube, gallium arsenide, or indium phosphide may be used. Note that the state in which the semiconductor layer has a light-transmitting property may be the state in which the semiconductor layer has a light-transmitting property which is higher than at least that of the conductive layer 104a which is included in the wiring 122 or the conductive layer 110a which is included in the wiring 126.

In this embodiment, since the semiconductor film 112 is provided after the conductive layers (the conductive layers 108a, the conductive layer 108b, and the conductive layer 110a) are formed, the semiconductor film 112 is not etched when these conductive layers are etched. Therefore, the semiconductor film 112 can be formed thin. Since the semiconductor film 112 is formed thin, a light-transmitting property can be improved and a depletion layer is easily formed. As a result, the S value of the transistor can be reduced and a switching characteristics of the transistor can be improved. In addition, off current can be reduced.

Note that the semiconductor film 112 is preferably formed thinner than the conductive layer 108a and the conductive layer 108b. However, this embodiment is not limited to this example.

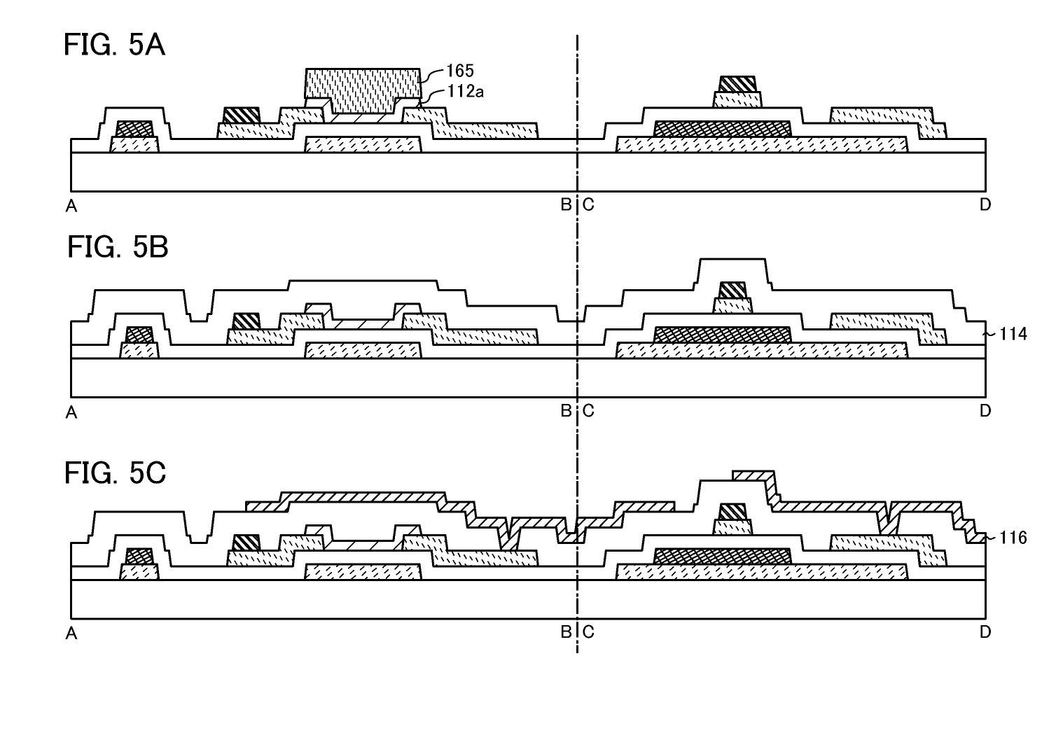

Next, a resist mask 165 is formed over the semiconductor film 112 and the semiconductor film 112 is etched with the resist mask 165, whereby the semiconductor layer 112a in an island shape is formed (see FIG. 5A).

Alternatively, the semiconductor layer 112a may be formed before the conductive film 110 is formed (after the step shown in FIG. 4A). In that case, the semiconductor layer 112 may be formed and etched to form the semiconductor layer 112a in an island shape after the step shown in FIG. 4A, and then the conductive film 110 may be formed.

In addition, after the semiconductor layer 112a is formed, heat treatment is preferably performed at 100 to 600° C., typically 200 to 400° C., under a nitrogen atmosphere or an air atmosphere. For example, heat treatment can be performed under a nitrogen atmosphere at 350° C. for one hour. Through the heat treatment, rearrangement at the atomic level is performed in the island-shape semiconductor layer 112a. This heat treatment (including photo-annealing and the like) is important in terms of releasing distortion which interrupts carrier movement in the island-shape semiconductor layer 112a. Note that there is no particular limitation on the timing of the above heat treatment as long as it is after the formation of the semiconductor film 112.

Next, the insulating layer 114 is formed so as to cover the semiconductor layer 112a, the wiring 126, the electrode 136, the electrode 138, and the conductive layer 108c (see FIG. 5B).

The insulating layer 114 can be formed using a film of a single-layer structure or a layered structure formed using an insulating film including oxygen or nitrogen, such as silicon oxide, silicon nitride, silicon oxynitride, or silicon nitride oxide, a film including carbon such as DLC (diamond like carbon), an organic material such as epoxy, polyimide, polyamide, polyvinyl phenol, benzocyclobutene, or acrylic, or a siloxane material such as a siloxane resin.

In addition, the insulating layer 114 can function as a color filter. By provision of a color filter on the substrate 100 side, a counter substrate side does not need to be provided with a color filter. Therefore, a margin for adjusting the position of two substrates is not necessary, whereby manufacturing of a panel can be made simple.

Next, a conductive layer 116 is formed over the insulating layer 114 (see FIG. 5C). The conductive layer 116 can function as a pixel electrode and is formed so as to be electrically connected to the conductive layer 108c.

The conductive layer 116 can be formed using a material having a light-transmitting property. As a material having a light-transmitting property, indium tin oxide (ITO), indium tin oxide containing silicon oxide (ITSO), organic indium, organic tin, zinc oxide (ZnO), or the like can be used. Further, indium zinc oxide (IZO) containing zinc oxide, zinc oxide doped with gallium (Ga), tin oxide (SnO₂), indium oxide containing tungsten oxide, indium zinc oxide containing tungsten oxide, indium oxide containing titanium oxide, indium tin oxide containing titanium oxide, or the like may also be used. Such a material can be used to form the conductive layer 116 with a single-layer structure or a layered structure by sputtering. However, in the case of the layered structure, it is preferable that the light transmittance of each of a plurality of films be adequately high. Specifically, the conductive layer 116 is preferably formed thinner than the conductive layer 102a and the conductive layer 108a to improve a light-transmitting property in the pixel portion. However, this embodiment is not limited to this example.

The semiconductor device can be manufactured through the above process. According to the manufacturing method described in this embodiment, the transistor 152 having a light-transmitting property and the storage capacitor portion 154 having a light-transmitting property can be formed. Therefore, even if a transistor or a capacitor is provided in a pixel, the aperture ratio can be high because light can pass also through a portion where the transistor or the capacitor is formed. Further, since a wiring for connecting the transistor and an element (e.g., another transistor) is formed by using a material with low resistivity and high conductivity, the distortion of the waveform of a signal and a voltage drop due to wiring resistance can be suppressed.

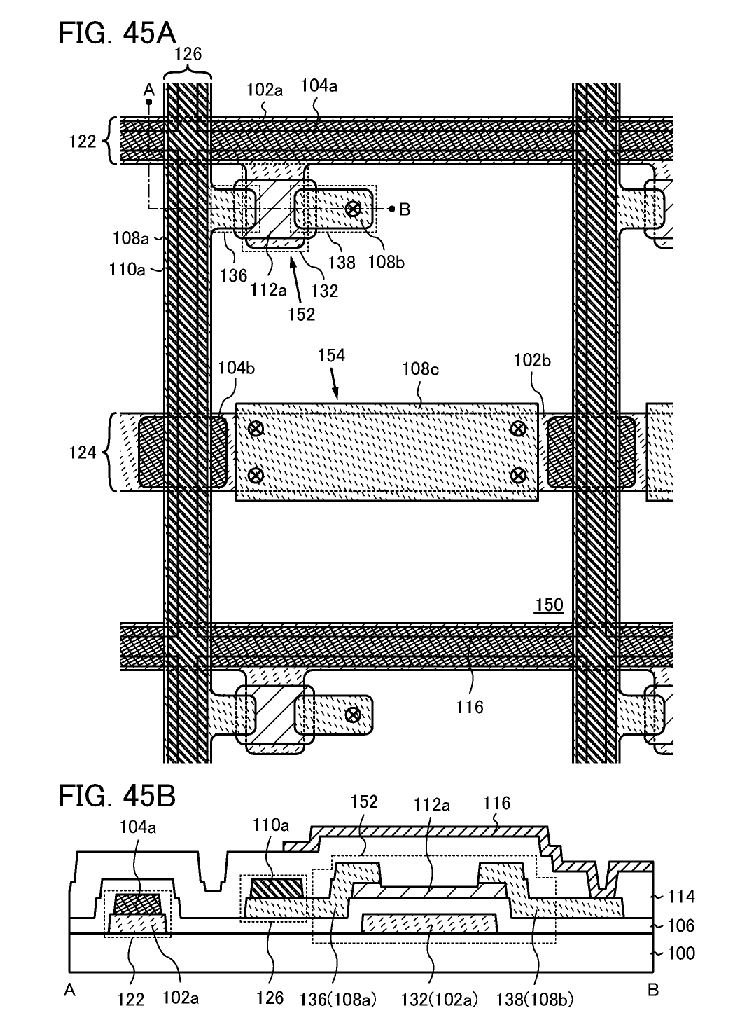

In addition, although the structure in which the semiconductor layer 112a is provided over the electrode 136 and the electrode 138 (a bottom contact structure) is shown in this embodiment, this embodiment is not limited to this example. For example, a structure in which the electrode 136 and the electrode 138 are provided over the semiconductor layer 112a (a channel etch structure) may be employed (see FIGS. 45A and 45B). Note that FIG. 45A is a top view and FIG. 45B corresponds to the cross section of FIG. 45A along line A-B.

The structure shown in FIGS. 45A and 45B can be obtained by formation of the conductive film 108 after the semiconductor film 112 is formed over the insulating layer 106 and is patterned in FIG. 3E.

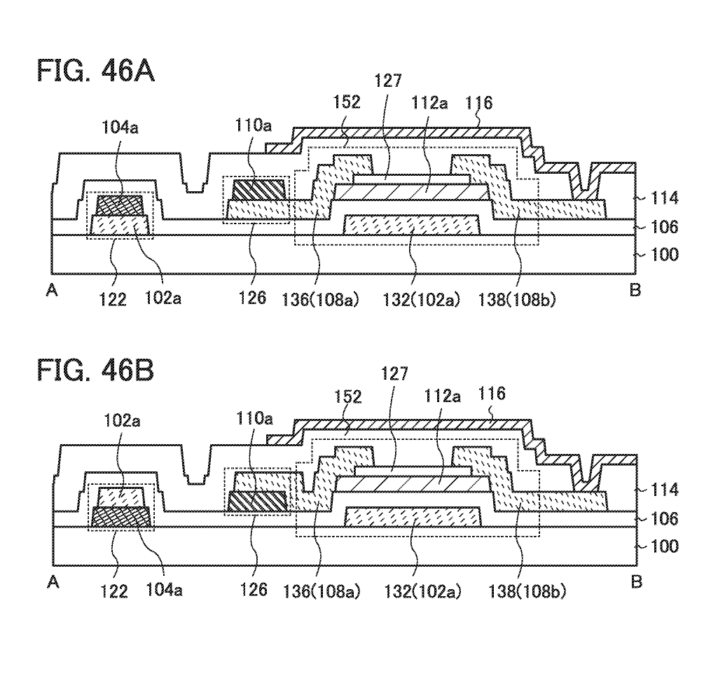

Alternatively, a structure in which an insulating layer 127 which functions as a channel protection film is provided over the semiconductor layer 112a in the structure of FIGS. 45A and 45B (a channel protection structure) may be employed (see FIG. 46A). By the provision of the insulating layer 127, the semiconductor layer 112a can be protected when the conductive film 108 is patterned.

### Embodiment 2

In this embodiment, a manufacturing method of a semiconductor device which is different from that of Embodiment 1 will be described with reference to drawings. Specifically, the case will be described in which a semiconductor device is formed using a multi-tone mask. Note that the manufacturing process of the semiconductor device in this embodiment has a lot in common with that in Embodiment 1. Thus, description of the common portions is omitted, and differences are described in detail below.

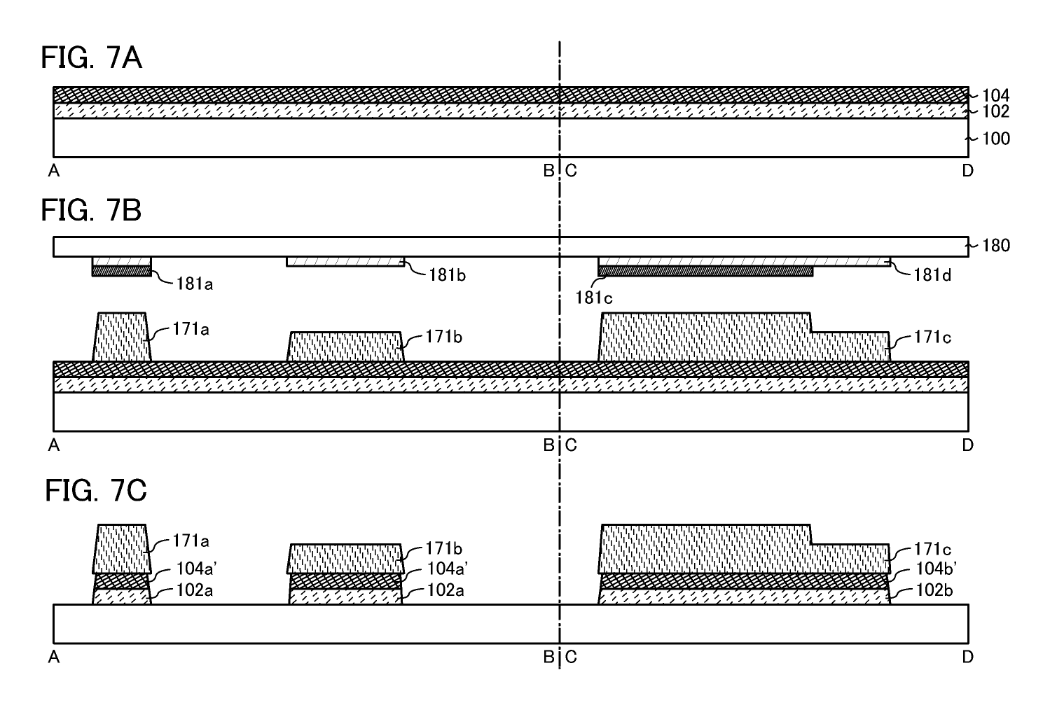

First, the conductive film 102 is formed over the substrate 100, and then the conductive film 104 is formed over the conductive film 102 (see FIG. 7A). A base insulating film may be provided between the substrate 100 and the conductive film 102.

Next, resist masks 171a to 171c are formed over the conductive film 104 (see FIG. 7B).

The resist masks 171a to 171c can be selectively formed to have different thicknesses by using a multi-tone mask.

A multi-tone mask is a mask capable of light exposure with multi-level light intensity, and typically, light exposure is performed with three levels of light intensity to provide an exposed region, a half-exposed region, and an unexposed region. With the use of a multi-tone mask, one-time exposure and development process allows a resist mask with plural thicknesses (typically, two kinds of thicknesses) to be formed. Thus, the use of a multi-tone mask can reduce the number of photomasks. The light transmittance in the case of using a multi-tone mask is described with reference to FIGS. 6A-1, 6A-2, 6B-1, and 6B-2 below.

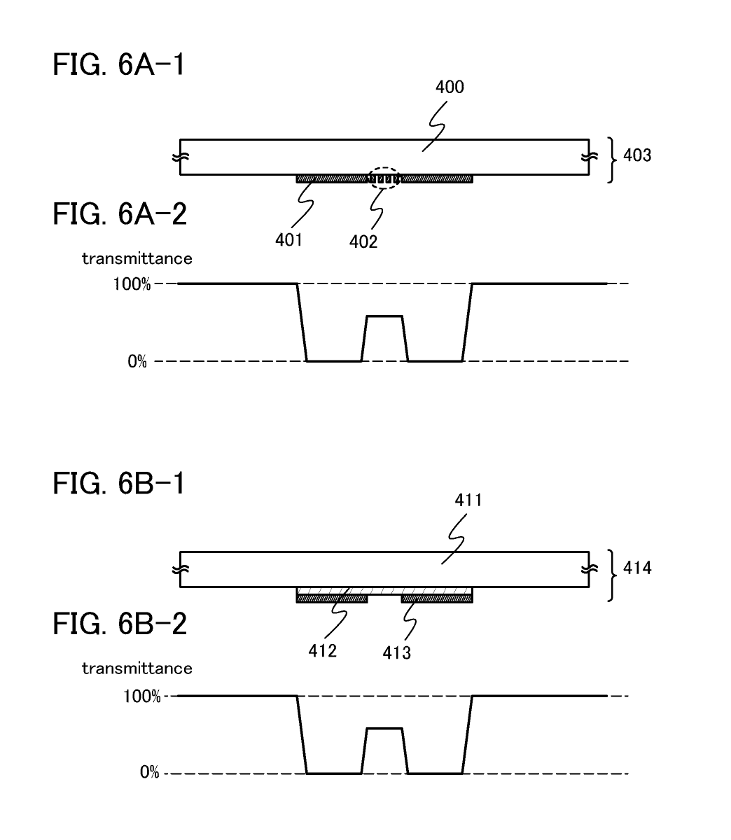

FIGS. 6A-1 and 6B-1 each show a cross section of a typical multi-tone mask. FIG. 6A-1 shows the case where a gray-tone mask 403 is used and FIG. 6B-1 shows the case where a half-tone mask 414 is used.

The gray-tone mask 403 shown in FIG. 6A-1 includes a light-shielding portion 401 formed using a light-shielding layer on a light-transmitting substrate 400 and a diffraction grating portion 402 formed by the pattern of the light-shielding layer.

The transmittance of light is controlled at the diffraction grating portion 402 in such a manner that slits, dots, mesh, or the like are provided at an interval equal to or less than the resolution limit of light used for light exposure. Note that the slits, dots, or mesh provided at the diffraction grating portion 402 may be provided periodically or not periodically.

As the light-transmitting substrate 400, quartz or the like can be used. The light-shielding layer included in the light-shielding portion 401 and the diffraction grating portion 402 may be formed using a metal film: preferably chromium, chromium oxide, or the like.

In the case where the gray-tone mask 403 is irradiated with light for light exposure, as illustrated in FIG. 6A-2, the transmittance in a region overlapping with the light-shielding portion 401 can be 0%, whereas the transmittance in a region where neither the light-blocking portion 401 nor the diffraction grating portion 401 are provided can be 100%. Further, the transmittance in the diffraction grating portion 402 is in the range of about 10 to 70%, which can be adjusted by the intervals of slits, dots, or mesh of the diffraction grating, or the like.

The half-tone mask 414 shown in FIG. 6B-1 includes a semi-light-transmitting portion 412 which is formed of a semi-light-transmitting layer provided for a substrate 411 having a light-transmitting property, and a light-shielding portion 413 formed of a light-shielding layer.

The semi-light-transmitting portion 412 can be formed by using a layer of MoSiN, MoSi, MoSiO, MoSiON, CrSi, or the like. The light-shielding portion 413 may be formed using a similar metal film to the light-shielding layer of the gray-tone mask; preferably, chromium, chromium oxide, or the like is used.

In the case where the half-tone mask 414 is irradiated with light for light exposure, as illustrated in FIG. 6B-2, the transmittance in a region overlapping with the light-shielding portion 413 can be 0%, whereas the transmittance in a region where both the light-shielding portion 413 and the semi-light-transmitting portion 412 are not provided can be 100%. In addition, the transmittance of the semi-light-transmitting portion 412 is approximately 10 to 70% and can be adjusted by the kind of material used or the thickness of a film to be formed, or the like.

In this manner, with the use of a multi-tone mask, a mask with three levels of light exposure, a mask having an exposed portion, a half-exposed portion, and an unexposed portion can be formed; one-time exposure and development process allows a resist mask with regions of plural thicknesses (typically, two kinds of thicknesses) to be formed. Therefore, with the use of a multi-tone mask, the number of photomasks can be reduced.

FIG. 7B shows the case where a half-tone mask is used as a multi-tone mask. The half-tone mask includes a substrate 180 which transmits light, light-shielding layers 181a and 181c, and semi-light-transmitting layers 181b and 181d provided on the substrate 180. Therefore, a resist mask 171a which is thick, a resist mask 171b which is thin, and a resist mask 171c which includes a thick portion and a thin portion are formed over the conductive film 104.

Next, with the use of the resist masks 171a to 171c, unnecessary portions of the conductive films 102 and 104 are etched, whereby conductive layers 102a, a conductive layer 102b, conductive layers 104a′, and a conductive layer 104b′ are formed (see FIG. 7C).

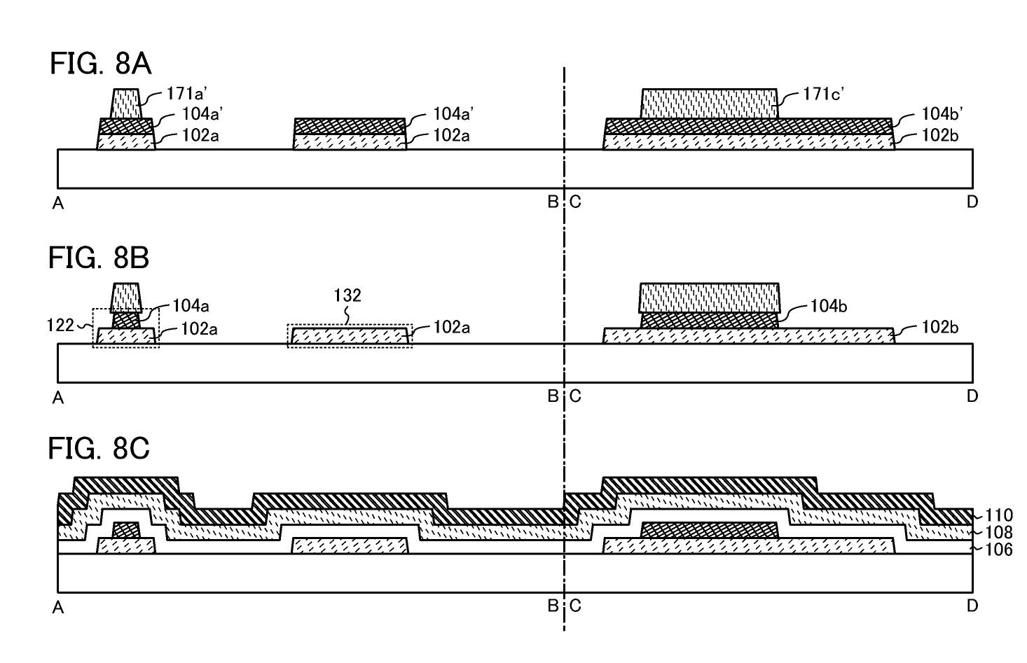

Next, ashing with an oxygen plasma is performed on the resist masks 171a to 171c. After the ashing with the oxygen plasma on the resist masks 171a to 171c, the resist mask 171b is removed and part of the conductive layer 104a′, which is formed over the conductive layer 102a, is exposed. In addition, the resist masks 171a and 171c diminish and remain as resist masks 171a′ and 171c′ (see FIG. 8A). In this manner, with the use of the multi-tone mask as the resist mask, an additional resist mask is not necessary. Therefore, steps can be simplified.

Next, the exposed conductive layers 104a′ and 104b′ are etched away with the use of the resist masks 171a′ and 171c′, whereby the conductive layer 104a and the conductive layer 104b are formed (see FIG. 8B). In that case, the conductive layer 104a′ formed over the conductive layer 102a which functions as the electrode 132 and the conductive layer 104b′ provided in a region, which is provided in the pixel portion, of the wiring 124 are removed.

As a result, the electrode 132 is formed using the conductive layer 102a having a light-transmitting property; and the wiring 122 is formed using a layered structure of the conductive layer 102a having a light-transmitting property and the conductive layer 104a whose resistance is lower than that of the conductive layer 102a.

In this manner, since the conductive layer 102a which functions as the electrode 132 is formed using the material having a light-transmitting property, the aperture ratio of the pixel portion can be increased. In addition, by formation of a conductive layer which functions as the wiring 122 using the conductive layer for forming the electrode 132 (here, the conductive layer 102a) and the conductive layer 104a formed using a metal material whose resistivity is lower than that of the conductive layer 102a, the wiring resistance can be suppressed and distortion of waveforms can be reduced. As a result, low power consumption can be achieved. In addition, since a conductive layer having a light-shielding property (here, the conductive layer 104a) is used for the wiring 122, a region between adjacent pixels can be shielded from light. Therefore, a black matrix can be eliminated. However, this embodiment is not limited to this example.

In addition, with the use of a multi-tone mask, the surface areas of the conductive layer 102a and the conductive layer 104a which are to be the wiring 122 are different from each other. In other words, the surface area of the conductive layer 102a is larger than that of the conductive layer 104a. Similarly, the surface area of the conductive layer 102b is larger than that of the conductive layer 104b.

Next, after the insulating layer 106 is formed so as to cover the conductive layers 102a, the conductive layer 102b, the conductive layer 104a, and the conductive layer 104b, the conductive film 108 and the conductive film 110 are sequentially formed and stacked over the insulating layer 106 (see FIG. 8C).

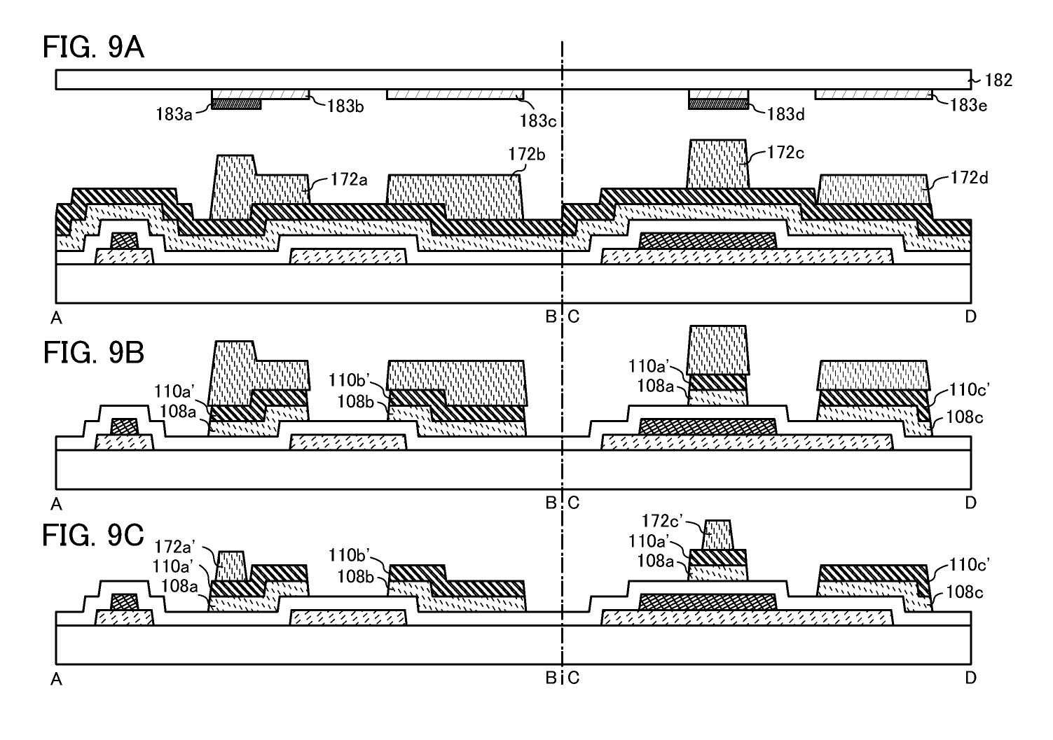

Next, resist masks 172a to 172d are formed over the conductive film 110 (see FIG. 9A).

The resist masks 172a to 172d can be formed to have regions with different thicknesses by using a multi-tone mask.

FIG. 9A shows the case where a half-tone mask is used as a multi-tone mask. The half-tone mask includes a substrate 182 which transmits light, semi-light-transmitting layers 183a and 183d, and light-shielding layers 183b, 183c, and 183e provided on the substrate 182. Therefore, a resist mask 172c which is thick, resist masks 172b and 172d which are thin, and a resist mask 172a which includes a thick portion and a thin portion are formed over the conductive film 110.

Next, with the use of the resist masks 172a to 172d, unnecessary portions of the conductive films 108 and 110 are etched away, whereby conductive layers 108a to 108c and conductive layers 110a′ to 110c′ are formed (see FIG. 9B).

Next, ashing with an oxygen plasma is performed on the resist masks 172a to 172d. After the ashing with the oxygen plasma on the resist masks 172a to 172d, the resist masks 172b and 172d are removed and the conductive layers 110b′ and 110c′ are exposed. In addition, the resist masks 172a and 172c diminish and remain as resist masks 172a′ and 172c′ (see FIG. 9C). In this manner, with the use of the multi-tone mask as the resist mask, an additional resist mask is not necessary. Therefore, steps can be simplified.

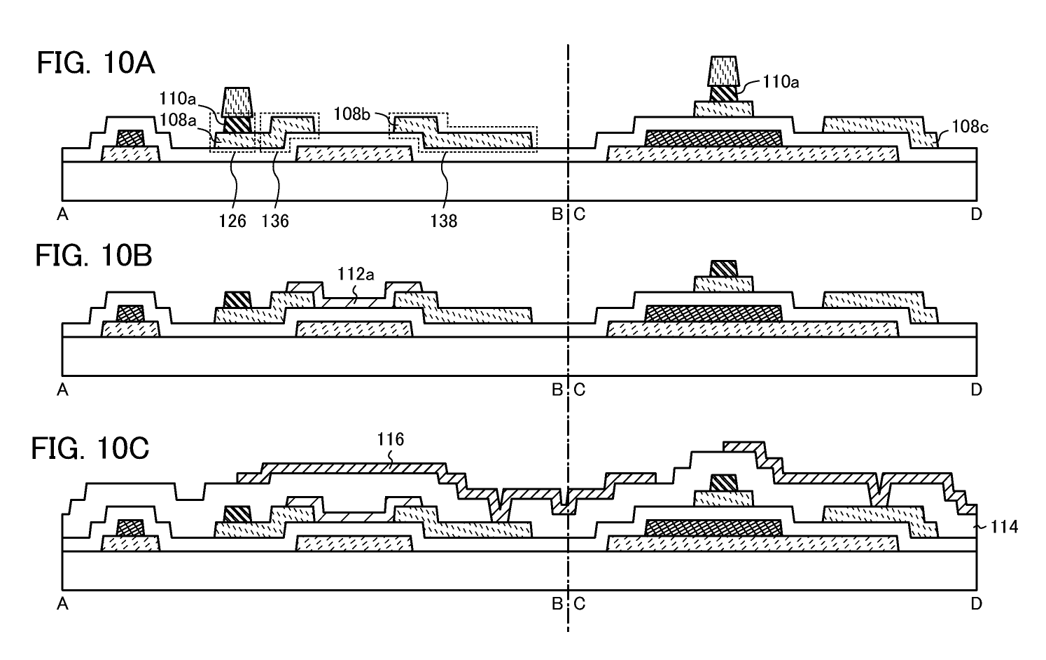

Next, the conductive layers 110b′ and 110c′ and part of the conductive layer 110a′ are etched away with the use of the resist masks 172a′ and 172c′, whereby the conductive layer 110a is formed (see FIG. 10A). In that case, part of the conductive layer 110a′ formed over the conductive layer 108a, the conductive layer 110b′ formed over the conductive layer 108b, and the conductive layer 110c′ formed over the conductive layer 108c are removed.

As a result, the electrode 136 is formed using the conductive layer 108a having a light-transmitting property, and the wiring 126 is formed using a layered structure of the conductive layer 108a having a light-transmitting property and the conductive layer 110a whose resistance is lower than that of the conductive layer 108a. In addition, the electrode 138 is formed using the conductive layer 108b having a light-transmitting property.

In this manner, since the conductive layer 108a, which functions as the electrode 136, and the conductive layer 108b, which functions as the electrode 138, are formed using the material having a light-transmitting property, the aperture ratio of the pixel portion can be increased. In addition, by formation of a conductive layer which functions as the wiring 126 using the conductive layer for forming the electrode 136 (here, the conductive layer 108a) and the conductive layer 110a formed using a metal material whose resistivity is lower than that of the conductive layer 108a, the wiring resistance can be reduced and distortion of waveforms can be reduced. As a result, low power consumption can be achieved. In addition, since the conductive layer having a light-shielding property (here, the conductive layer 110a) is used for the wiring 126, a region between adjacent pixels can be shielded from light.

Next, after an oxide semiconductor film is formed so as to cover the conductive layers 108a and 108b, the insulating layer 106, and the like, the oxide semiconductor film is etched, whereby the semiconductor layer 112a in an island shape is formed (see FIG. 10B).

Next, after the insulating layer 114 is formed so as to cover the semiconductor layer 112a, the wiring 126, the electrode 136, the electrode 138, and the conductive layer 108c, the conductive layer 116 is formed over the insulating layer 114 (see FIG. 10C). The conductive layer 116 is formed so as to be electrically connected to the conductive layer 108c.

According to the above-described steps, a semiconductor device can be manufactured. With the use of a multi-tone mask, a mask with three levels of light exposure, a mask having an exposed portion, a half-exposed portion, and an unexposed portion can be formed; one-time exposure and development process allows a resist mask with regions of plural thicknesses (typically, two kinds of thicknesses) to be formed. Therefore, with the use of a multi-tone mask, the number of photomasks can be reduced.

Note that although the case is described in which a multi-tone mask is used in both the step of forming a gate wiring and the step of forming the source wiring in this embodiment, a multi-tone mask may be used in either one step.

### Embodiment 3

In this embodiment, a semiconductor device which is different from that in Embodiment 1 above will be described with reference to drawings. Note that the structure of the semiconductor device shown below has many portions which are common to those in FIG. 1 and FIGS. 2A and 2B. Thus, description of the common portions is omitted, and differences are described below.

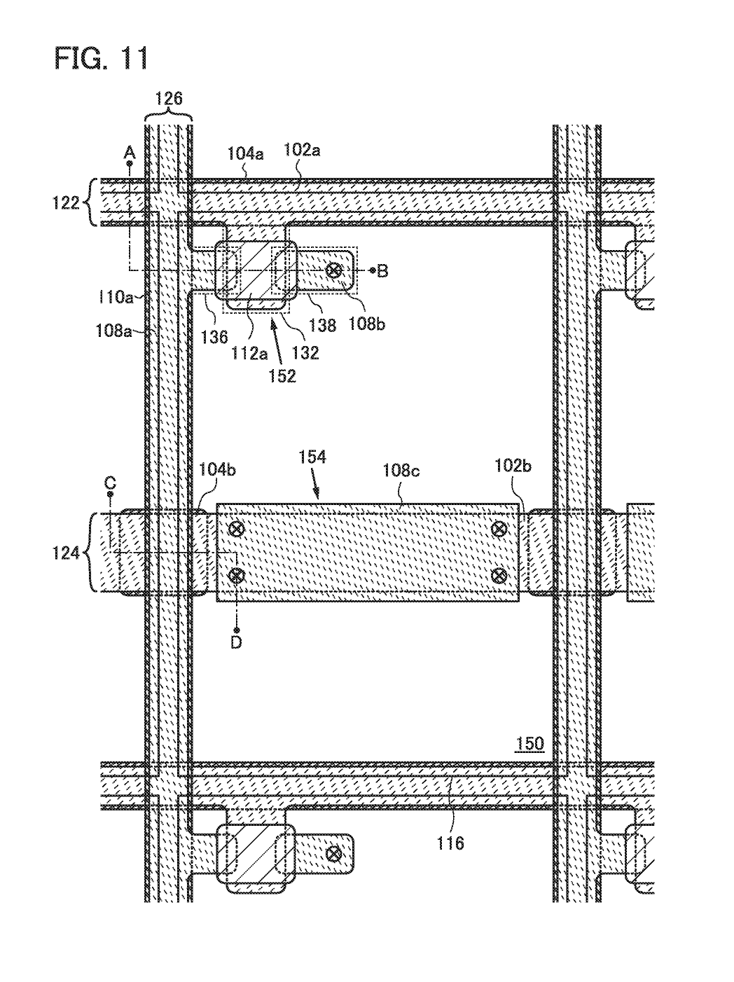

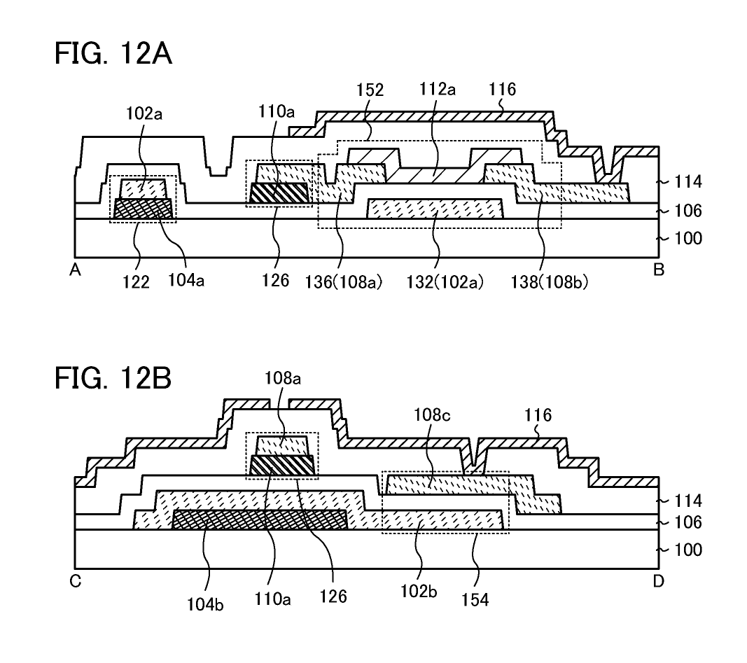

FIG. 11 and FIGS. 12A and 12B illustrate an example of another structure of the semiconductor device described in Embodiment 1. FIG. 11 shows a top view. FIG. 12A corresponds to a cross section of FIG. 11 along line A-B and FIG. 12B corresponds to a cross section of FIG. 11 along line C-D.

FIG. 11 and FIGS. 12A and 12B show the case where the gate wiring 120 of the semiconductor device in FIG. 1 and FIGS. 2A and 2B is formed by stacking the conductive layer 102a having a light-transmitting property over the conductive layer 104a and the wiring 126 is formed by stacking the conductive layer 108a having a light-transmitting property over the conductive film 110. That is, the order of stacking the conductive layers in each of the layered structures used for the gate wiring 120 and the wiring 126 in FIG. 11 and FIGS. 12A and 12B is opposite from that shown in FIG. 1 and FIGS. 2A and 2B.

In the structure shown in FIG. 11 and FIGS. 12A and 12B, the electrode 132, which is electrically connected to the gate wiring 120, is formed using the conductive layer 102a having a light-transmitting property and the electrode 136, which is electrically connected to the wiring 126, is formed using the conductive layer 108a having a light-transmitting property.

Note that other than the structure shown in FIG. 11 and FIGS. 12A and 12B, a structure in which the order of stacking the conductive layers used for either one of the wiring 122 and the wiring 126 may be opposite from that shown in FIG. 1 and FIGS. 2A and 2B.

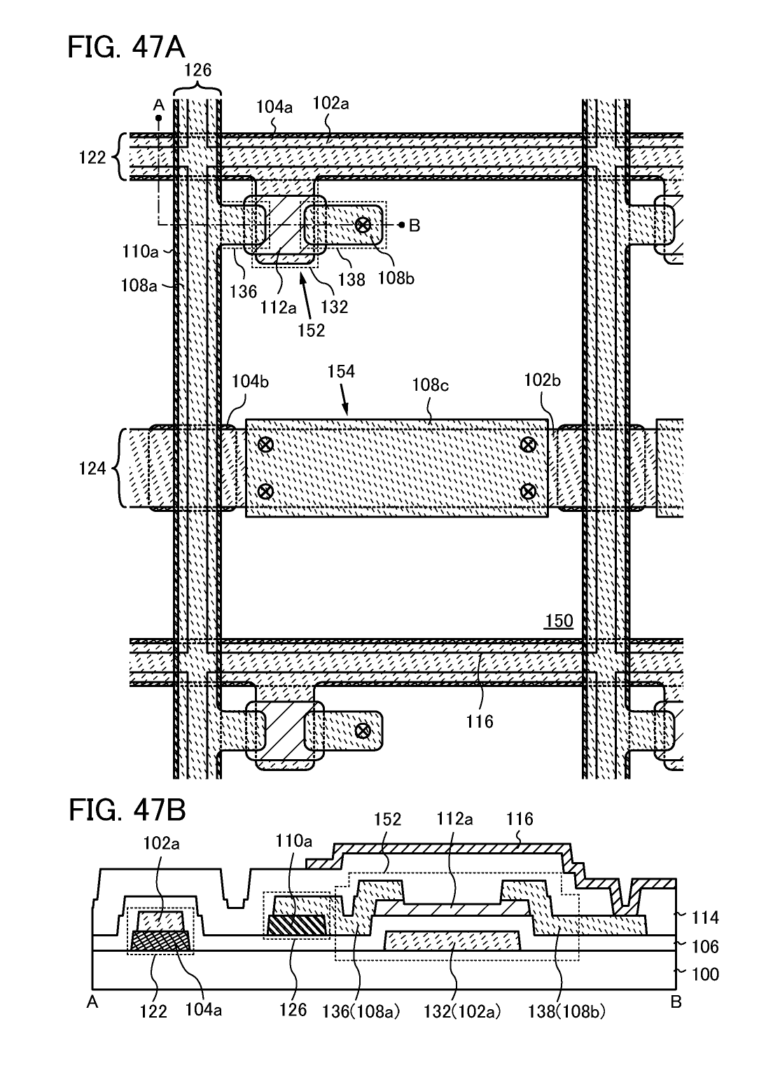

In addition, although the structure in which the semiconductor layer 112a is provided over the electrode 136 and the electrode 138 (a bottom contact structure) is shown in FIG. 11 and FIGS. 12A and 12B, this embodiment is not limited to this example. For example, a structure in which the electrode 136 and the electrode 138 are provided over the semiconductor layer 112a (a channel etch structure) may be employed (see FIGS. 47A and 47B). Note that FIG. 47A is a top view and FIG. 47B corresponds to a cross section of FIG. 47A along line A-B.

Alternatively, a structure in which an insulating layer 127 which functions as a channel protection film is provided over the semiconductor layer 112a in FIGS. 47A and 47B (a channel protection structure) may be employed (see FIG. 46B).

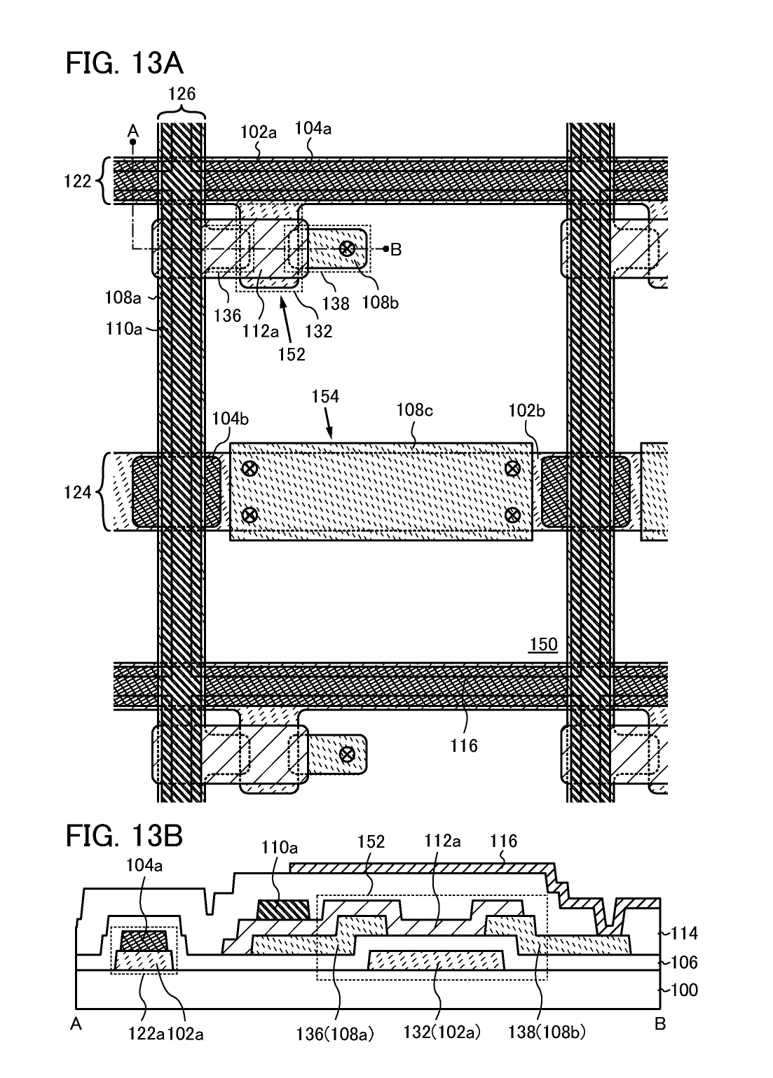

Next, FIGS. 13A and 13B illustrate an example of another structure of the semiconductor device described in Embodiment 1. FIG. 13A is a top view and FIG. 13B corresponds to a cross section of FIG. 13A along line A-B.

FIGS. 13A and 13B show the semiconductor device in which the semiconductor layer 112a is provided between the conductive layer 108a and the conductive layer 110a which are to be the wiring 126 in the semiconductor device shown in FIG. 1 and FIGS. 2A and 2B. That is, after the conductive layer 108a is formed, the semiconductor layer 112a is formed before the formation of the conductive layer 110a.

As shown in FIGS. 13A and 13B, by the formation of the semiconductor layer 112a between the conductive layer 108a and the conductive layer 110a, an area where the electrode 136 and the wiring 126 are in contact with the semiconductor layer 112a is increased, whereby contact resistance can be decreased.

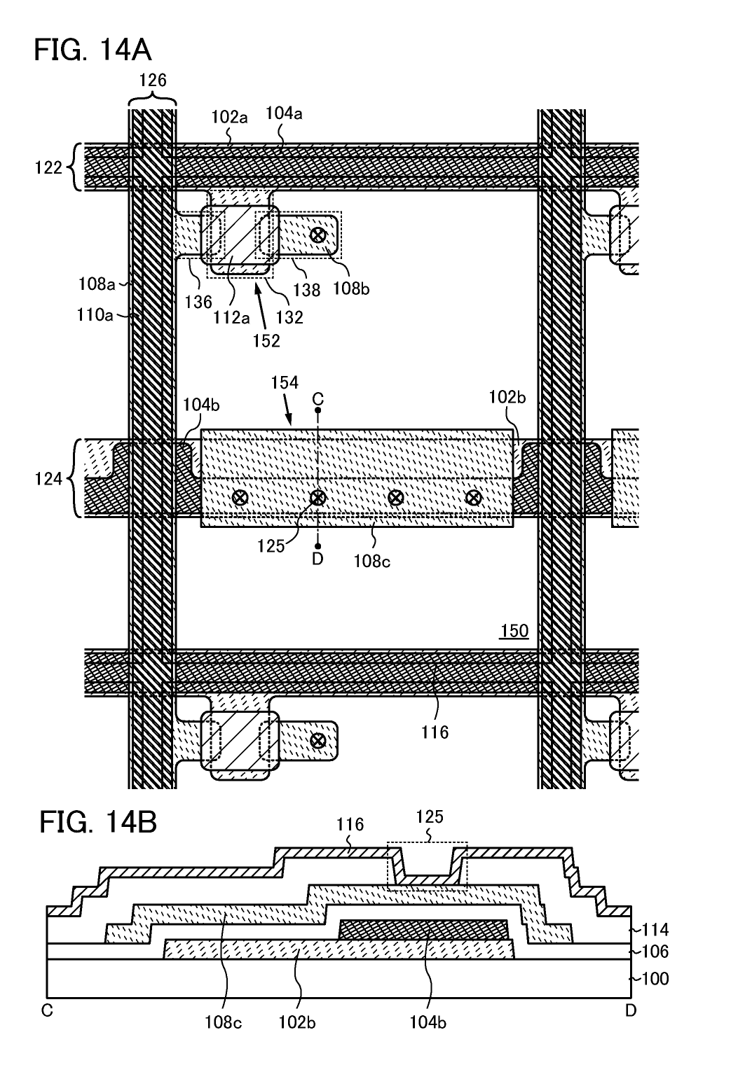

Next, FIGS. 14A and 14B illustrate an example of another structure of the semiconductor device described in Embodiment 1. FIG. 14A is a top view and FIG. 14B corresponds to a cross section of FIG. 14A along line C-D.

The semiconductor device shown in FIGS. 14A and 14B has the following structure; the conductive layer having a light-shielding property (here, the conductive layer 104b) is provided in a region below a contact hole 125 which is formed in the case where the conductive layer 108c serving as an electrode of the storage capacitor portion 154 is connected to the conductive layer 116 in the wiring 124. That is, FIGS. 14A and 14B show the structure in which a layered structure of the conductive layer 102b having a light-transmitting property and the conductive layer 104b having a light-shielding property whose resistance is lower than that of the conductive layer 102b is provided as the wiring 124 also in a region where the pixel portion 150 is provided in FIG. 1 and FIGS. 2A and 2B.

In general, in the case where the conductive layer 108c is electrically connected to the conductive layer 116 through the contact hole 125, a concave portion is formed on a surface of the conductive layer 116 because of the contact hole 125. As a result, the alignment of liquid crystal molecules provided over the concave portion of the conductive layer 116 is disordered, whereby light leaks in some cases.

In order to deal with this, a film having a light-shielding property is selectively formed below the contact hole 125 as shown in FIGS. 14A and 14B. Therefore, light leakage due to the concave portion on the surface of the conductive layer 116 can be reduced. In addition, when the conductive layer 104b whose resistance is lower than that of the conductive layer 102b is used as the film having a light-shielding property, the resistance of the wiring 124 can be reduced. Further, by setting of the positions of the contact holes 125 on only one side of the wiring 124 and formation of the conductive layer 104b on the one side of the wiring 124, the aperture ratio of the pixel portion 150 can be increased.

Note that the shape of the conductive layer 104b is not limited to the shape shown in FIG. 14A as long as the conductive layer 104b is formed below the contact hole 125. If the wiring resistance of the wiring 124 as well as light leakage is desired to be reduced, the conductive layer 104b may be extended in a direction parallel to the wiring 124 as shown in FIG. 14A. In that case, as described above, by setting of the positions of the contact holes 125 on only one side of the wiring 124 and formation of the conductive layer 104b on the one side of the wiring 124, the aperture ratio of the pixel portion 150 can be increased.

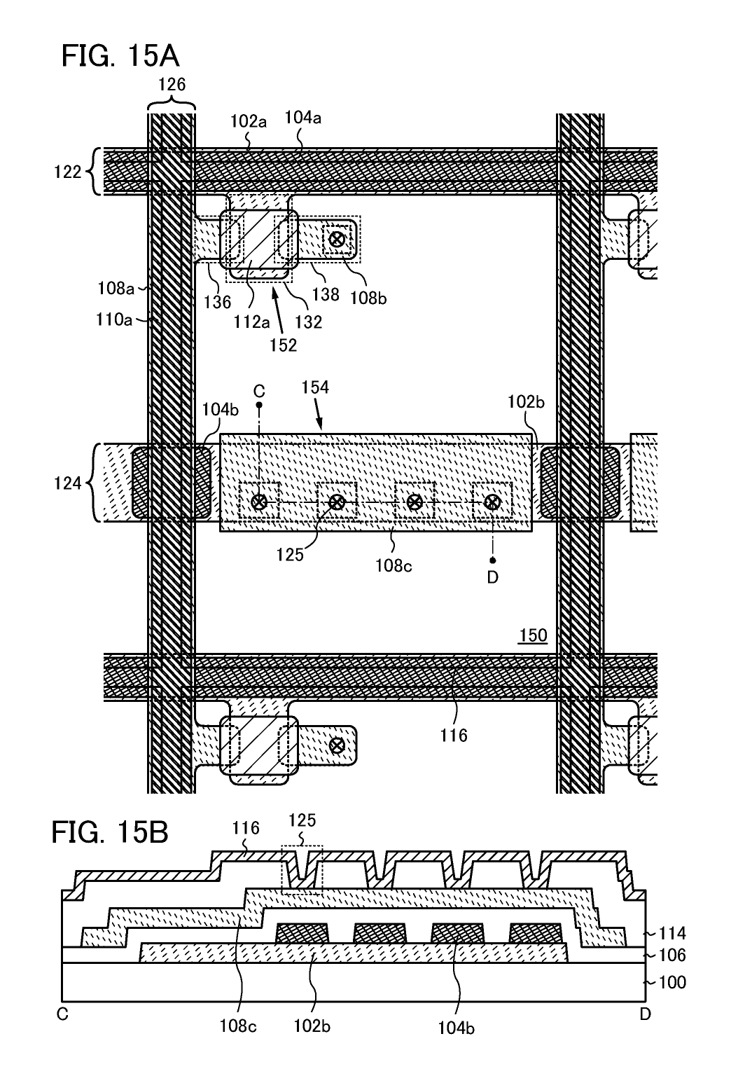

In addition, if the aperture ratio of the pixel portion 150 is desired to be further increased while the light leakage is reduced, the conductive layer 104b is not provided in a direction parallel to the wiring 124 to be electrically connected to the wiring 124; instead, island-shaped conductive layers 104b may be provided in respective regions which overlap with the respective contact holes 125 (see FIGS. 15A and 15B). Note that FIG. 15A is a top view and FIG. 15B corresponds to a cross section of FIG. 15A along line C-D.

In addition, a light-shielding film may be provided below a contact hole formed in a region other than the wiring 124 (a region where the conductive layer 108b is connected to the conductive layer 116) while the light-shielding films are provided below the contact holes 125 formed in the wiring 124 as shown in FIGS. 15A and 15B.

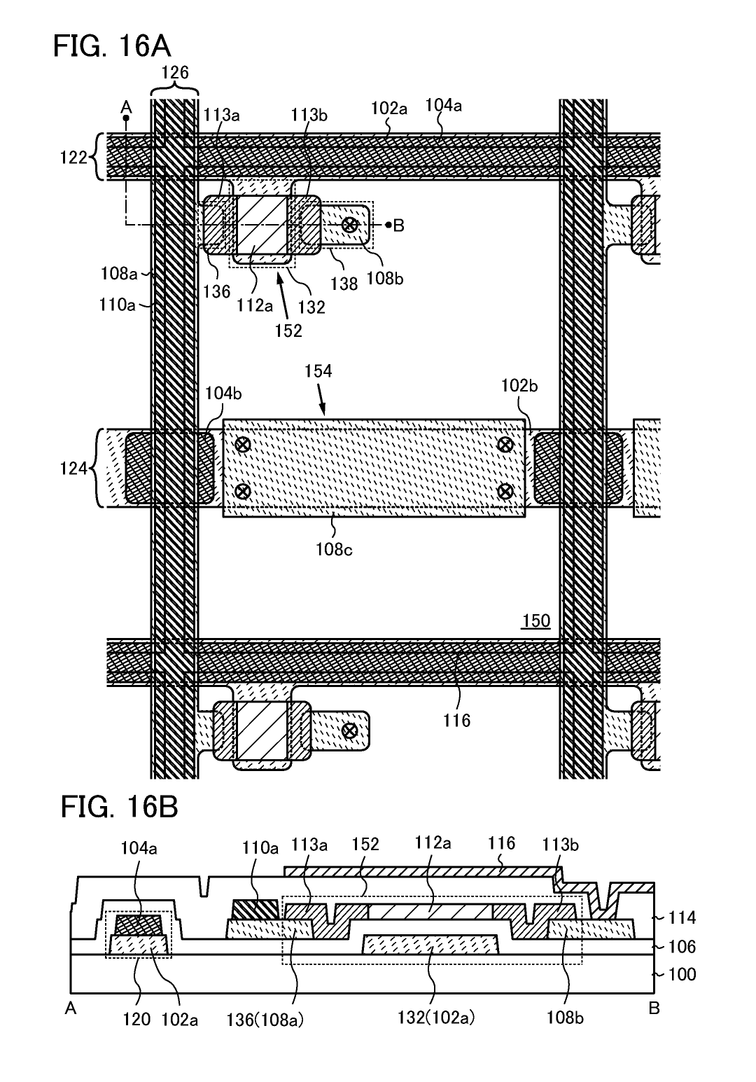

FIGS. 16A and 16B illustrate an example of another structure of the semiconductor device described in Embodiment 1. FIG. 16A is a top view and FIG. 16B corresponds to a cross section of FIG. 16A along line A-B.

The semiconductor device shown in FIGS. 16A and 16B has a structure in which regions with high conductivity (n+regions 113a and 113b) are provided in parts of the semiconductor layer 112a and the electrode 136, the electrode 138, and the electrode 132 are provided so as not to overlap with each other. The n+regions 113a and 113b can be provided in a region which is connected to the electrode 136 and a region which is connected to the electrode 138, respectively in the semiconductor layer 112a. Note that the n+regions 113a and 113b may be provided so as to or so as not to overlap with the electrode 132.

The n+regions 113a and 113b can be formed by selective addition of hydrogen to the semiconductor layer 112a. Hydrogen may be added to a portion, whose conductivity is desired to be increased, of the semiconductor layer 112a.

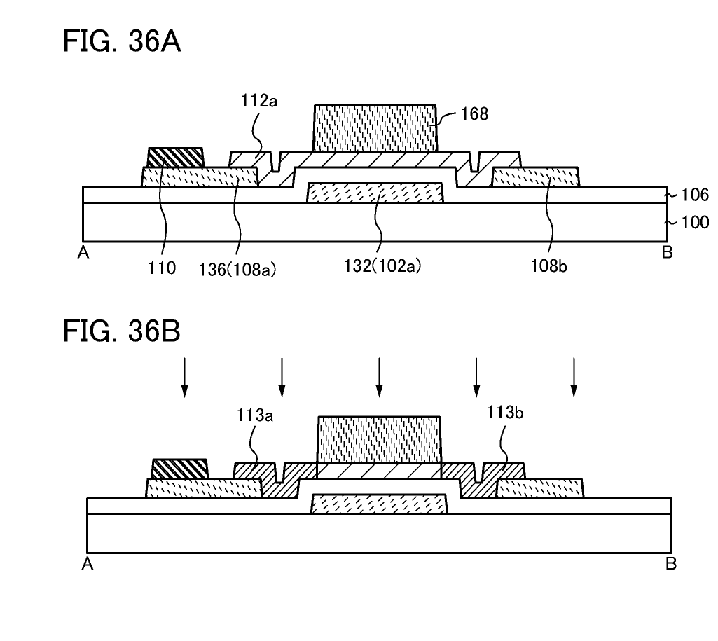

For example, the n+regions 113a and 113b can be formed in the semiconductor layer 112a as follows: the semiconductor layer 112a is formed using an oxide semiconductor containing In, M, or Zn, or the like; a resist mask 168 is formed over part of the semiconductor layer 112a (see FIG. 36A); and hydrogen ions are added thereto (see FIG. 36B).

In this manner, by formation of the electrode 136, the electrode 138, and the electrode 132 so as not to overlap with each other, the parasitic capacitance generated between the electrode 136 or the electrode 132 and between the electrode 138 and the electrode 132 can be suppressed.

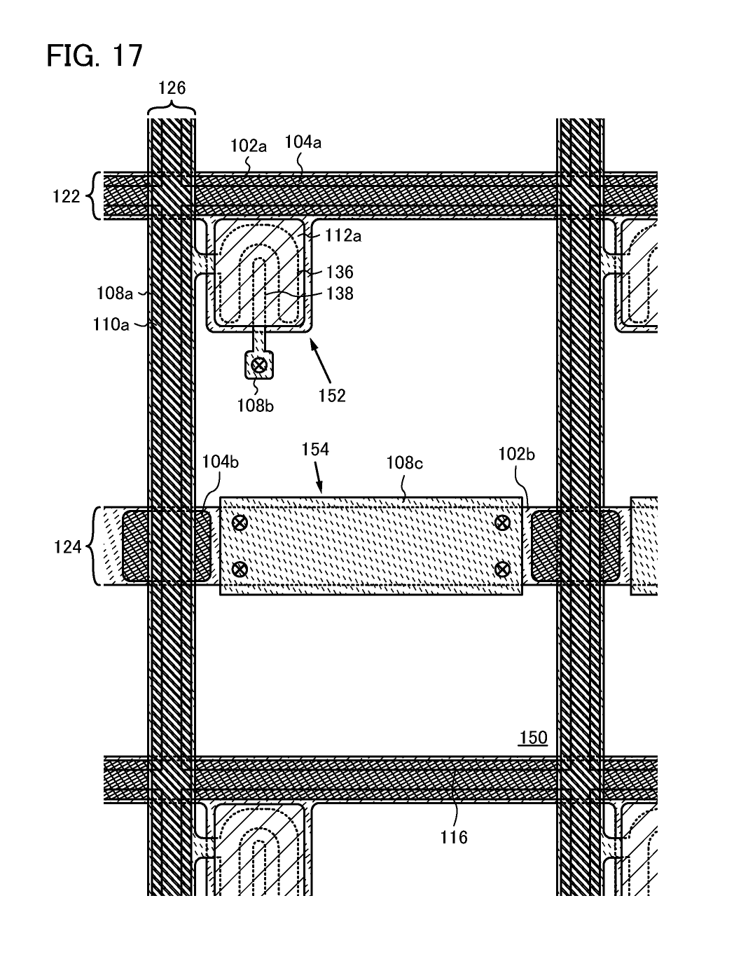

Note that although the above-described structure illustrates the case where a top surface of a channel formation region formed between a source and a drain of the transistor 152 has a parallel form, this embodiment is not limited to this example. Other than above, as shown in FIG. 17, a transistor whose channel formation region has a C-shaped (U-shaped) top view may be employed. In that case, the conductive layer 108a serving as the electrode 136 is formed into a C-shape or U-shape, and the conductive layer 108a is provided so as to surround the conductive layer 108b serving as the electrode 138. When such a structure is employed, the channel width of the transistor 152 can be increased.

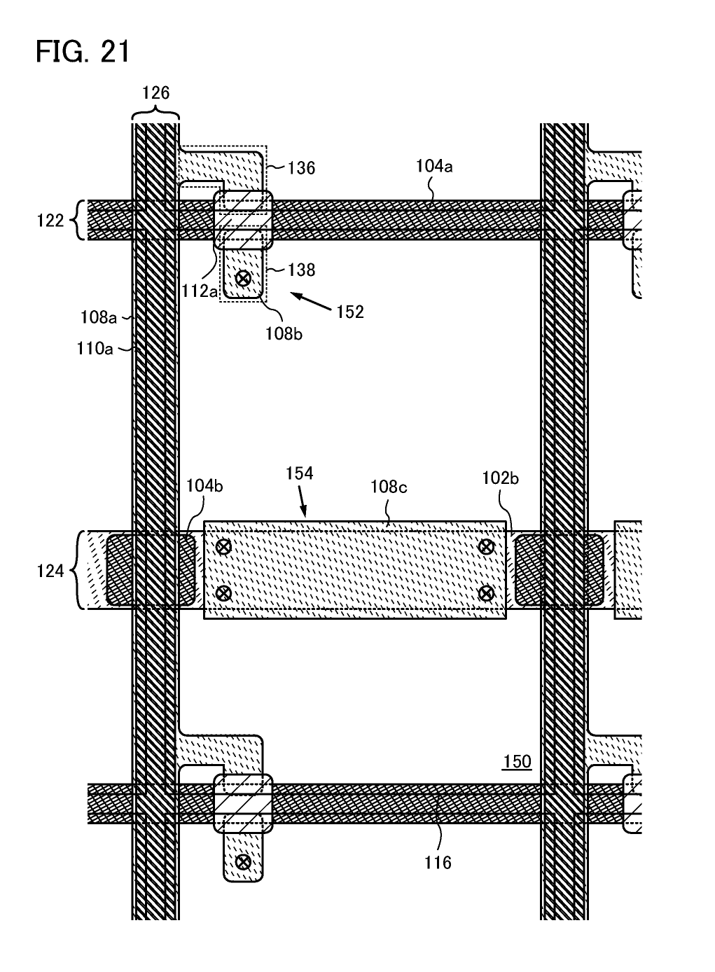

In addition, although the above-described structure illustrates the case where the semiconductor layer 112a is provided over the electrode 132 electrically connected to the wiring 122, this embodiment is not limited to this example. Other than above, as shown in FIG. 21, the semiconductor layer 112a may be provided over the wiring 122. In that case, the wiring 122 also functions as a gate electrode. In addition, the wiring 122 can be formed using the conductive layer 104a with low resistance. It is needless to say that the wiring 122 may be formed using a layered structure of the conductive layer 102a having a light-transmitting property and the conductive layer 104a. In addition, by formation of the conductive layer 104a using a conductive layer having a light-shielding property, light irradiation on the semiconductor layer 112a which is to be a channel formation region can be suppressed. Such a structure is effective when a material whose characteristics are adversely influenced by light is used for the semiconductor layer which forms a channel.

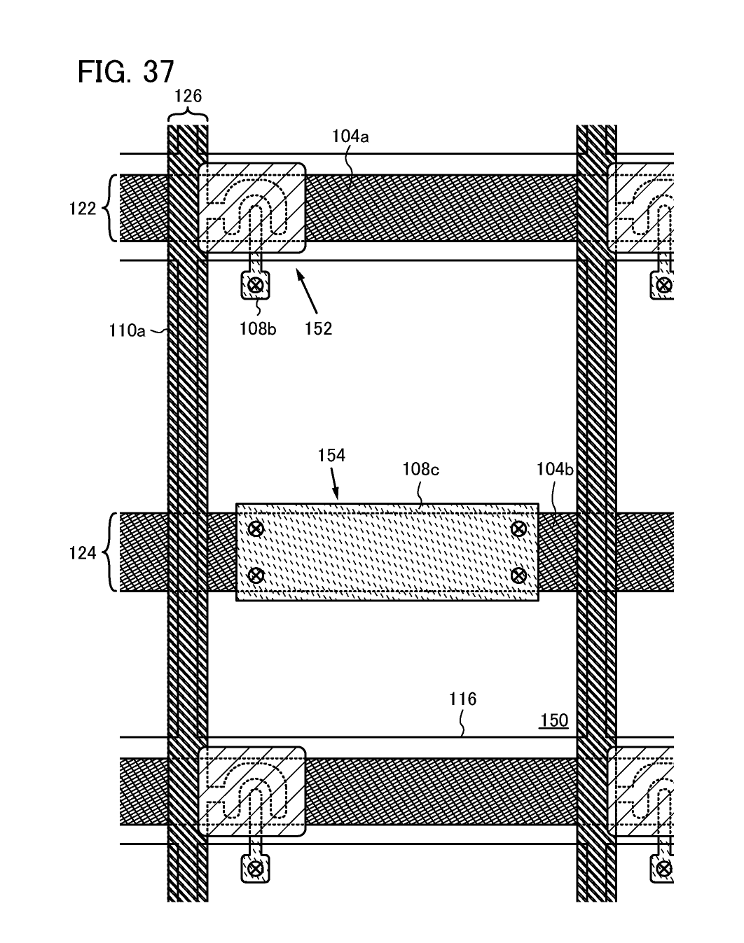

Alternatively, as shown in FIG. 37, the wiring 122 may be formed using only the conductive layer 104a. In addition, the wiring 126 may be formed using only the conductive layer 110a. Furthermore, the wiring 124 may be formed using only the conductive layer 104b.

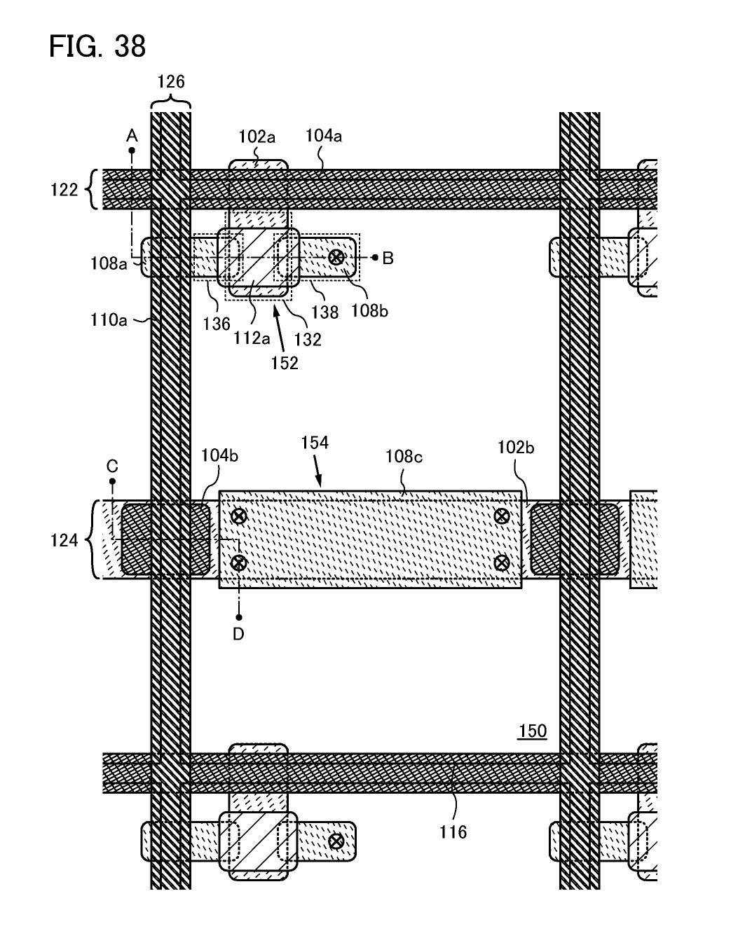

In addition as shown in FIG. 38, the conductive layer 108a may be selectively provided for part of the wiring 122 (part which is used as the electrode 132 of the transistor 152). Similarly, the conductive layer 110a may be selectively provided for part of the wiring 126 (part which is used as the electrode 136 of the transistor 152).

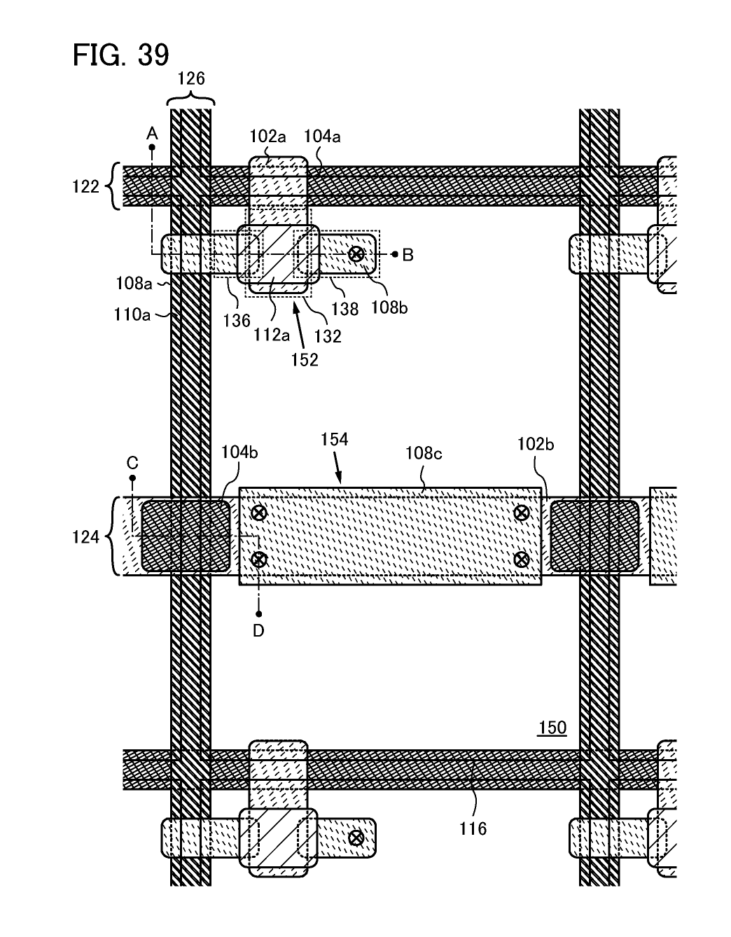

Note that although FIG. 38 illustrates the case where the conductive layer 102a is provided below the conductive layer 104a, the conductive layer 102a may be provided over the conductive layer 104a (see FIG. 39). Similarly, the conductive layer 108a may be provided over the conductive layer 110a (see FIG. 39).

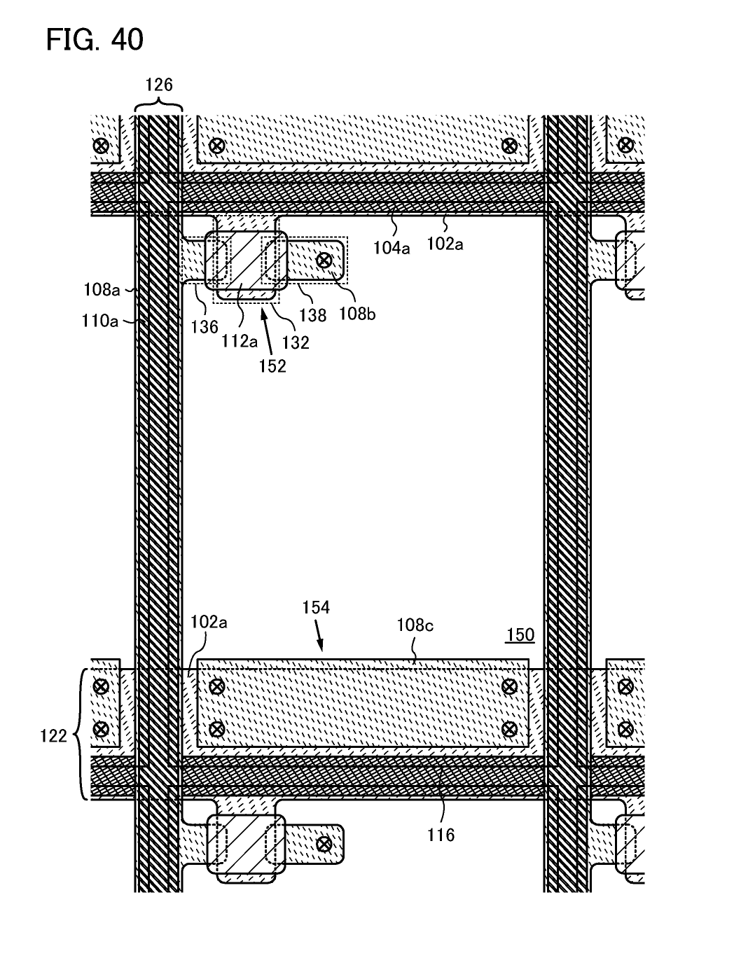

In addition, although the case where the storage capacitor portion 154 is formed using the wiring 124 is shown in the above-described structure, this embodiment is not limited to this example. As shown in FIG. 40, a structure in which the wiring 124 is not provided and the conductive layer 108c and the conductive layer 102a which is included in the wiring 122 of an adjacent pixel are used as an electrode of the storage capacitor portion 154 may be employed.

In addition, although the structure in which the semiconductor layer 112a is provided over the electrode 136 and the electrode 138 (bottom contact structure) is shown in FIGS. 13A and 13B, FIGS. 14A and 14B, FIGS. 15A and 15B, FIGS. 16A and 16B, FIG. 17, FIG. 37, FIG. 38, FIG. 39, and FIG. 40, this embodiment is not limited to this example. As shown in FIGS. 45A and 45B, FIGS. 46A and 46B, and FIGS. 47A and 47B, a structure in which the electrode 136 and the electrode 138 are provided over the semiconductor layer 112a (a channel etched structure) may be employed, or a structure in which the insulating layer 127 serving as a channel protection film is formed over the semiconductor layer 112a (a channel protection structure) may be employed.

### Embodiment 4

In this embodiment, a semiconductor device which is different from Embodiments 1 and 2 will be described with reference to drawings. Specifically, the case where a plurality of transistors is provided in one pixel portion is described. Note that many portions are common to the structure of the semiconductor device below and the semiconductor device in FIG. 1 and FIGS. 2A and 2B. Therefore, description of common portions is omitted and different points will be described.

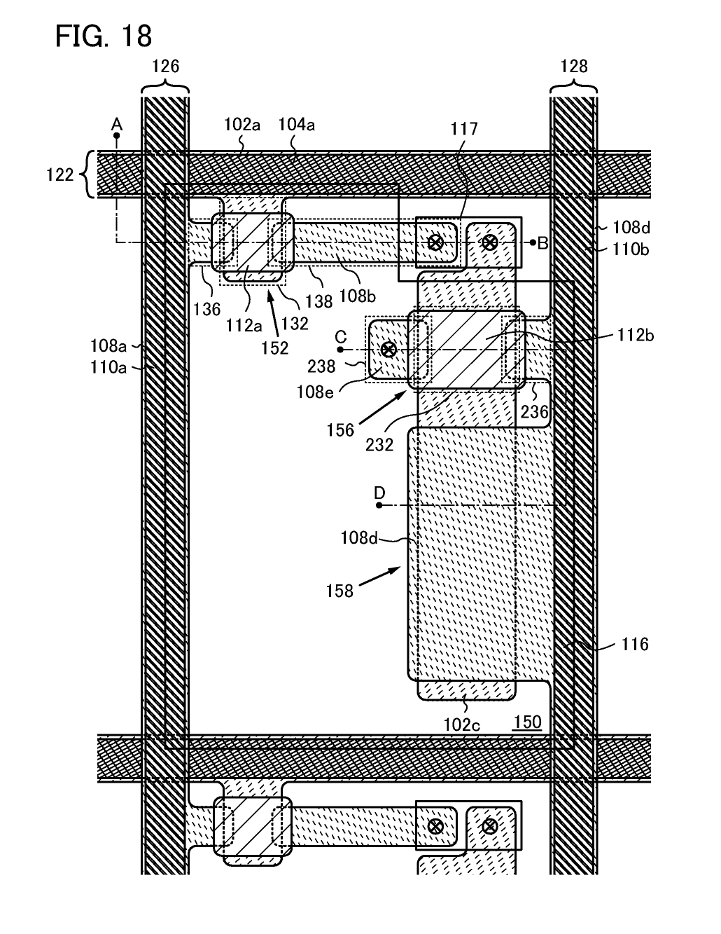

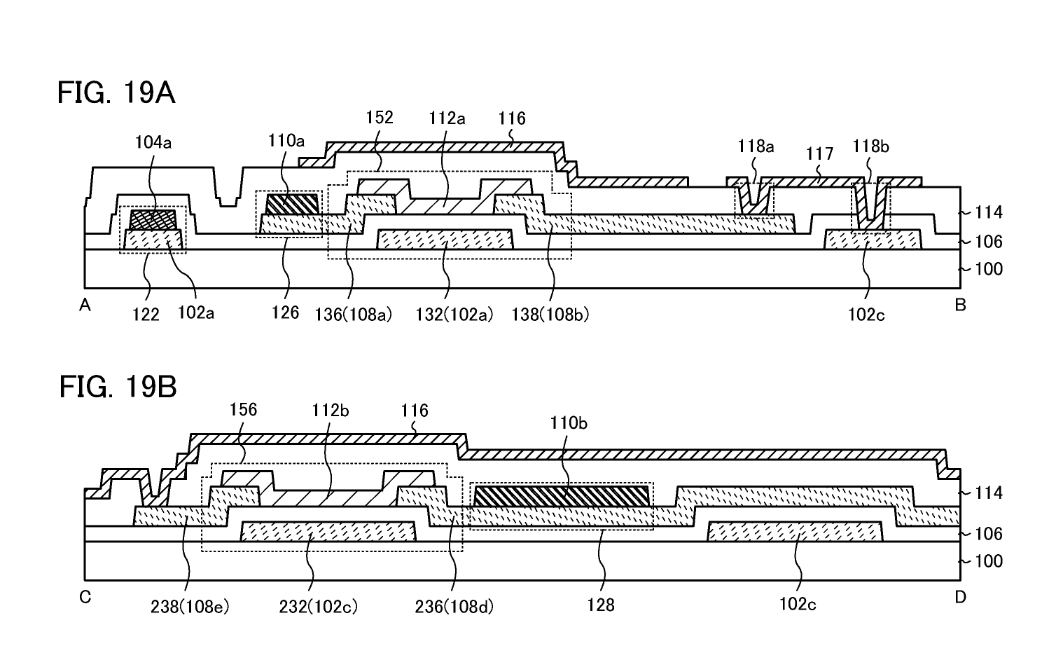

An example of a structure of a semiconductor device described in this embodiment is shown in FIG. 18 and FIGS. 19A and 19B. FIG. 18 shows a top view. FIG. 19A corresponds to a cross section of FIG. 18 along line A-B and FIG. 19B corresponds to a cross section of FIG. 18 along line C-D.

The semiconductor device shown in FIG. 18 and FIGS. 19A and 19B includes the pixel portion 150 provided with the transistor 152 for switching, a transistor 156 for driving, and a storage capacitor portion 158, the wiring 122, the wiring 126, and a wiring 128. The structure shown in FIG. 18 and FIGS. 19A and 19B can be applied to a pixel portion of an EL display device, for example.

The transistor 156 includes an electrode 232 provided over the substrate 100, the insulating layer 106 provided over the electrode 232, an electrode 236 and an electrode 238 provided over the insulating layer 106, and a semiconductor layer 112b provided over the insulating layer 106 so as to overlap with the electrode 232 and over the electrode 236 and the electrode 238.

Note that the electrode 232 can function as a gate electrode. The electrode 236 and the electrode 238 can each function as a source electrode or drain electrode. The semiconductor layer 112b can be formed using an oxide semiconductor. The wiring 128 can function as a power supply line. However, this embodiment is not limited to this example.

The electrode 232 is formed using a conductive layer 102c having a light-transmitting property and is electrically connected to the electrode 138 (the conductive layer 108b) of the transistor 152. The conductive layer 108b and the conductive layer 102c can be electrically connected to each other through a conductive layer 117.

In addition, the conductive layer 117 and the conductive layer 116 can be formed in the same step. That is, after the insulating layer 114 is formed, a contact hole 118a which reaches the conductive layer 108b and a contact hole 118b which reaches the conductive layer 102c are formed; then, the conductive layer 116 and the conductive layer 117 are formed over the insulating layer 114. The contact hole 118a and the contact hole 118b can be formed in the same step (the same etching process).

The conductive layer 102c and the conductive layer 102a can be formed in the same process.

The semiconductor layer 112b and the semiconductor layer 112a can be formed in the same process.

The electrode 236 is formed using a conductive layer 108d having a light-transmitting property and is electrically connected to the wiring 128. The wiring 128 is formed using a layered structure of a conductive layer 108d and the conductive layer 110b. In addition, the conductive layer 108d included in the electrode 236 and the conductive layer 108d included in the wiring 128 are formed in the same island.

Note that although FIG. 18 and FIGS. 19A and 19B show the case where the layered structure in which the conductive layer 110b is stacked over the conductive layer 108d is used as the wiring 128, the conductive layer 108d may be stacked over the conductive layer 110b.

In addition, the electrode 238 is formed using a conductive layer 108e having a light-transmitting property and is electrically connected to the conductive layer 116.

The conductive layer 108d, the conductive layer 108e, the conductive layer 108a and the conductive layer 108b can be formed in the same step. In addition, the conductive layer 110b and the conductive layer 110a can be formed in the same step.

A storage capacitor portion 158 includes the insulating layer 106 which is used as a dielectric, and the conductive layer 102c having a light-transmitting property and the conductive layer 108d having a light-transmitting property which are used as electrodes. In addition, the conductive layer 102c is electrically connected to the electrode 138 of the transistor 152.

In this manner, since the transistor 152, the transistor 156, and the storage capacitor portion 158 are each formed using the material having a light-transmitting property, light can pass through regions where the transistor 152 and the transistor 156 are formed and a region where the storage capacitor portion 158 is formed, whereby the aperture ratio of the pixel portion 150 can be increased. In addition, since part of each of the wiring 122, the wiring 126, and the wiring 128 is formed using a conductive layer of a metal material having low resistivity, wiring resistance can be reduced and power consumption can be reduced.

In addition, by formation of the conductive layer 104a which is included in the gate wiring, the conductive layer 110a which is included in the source wiring, and the conductive layer 110b which is included in the wiring 128 with the use of a metal material having a light-shielding property, wiring resistance can be reduced and a region between adjacent pixel portions can be shielded from light. In other words, with the gate wiring provided in a row direction and the source wiring and the wiring 128 provided in a column direction, the space between the pixels can be shielded from light without using a black matrix.

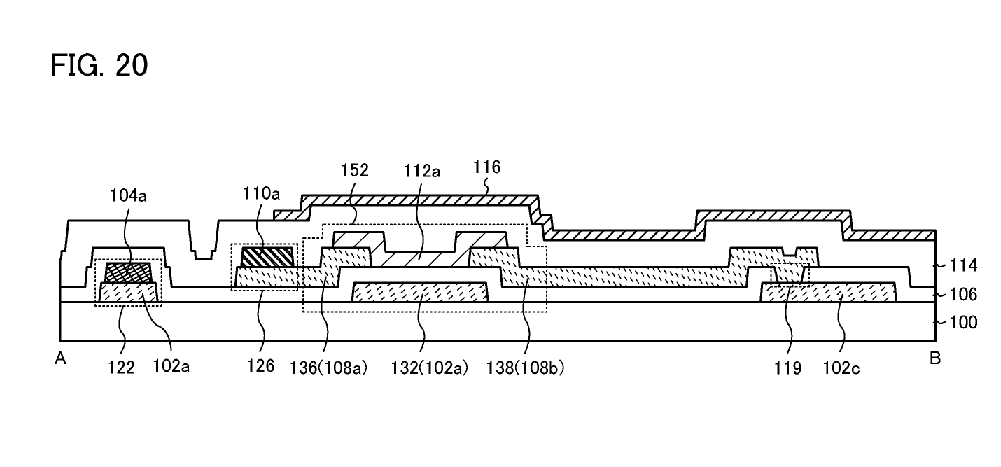

Note that although FIG. 18 and FIGS. 19A and 19B show the case where the conductive layer 108b and the conductive layer 102c are electrically connected to each other through the conductive layer 117, this embodiment is not limited to this example. For example, as shown in FIG. 20, the conductive layer 102c and the conductive layer 108b may be electrically connected to each other through a contact hole 119 formed in the insulating layer 106. In that case, the conductive layer 108b may be formed after the contact hole 119 is formed in the insulating layer 106. In the structure shown in FIG. 20, the conductive layer 116 can be provided also over a region where the conductive layer 108b and the conductive layer 102c are connected to each other.

In addition, although this embodiment shows the case where two transistors are provided in the pixel portion 150, this embodiment is not limited to this example. Three or more transistors can be provided in parallel or in series.

Although this embodiment shows the case where a transistor with a bottom contact structure is employed, this embodiment is not limited to this example. A transistor with a channel etch structure or a transistor with a channel protection structure may be employed.

### Embodiment 5

In this embodiment, the case where at least a pixel portion and part of a driving circuit are provided over one substrate using thin film transistors in a display device which is one embodiment of a semiconductor device is described below.

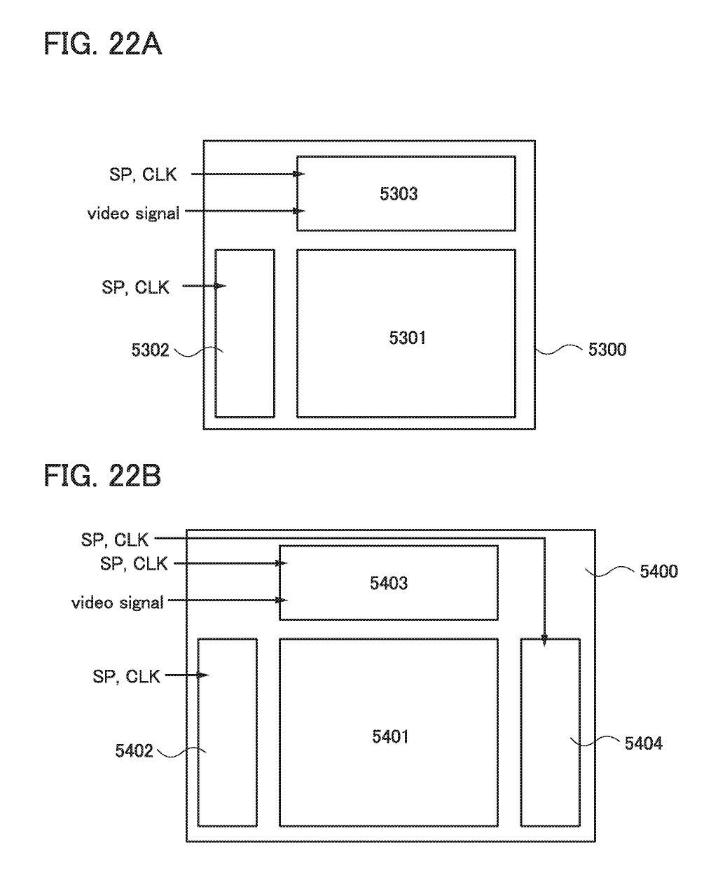

FIG. 22A is an example of a block diagram of an active matrix liquid crystal display device which is an example of display devices. The active matrix liquid crystal display device illustrated in FIG. 22A includes, over a substrate 5300, a pixel portion 5301 having a plurality of pixels each provided with a display element, a scan line driver circuit 5302 that selects a pixel, and a signal line driver circuit 5303 that controls input of a video signal to the selected pixel.

The light-emitting display device illustrated in FIG. 22B includes, over a substrate 5400, a pixel portion 5401 having a plurality of pixels each provided with a display element, a first scan line driver circuit 5402 and a second scan line driver circuit 5404 that select a pixel, and a signal line driver circuit 5403 that controls input of a video signal to the selected pixel.

When the video signal input to a pixel of the light-emitting display device shown in FIG. 22B is a digital signal, a pixel emits light or does not emit light by switching a transistor on/off. Thus, grayscale can be displayed using an area grayscale method or a time grayscale method. An area grayscale method refers to a driving method in which one pixel is divided into a plurality of subpixels and each of the subpixels is driven independently based on a video signal so that grayscale is displayed. Further, a time grayscale method refers to a driving method in which a period during which a pixel emits light is controlled so that grayscale is displayed.

Since the response speed of a light-emitting element is higher than that of a liquid crystal element or the like, the light-emitting element is more suitable for a time grayscale method than the liquid crystal element. In the case of displaying by a time grayscale method, one frame period is divided into a plurality of subframe periods. Then, in accordance with video signals, the light-emitting element in the pixel is brought into a light-emitting state or a non-light-emitting state in each subframe period. By dividing one frame into a plurality of subframes, the total length of time, in which pixels emit light in one frame period, can be controlled with video signals so that gray scales are displayed.

In the light-emitting display device illustrated in FIG. 22B, in the case where two switching TFTs are arranged in one pixel, the first scan line driver circuit 5402 generates a signal which is input to a first scan line serving as a gate wiring of one switching TFT, and the second scan line driver circuit 5404 generates a signal which is input to a second scan line serving as a gate wiring of the other switching TFT; however, one scan line driver circuit may generate both the signal which is input to the first scan line and the signal which is input to the second scan line. In addition, for example, there is a possibility that a plurality of scan lines used for controlling the operation of the switching element are provided in each pixel, depending on the number of the switching TFTs included in one pixel. In this case, one scan line driver circuit may generate all the signals that are input to the plurality of scan lines, or a plurality of scan line driver circuits may generate signals that are input to the plurality of scan lines.

The thin film transistor to be provided in the pixel portion of the liquid crystal display device can be formed according to any of Embodiments 1 and 4. In addition, the thin film transistor described in any of Embodiments 1 to 4 is an n-channel TFT; therefore, part of a driver circuit which can be formed using an n-channel TFT is formed over a substrate over which the thin film transistor of the pixel portion is formed.

Also in the light-emitting display device, part of a driver circuit that can include n-channel TFTs among driver circuits can be formed over a substrate over which the thin film transistors of the pixel portion are formed. Alternatively, the signal line driver circuit and the scan line driver circuit can be formed using only the n-channel TFTs described in Embodiment 1 or 4.

Note that it is not necessary that light is transmitted through a transistor in a protective circuit or a peripheral driver circuit portion such as a gate driver or a source driver. Thus, in a pixel portion, light is transmitted through a transistor and a capacitor, and in the peripheral driver circuit portion, light is not necessarily transmitted through a transistor.

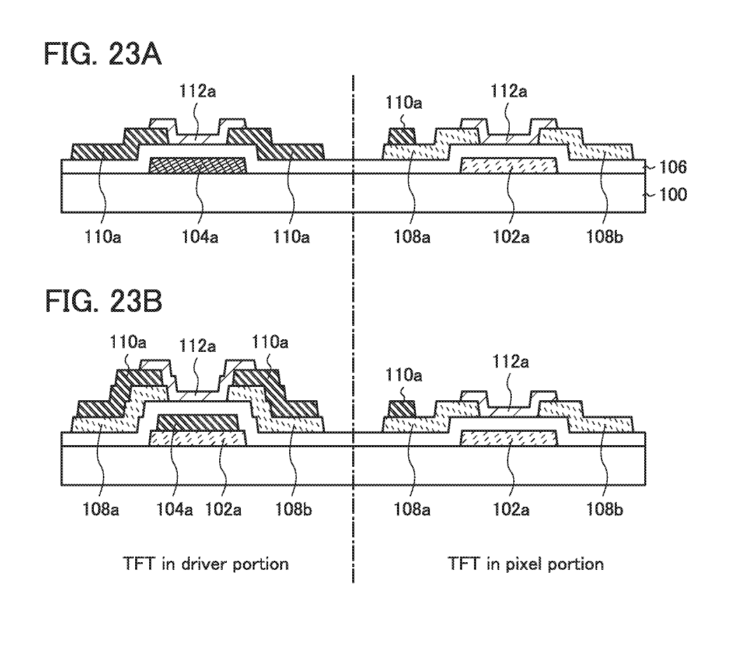

FIG. 23A illustrates thin film transistors of a driver portion and a pixel portion in the case where the thin film transistor is formed without using a multi-tone mask. FIG. 23B illustrates thin film transistors of a driver portion and a pixel portion in the case where the thin film transistor is formed using a multi-tone mask.

In the case where the thin film transistor is formed without using a multi-tone mask, the transistor of the driver portion can be formed in the following manner: a gate electrode is formed using the conductive layer 104a whose conductivity is higher than that of the conductive layer 102a; and a source electrode and a drain electrode are formed using the conductive layer 110a whose conductivity is higher than that of the conductive layer 108a. Also, in the driver portion, a gate wiring can be formed using the conductive layer 104a and a source wiring can be formed using the conductive layer 110a.

In the case where the thin film transistor is formed using a multi-tone mask, the transistor of the driver portion can be formed in the following manner: a layered structure of the conductive layer 102a and the conductive layer 104a is formed as the gate electrode; a layered structure of the conductive layer 108a and the conductive layer 110a is formed as the source electrode; and a layered structure of the conductive layer 108b and the conductive layer 110a is formed as the drain electrode.

Note that in FIGS. 23A and 23B, the transistor of the pixel portion can have the structure described in the above embodiments.

Moreover, the above-described driver circuit can be used for an electronic paper that drives electronic ink using an element electrically connected to a switching element, without being limited to applications to a liquid crystal display device or a light-emitting display device. The electronic paper is also referred to as an electrophoretic display device (electrophoretic display) and has advantages in that it has the same level of readability as plain paper, it has lower power consumption than other display devices, and it can be made thin and lightweight.

Embodiment 5 can be implemented in appropriate combination with the structures described in the other embodiments.

### Embodiment 6

In this embodiment, the case where a semiconductor device (also referred to as a display device) having a display function in which thin film transistors are used for a pixel portion and a driver circuit is manufactured will be described. Further, part or the whole of a driver circuit can be formed over a substrate over which a pixel portion is formed, using the thin film transistor, whereby a system-on-panel can be obtained.

The display device includes a display element. As the display element, a liquid crystal element (also referred to as a liquid crystal display element) or a light-emitting element (also referred to as a light-emitting display element) can be used. A light emitting element includes, in its scope, an element whose luminance is controlled by current or voltage, and specifically includes an inorganic electroluminescent (EL) element, an organic EL element, and the like. Furthermore, a display medium whose contrast is changed by an electric effect, such as electronic ink, can be used.

Further, a display device includes a panel in which a display element is sealed, and a module in which an IC or the like including a controller is mounted to the panel. Furthermore, the display device relates to one mode of an element substrate before the display element is completed in a manufacturing process of the display device, and the element substrate is provided with a means for supplying a current to the display element in each of a plurality of pixels. Specifically, the element substrate may be in a state of being provided with only a pixel electrode of the display element, a state after a conductive film to be a pixel electrode is formed and before the conductive film is etched to form the pixel electrode, or any other states.

Note that a display device in this specification means an image display device, a display device, or a light source (including a lighting device). Further, the “display device” includes the following modules in its category: a module including a connector such as a flexible printed circuit (FPC), a tape automated bonding (TAB) tape, or a tape carrier package (TCP) attached; a module having a TAB tape or a TCP which is provided with a printed wiring board at the end thereof; and a module having an integrated circuit (IC) which is directly mounted on a display element by a chip on glass (COG) method.

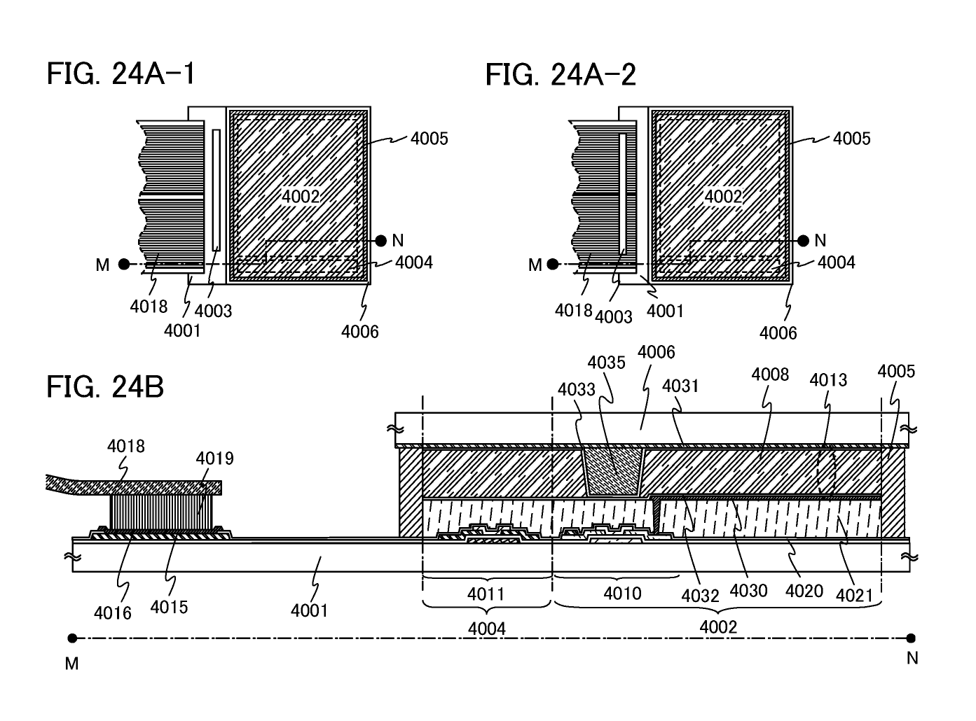

In this embodiment, an example of a liquid crystal display device will be described as a semiconductor device. First, the appearance and a cross section of a liquid crystal display panel, which is one embodiment of a semiconductor device, will be described with reference to FIGS. 24A1, 24A2, and 24B. Each of FIGS. 24A1 and 24A2 is a top view of a panel in which highly reliable thin film transistors 4010 and 4011 which include a semiconductor layer of an In—Ga—Zn—O-based non-single-crystal film, and a liquid crystal element 4013, which are formed over a first substrate 4001, are sealed between the first substrate 4001 and a second substrate 4006 with a sealant 4005. FIG. 24B corresponds to a cross-sectional view of FIGS. 24A1 and 24A2 along line M-N.

The sealant 4005 is provided so as to surround a pixel portion 4002 and a scan line driver circuit 4004 which are provided over the first substrate 4001. The second substrate 4006 is provided over the pixel portion 4002 and the scan line driver circuit 4004. Therefore, the pixel portion 4002 and the scan line driver circuit 4004 are sealed together with a liquid crystal layer 4008, by the first substrate 4001, the sealant 4005, and the second substrate 4006. A signal line driver circuit 4003 that is formed using a single crystal semiconductor film or a polycrystalline semiconductor film over a substrate separately prepared is mounted in a region that is different from the region surrounded by the sealant 4005 over the first substrate 4001.

Note that there is no particular limitation on the connection method of a driver circuit which is separately formed, and a COG method, a wire bonding method, a TAB method, or the like can be used. FIG. 24A1 illustrates an example of mounting the signal line driver circuit 4003 by a COG method, and FIG. 24A2 illustrates an example of mounting the signal line driver circuit 4003 by a TAB method.

In addition, the pixel portion 4002 and the scan line driver circuit 4004 provided over the first substrate 4001 include a plurality of thin film transistors. FIG. 24B illustrates the thin film transistor 4010 included in the pixel portion 4002 and the thin film transistor 4011 included in the scan line driver circuit 4004. Over the thin film transistors 4010 and 4011, insulating layers 4020 and 4021 are provided.

As the thin film transistors 4010 and 4011, highly reliable thin film transistors including an In—Ga—Zn—O-based non-single-crystal film as a semiconductor layer can be used. In Embodiment 6, the thin film transistors 4010 and 4011 are n-channel thin film transistors.

In addition, a pixel electrode layer 4030 included in the liquid crystal element 4013 is electrically connected to the thin film transistor 4010. A counter electrode layer 4031 of the liquid crystal element 4013 is provided for the second substrate 4006. A portion where the pixel electrode layer 4030, the counter electrode layer 4031, and the liquid crystal layer 4008 overlap with one another corresponds to the liquid crystal element 4013. Note that the pixel electrode layer 4030 and the counter electrode layer 4031 are provided with an insulating layer 4032 and an insulating layer 4033 respectively each of which functions as an alignment film, and the liquid crystal layer 4008 is sandwiched between the pixel electrode layer 4030 and the counter electrode layer 4031 with the insulating layers 4032 and 4033 therebetween.

Note that the first substrate 4001 and the second substrate 4006 can be formed of glass, metal (typically, stainless steel), ceramic, or plastic. As plastic, a fiberglass-reinforced plastics (FRP) plate, a polyvinyl fluoride (PVF) film, a polyester film, or an acrylic resin film can be used. In addition, a sheet with a structure in which an aluminum foil is sandwiched between PVF films or polyester films can be used.

In addition, reference numeral 4035 denotes a columnar spacer obtained by selectively etching an insulating film and is provided to control the distance between the pixel electrode layer 4030 and the counter electrode layer 4031 (a cell gap). Alternatively, a spherical spacer may also be used. Further, the counter electrode layer 4031 is electrically connected to a common potential line formed over a substrate over which the thin film transistor 4010 is formed. With the use of the common connection portion, the counter electrode layer 4031 and the common potential line can be electrically connected to each other by conductive particles arranged between a pair of substrates. Note that the conductive particles are included in the sealant 4005.

Alternatively, liquid crystal exhibiting a blue phase for which an alignment film is unnecessary may be used. A blue phase is one of liquid crystal phases, which is generated just before a cholesteric phase changes into an isotropic phase while temperature of cholesteric liquid crystal is increased. Since the blue phase is generated within an only narrow range of temperature, liquid crystal composition containing a chiral agent at 5 wt % or more so as to improve the temperature range is used for the liquid crystal layer 4008. The liquid crystal composition which includes liquid crystal exhibiting a blue phase and a chiral agent have such characteristics that the response time is 10 to 100 μs, which is short, the alignment process is unnecessary because the liquid crystal composition has optical isotropy, and viewing angle dependency is small.

Note that the liquid crystal display device described in this embodiment is an example of a transmissive liquid crystal display device; however, the liquid crystal display device can be applied to either a reflective liquid crystal display device or a semi-transmissive liquid crystal display device.

An example of the liquid crystal display device described in this embodiment is illustrated in which a polarizing plate is provided on the outer surface of the substrate (on the viewer side) and a coloring layer and an electrode layer used for a display element are provided on the inner surface of the substrate in that order; however, the polarizing plate may be provided on the inner surface of the substrate. The layered structure of the polarizing plate and the coloring layer is not limited to this embodiment and may be set as appropriate depending on materials of the polarizing plate and the coloring layer or conditions of manufacturing process. Further, a light-shielding film serving as a black matrix may be provided.

In this embodiment, in order to reduce the surface roughness of the thin film transistor and to improve the reliability of the thin film transistor, the thin film transistor is covered with the insulating layers (the insulating layer 4020 and the insulating layer 4021) serving as a protection film or a planarization insulating film. Note that the protection film is provided to prevent entry of contaminant impurities such as organic substance, metal, or moisture existing in air and is preferably a dense film. The protection film may be formed with a single layer or a stacked layer of a silicon oxide film, a silicon nitride film, a silicon oxynitride film, a silicon nitride oxide film, an aluminum oxide film, an aluminum nitride film, aluminum oxynitride film, and/or an aluminum nitride oxide film by a sputtering method. Although an example in which the protection film is formed by a sputtering method is described in Embodiment 6, this embodiment is not limited to this method and a variety of methods may be employed.

In this embodiment, the insulating layer 4020 having a layered structure is formed as a protective film. Here, a silicon oxide film is formed by a sputtering method, as a first layer of the insulating layer 4020. The use of a silicon oxide film as a protection film has an effect of preventing hillock of an aluminum film which is used as the source and drain electrode layers.

As a second layer of the protection film, an insulating layer is formed. Here, a silicon nitride film is formed by a sputtering method, as a second layer of the insulating layer 4020. The use of the silicon nitride film as the protection film can prevent mobile ions of sodium or the like from entering a semiconductor region so that variation in electrical characteristics of the TFT can be suppressed.

After the protection film is formed, the semiconductor layer may be subjected to annealing (300 to 400° C.).

The insulating layer 4021 is formed as the planarization insulating film. As the insulating layer 4021, an organic material having heat resistance such as polyimide, acrylic, benzocyclobutene, polyamide, or epoxy can be used. Other than such organic materials, it is also possible to use a low-dielectric constant material (a low-k material), a siloxane-based resin, PSG (phosphosilicate glass), BPSG (borophosphosilicate glass), or the like. Note that the insulating layer 4021 may be formed by stacking a plurality of insulating films formed of these materials.

Note that the siloxane-based resin corresponds to a resin including a Si—O—Si bond formed using a siloxane-based material as a starting material. The siloxane-based resin may include an organic group (e.g., an alkyl group or an aryl group) or a fluoro group as a substituent. In addition, the organic group may include a fluoro group.

There is no particular limitation on a formation method of the insulating layer 4021, and the following method can be employed depending on the material: a sputtering method, an SOG method, a spin coating method, a dipping method, a spray coating method, a droplet discharge method (e.g., an ink-jet method, screen printing, offset printing, or the like), a doctor knife, a roll coater, a curtain coater, a knife coater, or the like. In a case of forming the insulating layer 4021 using a material solution, annealing (300 to 400° C.) of the semiconductor layer may be performed at the same time as a baking step. The baking step of the insulating layer 4021 also serves as annealing of the semiconductor layer, whereby a semiconductor device can be manufactured efficiently.

The pixel electrode layer 4030 and the counter electrode layer 4031 can be formed using a light-transmitting conductive material such as indium oxide containing tungsten oxide, indium zinc oxide containing tungsten oxide, indium oxide containing titanium oxide, indium tin oxide containing titanium oxide, indium tin oxide (hereinafter referred to as ITO), indium zinc oxide, indium tin oxide to which silicon oxide is added, or the like.

Conductive compositions including a conductive high molecule (also referred to as a conductive polymer) can be used for the pixel electrode layer 4030 and the counter electrode layer 4031. The pixel electrode formed using a conductive composition preferably has a light transmittance of greater than or equal to 70% at a wavelength of 550 nm. Further, the resistivity of the conductive high molecule included in the conductive composition is preferably less than or equal to 0.1 Ω·cm.

As the conductive high molecule, a so-called 7c-electron conjugated conductive polymer can be used. For example, polyaniline or a derivative thereof, polypyrrole or a derivative thereof, polythiophene or a derivative thereof, a copolymer of two or more kinds of them, and the like can be given.

Further, a variety of signals and potentials are supplied to the signal line driver circuit 4003 which is formed separately, the scan line driver circuit 4004, or the pixel portion 4002 from an FPC 4018.

In this embodiment, a connection terminal electrode 4015 is formed from the same conductive film as the pixel electrode layer 4030 included in the liquid crystal element 4013, and a terminal electrode 4016 is formed from the same conductive film as the source and drain electrode layers of the thin film transistors 4010 and 4011.

The connection terminal electrode 4015 is electrically connected to a terminal included in the FPC 4018 via an anisotropic conductive film 4019.

FIGS. 24A1, 24A2, and 24B illustrate an example in which the signal line driver circuit 4003 is separately formed and mounted on the first substrate 4001; however, this embodiment is not limited to this structure. The scan line driver circuit may be separately formed and then mounted, or only part of the signal line driver circuit or part of the scan line driver circuit may be separately formed and then mounted.

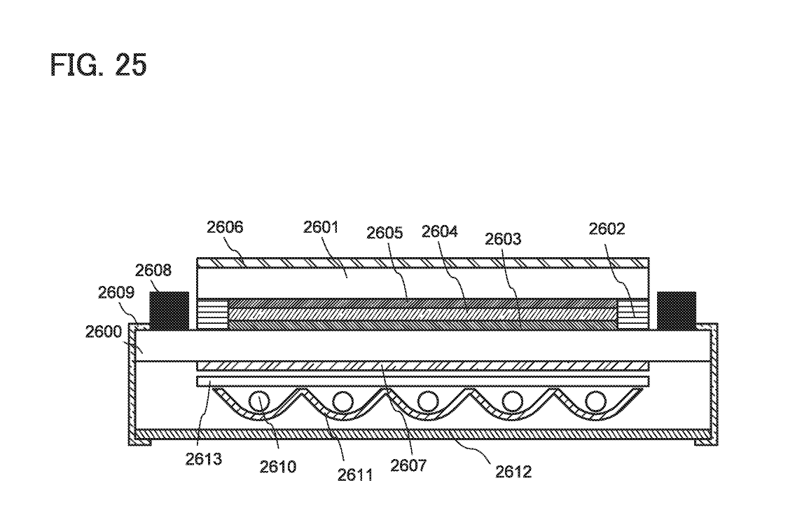

FIG. 25 illustrates an example in which a TFT substrate 2600 is used for a liquid crystal display module corresponding to one mode of a semiconductor device.

FIG. 25 illustrates an example of a liquid crystal display module, in which, to form a display region, the TFT substrate 2600 and a counter substrate 2601 are fixed to each other with a sealant 2602; an element layer 2603 including a TFT or the like, a display element 2604 including a liquid crystal layer, and a coloring layer 2605 are provided between the substrates. The coloring layer 2605 is necessary to perform color display. In the RGB system, respective coloring layers corresponding to colors of red, green, and blue are provided for respective pixels. The polarizing plate 2606, a polarizing plate 2607, and a diffusion plate 2613 are provided outside the TFT substrate 2600 and the counter substrate 2601. A light source includes a cold cathode tube 2610 and a reflective plate 2611, and a circuit substrate 2612 is connected to a wiring circuit portion 2608 of the TFT substrate 2600 by a flexible wiring board 2609 and includes an external circuit such as a control circuit or a power supply circuit. The polarizing plate and the liquid crystal layer may be stacked with a retardation plate therebetween.

For the liquid crystal display module, a twisted nematic (TN) mode, an in-plane-switching (IPS) mode, a fringe field switching (FFS) mode, a multi-domain vertical alignment (MVA) mode, a patterned vertical alignment (PVA) mode, an axially symmetric aligned micro-cell (ASM) mode, an optical compensated birefringence (OCB) mode, a ferroelectric liquid crystal (FLC) mode, an antiferroelectric liquid crystal (AFLC) mode, or the like can be used.

Through this process, a highly reliable liquid crystal display device as a semiconductor device can be manufactured.

Embodiment 6 can be implemented in appropriate combination with the structures described in the other embodiments.

### Embodiment 7

In this embodiment, an electronic paper is described as an example of a semiconductor device.

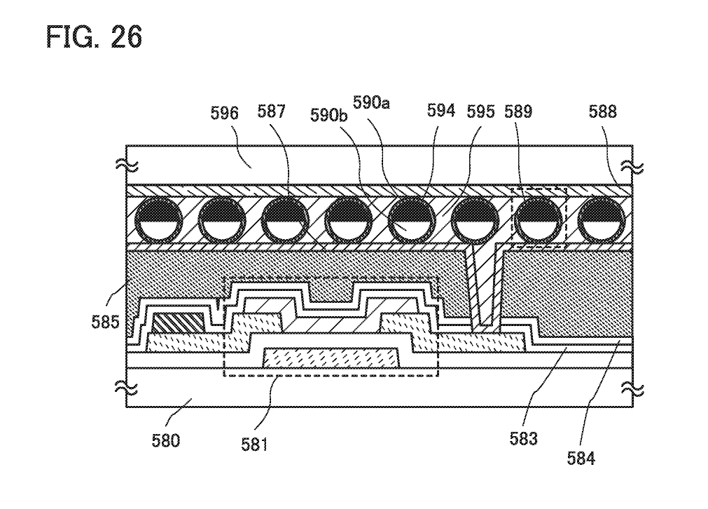

FIG. 26 illustrates an active matrix electronic paper as an example of the semiconductor device. A thin film transistor 581 used for the semiconductor device can be formed in a manner similar to the thin film transistor described in any of Embodiments 1 to 3.

The electronic paper in FIG. 26 is an example of a display device using a twisting ball display system. The twisting ball display system refers to a method in which spherical particles each colored in black and white are arranged between a first electrode layer and a second electrode layer which are used for a display element, and a potential difference is generated between the first electrode layer and the second electrode layer to control orientation of the spherical particles, so that display is performed.

The thin film transistor 581 provided over a substrate 580 is a thin film transistor having a bottom gate structure. A source electrode layer or a drain electrode layer is electrically connected to a first electrode layer 587 through a contact hole formed in insulating layers 583, 584, and 585. Between the first electrode layer 587 and a second electrode layer 588, spherical particles 589 each having a black region 590a, a white region 590b, and a cavity 594 around the regions which is filled with liquid are provided. A space around the spherical particles 589 is filled with a filler 595 such as a resin (see FIG. 26). In FIG. 26, the first electrode layer 587 corresponds to a pixel electrode, and the second electrode layer 588 corresponds to a common electrode. The second electrode layer 588 is electrically connected to a common potential line provided over a substrate where the thin film transistor 581 is formed. A common connection portion described in the above embodiment is used, whereby the second electrode layer 588 provided on a substrate 596 and the common potential line can be electrically connected to each other through the conductive particles arranged between a pair of substrates.

Further, instead of the twisting ball, an electrophoretic element can also be used. In that case, a microcapsule having a diameter of approximately 10 to 200 μm, in which transparent liquid, positively charged white fine particles, and negatively charged black fine particles are encapsulated, is used. In the microcapsule which is provided between the first electrode layer and the second electrode layer, when an electric field is applied by the first electrode layer and the second electrode layer, the white fine particles and the black fine particles move to opposite sides, so that white or black can be displayed. A display element using this principle is an electrophoretic display element, and is called electronic paper in general. The electrophoretic display element has higher reflectivity than a liquid crystal display element, and thus, an auxiliary light is unnecessary, power consumption is low, and a display portion can be recognized in a dim place. In addition, even when power is not supplied to the display portion, an image which has been displayed once can be maintained. Accordingly, a displayed image can be stored even if a semiconductor device having a display function (which may be referred to simply as a display device or a semiconductor device provided with a display device) is distanced from an electric wave source.

In this manner, a highly reliable electronic paper can be formed as a semiconductor device.

Embodiment 7 can be implemented in appropriate combination with the structures described in the other embodiments.

### Embodiment 8

In Embodiment 8, an example of a light-emitting display device as a semiconductor device will be described. As a display element included in a display device, a light-emitting element utilizing electroluminescence is described here. Light-emitting elements utilizing electroluminescence are classified according to whether a light-emitting material is an organic compound or an inorganic compound. In general, the former is referred to as an organic EL element, and the latter is referred to as an inorganic EL element.

In an organic EL element, by application of voltage to a light-emitting element, electrons and holes are separately injected from a pair of electrodes into a layer containing a light-emitting organic compound, and current flows. The carriers (electrons and holes) are recombined, and thus, the light-emitting organic compound is excited. The light-emitting organic compound returns to a ground state from the excited state, thereby emitting light. Owing to such a mechanism, this light-emitting element is referred to as a current-excitation light-emitting element.

The inorganic EL elements are classified according to their element structures into a dispersion-type inorganic EL element and a thin-film inorganic EL element. A dispersion-type inorganic EL element has a light-emitting layer where particles of a light-emitting material are dispersed in a binder, and its light emission mechanism is donor-acceptor recombination type light emission that utilizes a donor level and an acceptor level. A thin-film inorganic EL element has a structure where a light-emitting layer is sandwiched between dielectric layers, which are further sandwiched between electrodes, and its light emission mechanism is localized type light emission that utilizes inner-shell electron transition of metal ions. Note that an example of an organic EL element as a light-emitting element is described here.

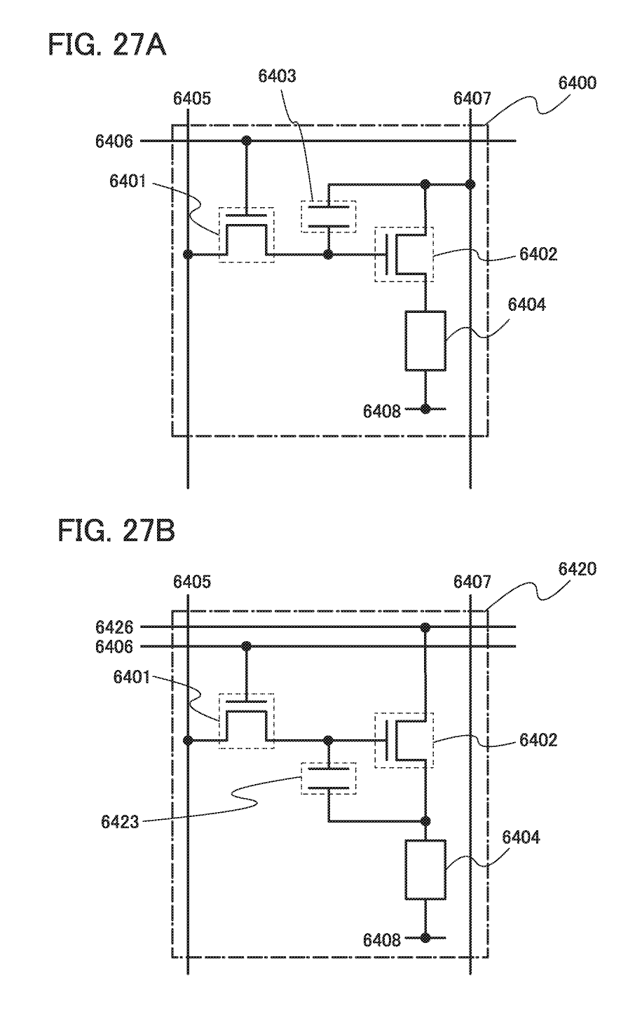

FIGS. 27A and 27B each illustrate an example of a pixel structure to which digital time grayscale driving can be applied, as an example of a semiconductor device.

A structure and operation of a pixel to which digital time grayscale driving can be applied are described. Here, for example, one pixel includes two n-channel transistors each of which includes an oxide semiconductor layer (an In—Ga—Zn—O-based non-single-crystal film) as its channel formation region.

A pixel 6400 shown in FIG. 27A includes a switching transistor 6401, a driving transistor 6402, a light-emitting element 6404, and a capacitor 6403. A gate of the switching transistor 6401 is connected to a scan line 6406, a first electrode (one of a source electrode and a drain electrode) of the switching transistor 6401 is connected to a signal line 6405, and a second electrode (the other of the source electrode and the drain electrode) of the switching transistor 6401 is connected to a gate of the driver transistor 6402. The gate of the driver transistor 6402 is connected to a power supply line 6407 via the capacitor 6403, a first electrode of the driver transistor 6402 is connected to the power supply line 6407, and a second electrode of the driver transistor 6402 is connected to a first electrode (pixel electrode) of the light-emitting element 6404. A second electrode of the light-emitting element 6404 corresponds to a common electrode 6408.

The second electrode (common electrode 6408) of the light-emitting element 6404 is set to a low power supply potential. Note that the low power supply potential is a potential satisfying the relation, the low power supply potential <a high power supply potential, by using the high power supply potential that is set to the power supply line 6407 as a reference. As the low power supply potential, GND, 0 V, or the like may be employed, for example. A potential difference between the high power supply potential and the low power supply potential is applied to the light-emitting element 6404 and current is supplied to the light-emitting element 6404, so that the light-emitting element 6404 emits light. Here, in order to make the light-emitting element 6404 emit light, each potential is set so that the potential difference between the high power supply potential and the low power supply potential is a forward threshold voltage or higher of the light-emitting element 6404.

However, this embodiment is not limited to this example. The second electrode may be set to have a high power supply potential and the power supply line 6407 may be set to have a low-power supply potential.

Note that gate capacitor of the driver transistor 6402 may be used as a substitute for the capacitor 6403, so that the capacitor 6403 can be eliminated. The gate capacitor of the driver transistor 6402 may be formed between the channel region and the gate electrode.

In the case of a voltage-input voltage driving method, a video signal is input to the gate of the driver transistor 6402 so that the driver transistor 6402 is in either of two states of being sufficiently turned on or turned off. That is, the driver transistor 6402 operates in a linear region. Since the driver transistor 6402 operates in the linear region, a voltage higher than the voltage of the power supply line 6407 is applied to the gate of the driver transistor 6402. Note that a voltage higher than or equal to (voltage of the power supply line+Vth of the driver transistor 6402) is applied to the signal line 6405.

In the case of performing analog grayscale driving instead of digital time grayscale driving, the same pixel structure as that in FIGS. 27A and 27B can be used by changing signal input.

In the case of performing analog grayscale driving, a voltage higher than or equal to (forward voltage of the light-emitting element 6404+Vth of the driver transistor 6402) is applied to the gate of the driver transistor 6402. The forward voltage of the light-emitting element 6404 indicates a voltage at which a desired luminance is obtained, and includes at least forward threshold voltage. The video signal by which the driver transistor 6402 operates in a saturation region is input, so that current can be supplied to the light-emitting element 6404. In order for the driver transistor 6402 to operate in the saturation region, the potential of the power supply line 6407 is set higher than the gate potential of the driver transistor 6402. When an analog video signal is used, current can be supplied to the light-emitting element 6404 in accordance with the video signal and perform analog grayscale driving.

Note that this embodiment is not limited to the pixel structures described in this embodiment. A switch, a resistor, a capacitor, a transistor, a logic circuit, or the like may be additionally provided to the pixel illustrated in FIG. 27A. For example, the one shown in FIG. 27B may be employed. A pixel 6420 shown in FIG. 27B includes the switching transistor 6401, the driver transistor 6402, the light-emitting element 6404, and the capacitor 6423. The gate of the switching transistor 6401 is connected to the scan line 6406, the first electrode (one of a source electrode and a drain electrode) of the switching transistor 6401 is connected to the signal line 6405, and the second electrode (the other of the source electrode and the drain electrode) of the switching transistor 6401 is connected to the gate of the driver transistor 6402. The gate of the driving transistor 6402 is connected to the first electrode (pixel electrode) of the light-emitting element 6404 through the capacitor 6423, the first electrode of the driving transistor 6402 is connected to a wiring 6426 for applying a pulse voltage, and the second electrode of the driving transistor 6402 is connected to the first electrode of the light-emitting element 6404. The second electrode of the light-emitting element 6404 corresponds to the common electrode 6408. It is needless to say that a switch, a resistor, a capacitor, a transistor, a logic circuit, or the like can be additionally provided for the structure.

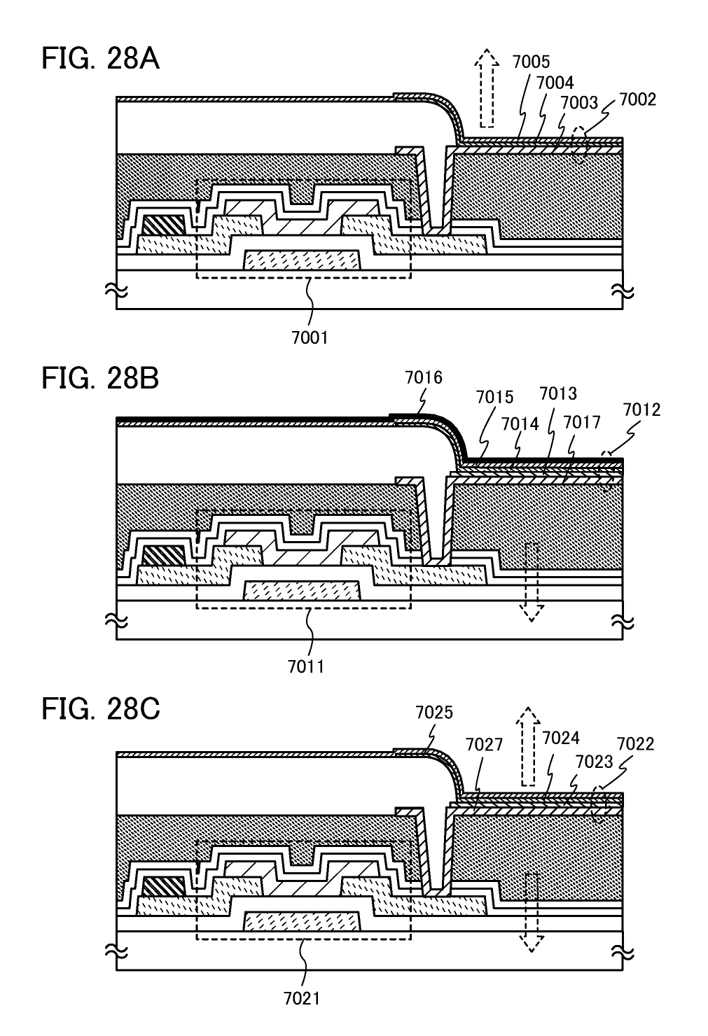

Next, a structure of a light-emitting element will be described with reference to FIGS. 28A to 28C. Here, a cross-sectional structure of a pixel will be described by taking an n-channel driver TFT as an example. TFTs 7001, 7011, and 7021 serving as driver TFTs used for a semiconductor device, which are illustrated in FIGS. 28A, 28B, and 28C, can be manufactured in a manner similar to that of the thin film transistor described in the above embodiment. The TFTs 7001, 7011, and 7021 are highly reliable thin film transistors each including an In—Ga—Zn—O-based non-single-crystal film as a semiconductor layer.

In order to extract light emitted from the light-emitting element, at least one of an anode and a cathode is required to transmit light. A thin film transistor and a light-emitting element are formed over a substrate. A light-emitting element can have a top emission structure, in which light emission is extracted through the surface opposite to the substrate; a bottom emission structure, in which light emission is extracted through the surface on the substrate side; or a dual emission structure, in which light emission is extracted through the surface opposite to the substrate and the surface on the substrate side. The pixel structure can be applied to a light-emitting element having any of these emission structures.

A light-emitting element having a top emission structure will be described with reference to FIG. 28A.

FIG. 28A is a cross-sectional view of a pixel in the case where the driving TFT 7001 is an n-channel transistor and light is emitted from a light-emitting element 7002 to an anode 7005 side. In FIG. 28A, a cathode 7003 of the light-emitting element 7002 is electrically connected to the driver TFT 7001, and a light-emitting layer 7004 and the anode 7005 are stacked in this order over the cathode 7003. The cathode 7003 can be formed using a variety of conductive materials as long as they have a low work function and reflect light. For example, Ca, Al, CaF, MgAg, AlLi, or the like is preferably used. The light-emitting layer 7004 may be formed using a single layer or a plurality of layers stacked. When the light-emitting layer 7004 is formed using a plurality of layers, the light-emitting layer 7004 is formed by stacking an electron-injecting layer, an electron-transporting layer, a light-emitting layer, a hole-transporting layer, and a hole-injecting layer in this order over the cathode 7003. Note that it is not necessary to form all of these layers. The anode 7005 is formed using a light-transmitting conductive film such as a film of indium oxide containing tungsten oxide, indium zinc oxide containing tungsten oxide, indium oxide containing titanium oxide, indium tin oxide containing titanium oxide, indium tin oxide (hereinafter referred to as ITO), indium zinc oxide, or indium tin oxide to which silicon oxide is added.

The light-emitting element 7002 corresponds to a region where the light-emitting layer 7004 is sandwiched between the cathode 7003 and the anode 7005. In the case of the pixel illustrated in FIG. 28A, light is emitted from the light-emitting element 7002 to the anode 7005 side as indicated by an arrow.

Note that a micro cavity structure in which the thickness of the light-emitting layer 7004 in the above structure is adjusted may be employed. When the micro cavity structure is employed, color purity can be increased. In addition, in the case where a plurality of light-emitting layers 7004 emits light of their respective colors (e.g., R, G, and B), a micro cavity structure obtained by adjusting the thicknesses of the light-emitting layers 7004 is preferably employed for each color.

In addition, in the above-structure, an insulating film of silicon oxide, silicon nitride, or the like may be provided over the anode 7005. Accordingly, the deterioration of the light-emitting layer can be suppressed.

Next, a light-emitting element having a bottom emission structure will be described with reference to FIG. 28B. FIG. 28B is a cross-sectional view of a pixel in the case where the driving TFT 7011 is an n-channel transistor and light is emitted from a light-emitting element 7012 to a cathode 7013 side. In FIG. 28B, the cathode 7013 of the light-emitting element 7012 is formed over a light-transmitting conductive film 7017 that is electrically connected to the driver TFT 7011, and a light-emitting layer 7014 and an anode 7015 are stacked in this order over the cathode 7013. A light-shielding film 7016 for reflecting or shielding light may be formed to cover the anode 7015 in the case where the anode 7015 has a light-transmitting property. For the cathode 7013, various materials can be used as in the case of FIG. 28A as long as they are conductive materials having a low work function. Note that the cathode 7013 is formed to have a thickness that can transmit light (preferably, approximately 5 to 30 nm). For example, an aluminum film with a thickness of 20 nm can be used as the cathode 7013. In a manner similar to the case of FIG. 28A, the light-emitting layer 7014 may be formed using either a single layer or a plurality of layers stacked. The anode 7015 does not necessarily transmit light, but can be formed using a conductive material having a light-transmitting property as in the case of FIG. 28A. As the light-shielding film 7016, a metal or the like that reflects light can be used for example; however, it is not limited to a metal film. For example, a resin or the like to which black pigments are added can also be used.

The light-emitting element 7012 corresponds to a region where the light-emitting layer 7014 is sandwiched between the cathode 7013 and the anode 7015. In the case of the pixel illustrated in FIG. 28B, light is emitted from the light-emitting element 7012 to the cathode 7013 side as indicated by an arrow.

Next, a light-emitting element having a dual emission structure will be described with reference to FIG. 28C. In FIG. 28C, a cathode 7023 of a light-emitting element 7022 is formed over a light-transmitting conductive film 7027 which is electrically connected to the driver TFT 7021, and a light-emitting layer 7024 and an anode 7025 are stacked in this order over the cathode 7023. As in the case of FIG. 28A, the cathode 7023 can be formed using a variety of conductive materials as long as they have a low work function. Note that the cathode 7023 is formed to have a thickness that can transmit light. For example, a film of Al having a thickness of 20 nm can be used as the cathode 7023. As in FIG. 28A, the light-emitting layer 7024 may be formed using either a single layer or a plurality of layers stacked. The anode 7025 can be formed using a light-transmitting conductive material as in the case of FIG. 28A.

The light-emitting element 7022 corresponds to a region where the cathode 7023, the light-emitting layer 7024, and the anode 7025 overlap with one another. In the case of the pixel illustrated in FIG. 28C, light is emitted from the light-emitting element 7022 to both the anode 7025 side and the cathode 7023 side as indicated by arrows.

Note that, although the organic EL elements are described here as the light-emitting elements, an inorganic EL element can also be provided as a light-emitting element.

In this embodiment, the example is described in which a thin film transistor (a driver TFT) which controls the driving of a light-emitting element is electrically connected to the light-emitting element; however, a structure may be employed in which a TFT for current control is connected between the driver TFT and the light-emitting element.

Note that a semiconductor device described in this embodiment is not limited to the structures illustrated in FIGS. 28A to 28C and can be modified in various ways.

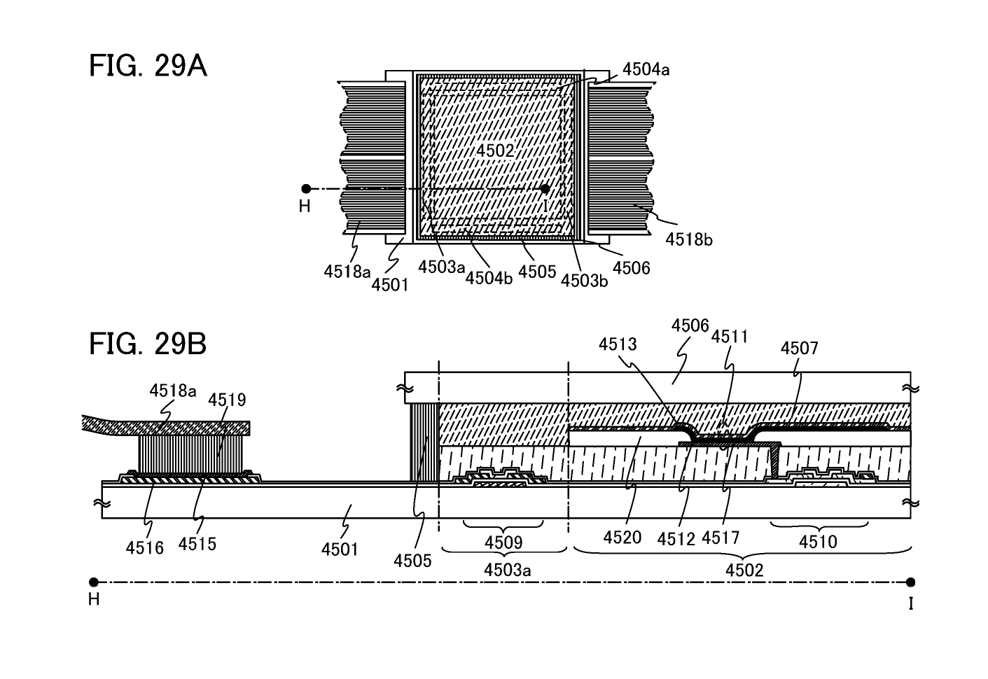

Next, the appearance and cross section of a light-emitting display panel (also referred to as a light-emitting panel) which corresponds to one mode of a semiconductor device will be described with reference to FIGS. 29A and 29B. FIG. 29A is a top view of a panel in which highly reliable thin film transistors 4509 and 4510 which include semiconductor layers of In—Ga—Zn—O-based non-single crystal films, and a light-emitting element 4511, which are formed over a first substrate 4501, are sealed between the first substrate 4501 and a second substrate 4506 with a sealant 4505. FIG. 29B corresponds to a cross-sectional view of FIG. 29A along line H-I.

A sealant 4505 is provided so as to surround a pixel portion 4502, signal line driver circuits 4503a and 4503b, and scan line driver circuits 4504a and 4504b which are provided over a first substrate 4501. In addition, a second substrate 4506 is provided over the pixel portion 4502, the signal line driver circuits 4503a and 4503b, and the scan line driver circuits 4504a and 4504b. Accordingly, the pixel portion 4502, the signal line driver circuits 4503a and 4503b, and the scan line driver circuits 4504a and 4504b are sealed together with a filler 4507, by the first substrate 4501, the sealant 4505, and the second substrate 4506. It is preferable that a panel be packaged (sealed) with a protection film (such as a laminate film or an ultraviolet curable resin film) or a cover material with high air-tightness and little degasification so that the panel is not exposed to the outside air, in this manner.

The pixel portion 4502, the signal line driver circuits 4503a and 4503b, and the scan line driver circuits 4504a and 4504b formed over the first substrate 4501 each include a plurality of thin film transistors, and a thin film transistor 4510 included in the pixel portion 4502 and a thin film transistor 4509 included in the signal line driver circuit 4503a are illustrated as examples in FIG. 29B.

The thin film transistors 4509 and 4510 can have the structure described in the above embodiments. Here, as the thin film transistors 4509 and 4510, the highly reliable thin film transistor which includes an In—Ga—Zn—O-based non-single-crystal film as a semiconductor layer, can be employed. In Embodiment 8, the thin film transistors 4509 and 4510 are n-channel thin film transistors.

Moreover, reference numeral 4511 denotes a light-emitting element. A first electrode layer 4517 which is a pixel electrode included in the light-emitting element 4511 is electrically connected to a source electrode layer or a drain electrode layer of the thin film transistor 4510. Note that a structure of the light-emitting element 4511 is a layered structure of the first electrode layer 4517, the electroluminescent layer 4512, and the second electrode layer 4513, but there is no particular limitation on the structure. The structure of the light-emitting element 4511 can be changed as appropriate depending on the direction in which light is extracted from the light-emitting element 4511, or the like.

A partition 4520 is formed using an organic resin film, an inorganic insulating film, or organic polysiloxane. It is particularly preferable that the partition 4520 be formed using a photosensitive material and an opening be formed over the first electrode layer 4517 so that a sidewall of the opening is formed as an inclined surface with continuous curvature.

The electroluminescent layer 4512 may be formed with a single layer or a plurality of layers stacked.

A protection film may be formed over the second electrode layer 4513 and the partition 4520 in order to prevent entry of oxygen, hydrogen, moisture, carbon dioxide, or the like into the light-emitting element 4511. As the protection film, a silicon nitride film, a silicon nitride oxide film, a DLC film, or the like can be formed.

In addition, a variety of signals and potentials are supplied to the signal line driver circuits 4503a and 4503b, the scan line driver circuits 4504a and 4504b, or the pixel portion 4502 from FPCs 4518a and 4518b.

In this embodiment, a connection terminal electrode 4515 is formed from the same conductive film as the first electrode layer 4517 included in the light-emitting element 4511, and a terminal electrode 4516 is formed from the same conductive film as the source and drain electrode layers included in the thin film transistors 4509 or 4510.

The connection terminal electrode 4515 is electrically connected to a terminal included in the FPC 4518a via an anisotropic conductive film 4519.

As a substrate located in the direction in which light is extracted from the light-emitting element 4511 needs to have a light-transmitting property. In that case, a light-transmitting material such as a glass plate, a plastic plate, a polyester film, or an acrylic film is used for the substrate.

In addition, as the filler 4507, an ultraviolet curable resin or a thermosetting resin can be used, in addition to an inert gas such as nitrogen or argon. For example, PVC (polyvinyl chloride), acrylic, polyimide, an epoxy resin, a silicone resin, PVB (polyvinyl butyral), or EVA (ethylene vinyl acetate) can be used. In Embodiment 8, nitrogen is used for the filler.

In addition, if needed, an optical film, such as a polarizing plate, a circularly polarizing plate (including an elliptically polarizing plate), a retardation plate (a quarter-wave plate or a half-wave plate), or a color filter, may be provided as appropriate on a light-emitting surface of the light-emitting element. Further, the polarizing plate or the circularly polarizing plate may be provided with an anti-reflection film. For example, anti-glare treatment by which reflected light can be diffused by projections and depressions on the surface so as to reduce the glare can be performed.

The signal line driver circuits 4503a and 4503b and the scanning line driver circuits 4504a and 4504b may be mounted as driver circuits formed using a single crystal semiconductor film or a polycrystalline semiconductor film over a substrate separately prepared. In addition, only the signal line driver circuits or part thereof, or the scan line driver circuits or part thereof may be separately formed and mounted. This embodiment is not limited to the structure illustrated in FIGS. 29A and 29B.

Through the above process, a highly reliable light-emitting display device (display panel) as a semiconductor device can be manufactured.

Embodiment 8 can be implemented in appropriate combination with the structures described in the other embodiments.

### Embodiment 9

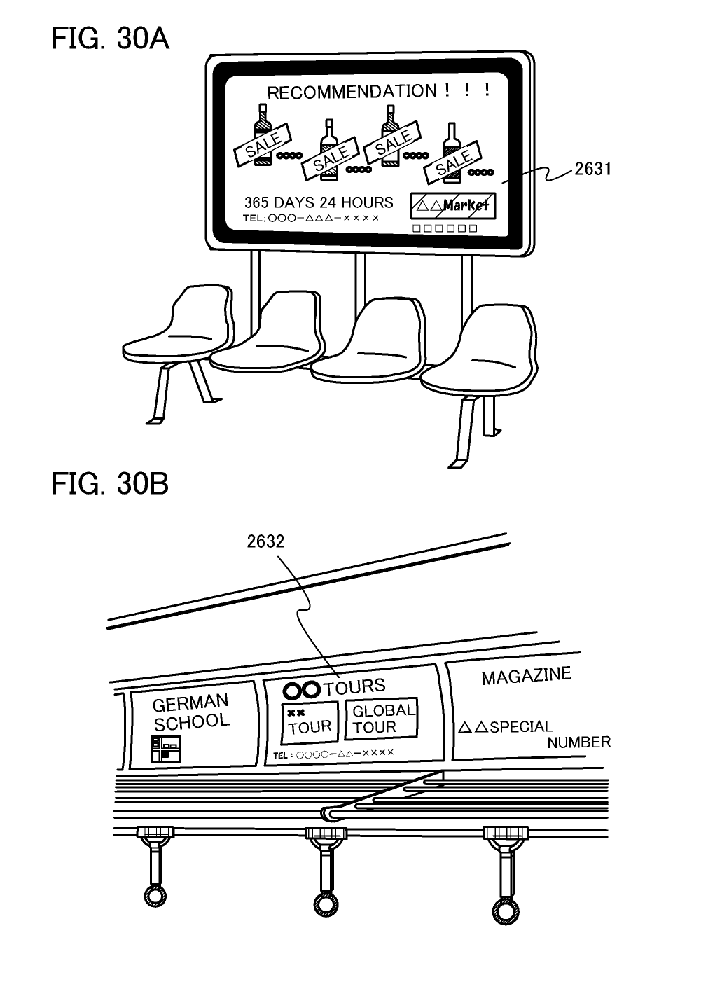

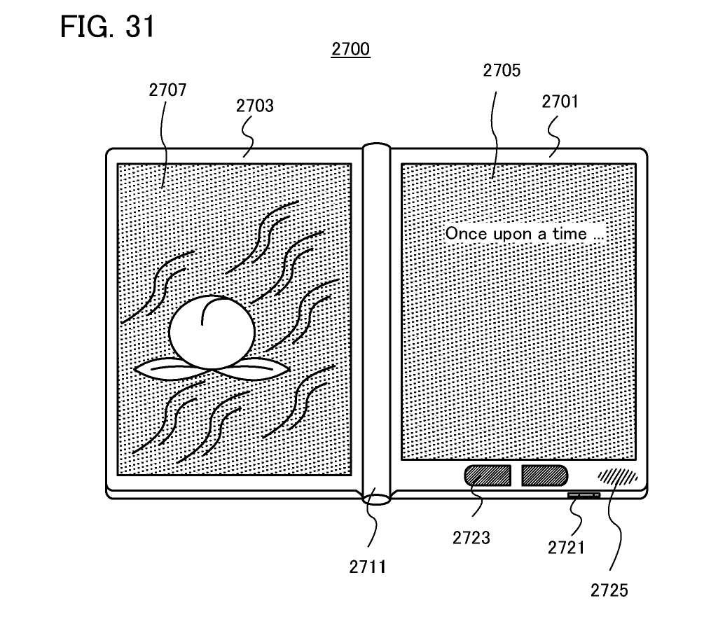

The semiconductor device can be applied as an electronic paper. An electronic paper can be used for electronic appliances of a variety of fields as long as they can display data. For example, an electronic paper can be applied to an e-book reader (electronic book), a poster, an advertisement in a vehicle such as a train, or displays of various cards such as a credit card. Examples of the electronic appliances are illustrated in FIGS. 30A and 30B and FIG. 31.

FIG. 30A illustrates a poster 2631 formed using electronic paper. In the case where an advertising medium is printed paper, the advertisement is replaced by hands; however, by using the electronic paper, the advertising display can be changed in a short time. Furthermore, stable images can be obtained without display defects. Note that the poster may have a configuration capable of wirelessly transmitting and receiving data.

FIG. 30B illustrates an advertisement 2632 in a vehicle such as a train. In the case where an advertising medium is printed paper, the advertisement is replaced by hands; however, by using the electronic paper, much manpower is not needed and the advertising display can be changed in a short time. Furthermore, stable images can be obtained without display defects. Note that the poster may have a configuration capable of wirelessly transmitting and receiving data.

FIG. 31 illustrates an example of an e-book reader 2700. For example, the e-book reader 2700 includes two housings, a housing 2701 and a housing 2703. The housing 2701 and the housing 2703 are combined with a hinge 2711 so that the e-book reader 2700 can be opened and closed with the hinge 2711 as an axis. With such a structure, the e-book reader 2700 can operate like a paper book.

A display portion 2705 and a display portion 2707 are incorporated in the housing 2701 and the housing 2703, respectively. The display portion 2705 and the display portion 2707 may display one image or different images. In the structure where different images are displayed in different display portions, for example, the right display portion (the display portion 2705 in FIG. 31) displays text and the left display portion (the display portion 2707 in FIG. 31) displays images.

FIG. 31 illustrates an example in which the housing 2701 is provided with an operation portion and the like. For example, the housing 2701 is provided with a power switch 2721, an operation key 2723, a speaker 2725, and the like. With the operation key 2723, pages can be turned. Note that a keyboard, a pointing device, and the like may be provided on the same surface as the display portion of the housing. Furthermore, an external connection terminal (an earphone terminal, a USB terminal, a terminal that can be connected to various cables such as an AC adapter and a USB cable, or the like), a recording medium insertion portion, and the like may be provided on the back surface or the side surface of the housing. Moreover, the e-book reader 2700 may have a function of an electronic dictionary.

The e-book reader 2700 may have a configuration capable of wirelessly transmitting and receiving data. Through wireless communication, desired book data or the like can be purchased and downloaded from an electronic book server.

### Embodiment 10

In this embodiment, a structure and an operation of a pixel which can be applied to a liquid crystal display device will be described. In this embodiment, as an operation mode of a liquid crystal element, a TN (twisted nematic) mode, an IPS (in-plane-switching) mode, an FFS (fringe field switching) mode, an MVA (multi-domain vertical alignment) mode, a PVA (patterned vertical alignment) mode, an ASM (axially symmetric aligned micro-cell) mode, an OCB (optical compensated birefringence) mode, an FLC (ferroelectric liquid crystal) mode, an AFLC (antiferroelectric liquid crystal) mode, or the like can be used.

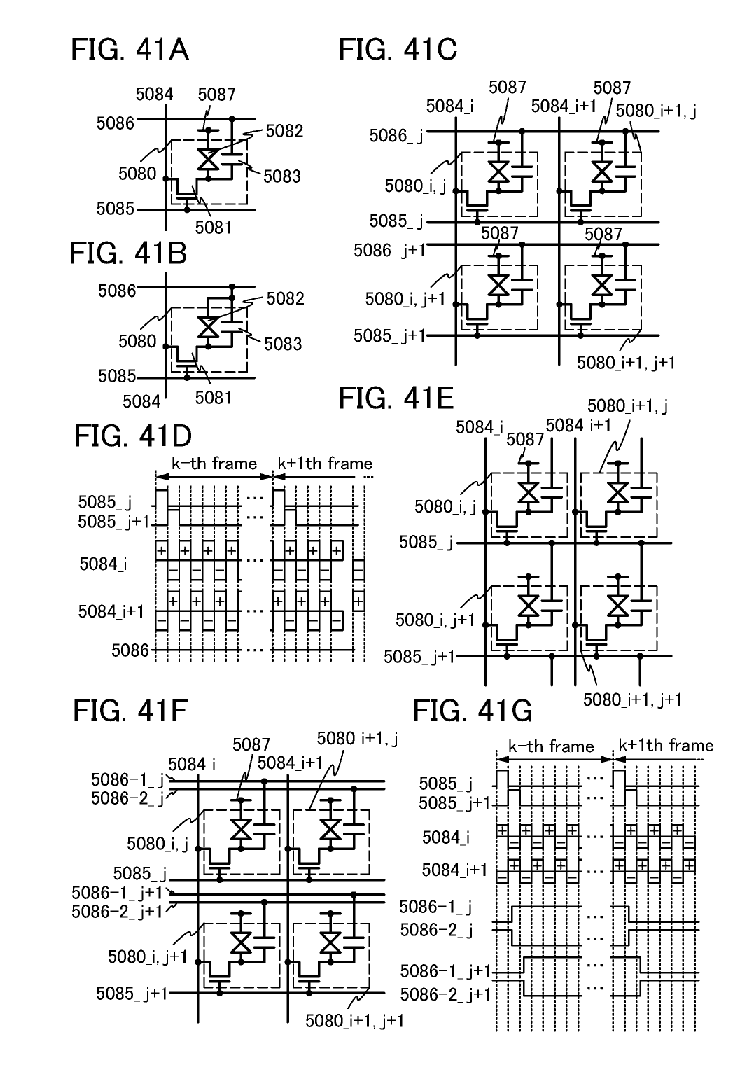

FIG. 41A is a diagram showing an example of a pixel structure which can be applied to the liquid crystal display device. A pixel 5080 includes a transistor 5081, a liquid crystal element 5082, and a capacitor 5083. A gate of the transistor 5081 is electrically connected to a wiring 5085. A first terminal of the transistor 5081 is electrically connected to a wiring 5084. A second terminal of the transistor 5081 is electrically connected to a first terminal of the liquid crystal element 5082. A second terminal of the liquid crystal element 5082 is electrically connected to a wiring 5087. A first terminal of the capacitor 5083 is electrically connected to the first terminal of the liquid crystal element 5082. A second terminal of the capacitor 5083 is electrically connected to a wiring 5086. Note that a first terminal of a transistor is one of a source and a drain, and a second terminal of the transistor is the other of the source and the drain. That is, when the first terminal of the transistor is the source, the second terminal of the transistor is the drain. Similarly, when the first terminal of the transistor is the drain, the second terminal of the transistor is the source.

The wiring 5084 can function as a signal line. The signal line is a wiring for transmitting a signal voltage, which is input from the outside of the pixel, to the pixel 5080. The wiring 5085 can function as a scan line. The scan line is a wiring for controlling on and off of the transistor 5081. The wiring 5086 can function as a capacitor line. The capacitor line is a wiring for applying a predetermined voltage to the second terminal of the capacitor 5083. The transistor 5081 can function as a switch. The capacitor 5083 can function as a storage capacitor. The storage capacitor is a capacitor with which the signal voltage continues to be applied to the liquid crystal element 5082 even when the switch is off. The wiring 5087 can function as a counter electrode. The counter electrode is a wiring for applying a predetermined voltage to the second terminal of the liquid crystal element 5082. Note that a function of each wiring is not limited thereto, and each wiring can have a variety of functions. For example, by changing a voltage applied to the capacitor line, a voltage applied to the liquid crystal element can be adjusted. Note that the transistor 5081 can be a p-channel transistor or an n-channel transistor because it merely functions as a switch.

FIG. 41B illustrates an example of a pixel structure which can be applied to the liquid crystal display device. The example of the pixel structure illustrated in FIG. 41B is the same as that in FIG. 41A except that the wiring 5087 is eliminated and the second terminal of the liquid crystal element 5082 and the second terminal of the capacitor 5083 are electrically connected to each other. The example of the pixel structure in FIG. 41B can be particularly applied to the case of using a horizontal electric field mode (including an IPS mode and FFS mode) liquid crystal element. This is because in the horizontal electric field mode liquid crystal element, the second terminal of the liquid crystal element 5082 and the second terminal of the capacitor 5083 can be formed over one substrate, and thus it is easy to electrically connect the second terminal of the liquid crystal element 5082 to the second terminal of the capacitor 5083. With the pixel structure in FIG. 41B, the wiring 5087 can be eliminated, whereby a manufacturing process can be simplified, and manufacturing costs can be reduced.

A plurality of pixel structures illustrated in FIG. 41A or FIG. 41B can be arranged in a matrix. Thus, a display portion of the liquid crystal display device is formed, so that a variety of images can be displayed. FIG. 41C illustrates a circuit configuration in the case where a plurality of pixel structures illustrated in FIG. 41A is arranged in a matrix. FIG. 41C is a diagram illustrating four pixels among a plurality of pixels included in the display portion. A pixel arranged in ith column and jth row (each of i and j is a natural number) is represented as a pixel 5080_i,j, and a wiring 5084_i, a wiring 5085_j, and a wiring 5086_j are electrically connected to the pixel 5080_i,j. Similarly, a wiring 5084_i+1, the wiring 5085_j, and the wiring 5086_j are electrically connected to a pixel 5080_i+1,j. Similarly, the wiring 5084_i, a wiring 5085_j+1, and a wiring 5086_j+1 are electrically connected to a pixel 5080_i,j+1. Similarly, the wiring 5084_i+1, the wiring 5085_j+1, and the wiring 5086_j+1 are electrically connected to a pixel 5080_i+1,j+1. Note that each wiring can be used in common with a plurality of pixels in the same row or the same column. In the pixel structure illustrated in FIG. 41C, the wiring 5087 is a counter electrode, which is used by all the pixels in common; therefore, the wiring 5087 is not indicated by the natural number i or j. Further, since the pixel structure in FIG. 41B can also be used in this embodiment, the wiring 5087 is not essential even in a structure where the wiring 5087 is described, and can be eliminated when another wiring functions as the wiring 5087, for example.

The pixel structure in FIG. 41C can be driven by a variety of driving methods. In particular, when the pixels are driven by a method called alternating-current driving, degradation (burn-in) of the liquid crystal element can be suppressed. FIG. 41D is a timing chart of voltages applied to each wiring in the pixel structure in FIG. 41C in the case where dot inversion driving which is a kind of alternating-current driving is performed. By the dot inversion driving, flickers seen when the alternating-current driving is performed can be suppressed.

In the pixel structure in FIG. 41C, a switch in a pixel electrically connected to the wiring 5085_j is brought into a selection state (an on state) in a jth gate selection period in one frame period, and into a non-selection state (an off state) in the other periods. Then, after the jth gate selection period, a (j+1)th gate selection period is provided. By performing sequential scanning in this manner, all the pixels are sequentially selected in one frame period. In the timing chart of FIG. 41D, when a voltage is at high level, the switch in the pixel is brought into a selection state; when a voltage is at low level, the switch is brought into a non-selection state. Note that this is the case where the transistors in the pixels are n-channel transistors. In the case of using p-channel transistors, the relation between the voltage and the selection state is opposite to that in the case of using n-channel transistors.

In the timing chart illustrated in FIG. 41D, in the jth gate selection period in a kth frame (k is a natural number), positive signal voltage is applied to the wiring 5084_i used as a signal line, and negative signal voltage is applied to the wiring 5084_i+1. Then, in the (j+1)th gate selection period in the kth frame, a negative signal voltage is applied to the wiring 5084_o, and a positive signal voltage is applied to the wiring 5084_i+1. After that, signals whose polarity is reversed in each gate selection period are alternately supplied to the signal line. As a result, in the kth frame, the positive signal voltage is applied to the pixels 5080_i,j and 5080_i+1,j+1, and the negative signal voltage is applied to the pixels 5080_i+1,j and 5080_i,j+1. Then, in a (k+1)th frame, a signal voltage whose polarity is opposite to that of the signal voltage written in the kth frame is written to each pixel. Thus, in the (k+1)th frame, the positive signal voltage is applied to the pixels 5080_i+1,j and 5080_i,j+1, and the negative signal voltage is applied to the pixels 5080_i,j and 5080_i+1,j+1. In such a manner, the dot inversion driving is a driving method in which signal voltages whose polarity is different between adjacent pixels are applied in one frame and the polarity of the signal voltage for the pixel is reversed in each frame. By the dot inversion driving, flickers seen when the entire or part of an image to be displayed is uniform can be suppressed while deterioration of the liquid crystal element is suppressed. Note that voltages applied to all the wirings 5086 including the wirings 5086_j and 5086_j+1 can be a fixed voltage. Moreover, only the polarity of the signal voltages for the wirings 5084 is shown in the timing chart, the signal voltages can actually have a variety of values in the polarity shown. Here, the case where the polarity is reversed per dot (per pixel) is described; however, this embodiment is not limited thereto, and the polarity can be reversed per a plurality of pixels. For example, the polarity of signal voltages to be written is reversed per two gate selection periods, whereby power consumed by writing the signal voltages can be reduced. Alternatively, the polarity may be reversed per column (source line inversion) or per row (gate line inversion).

Note that a fixed voltage may be applied to the second terminal of the capacitor 5083 in the pixel 5080 in one frame period. Since a voltage applied to the wiring 5085 used as a scan line is at low level in most one frame period, which means that a substantially constant voltage is applied to the wiring 5085; therefore, the second terminal of the capacitor 5083 in the pixel 5080 may be connected to the wiring 5085. FIG. 41E is a diagram showing an example of a pixel structure which can be applied to the liquid crystal display device. Compared to the pixel structure in FIG. 41C, a feature of the pixel structure in FIG. 41E is that the wiring 5086 is eliminated and the second terminal of the capacitor 5083 in the pixel 5080 and the wiring 5085 in the previous row are electrically connected to each other. Specifically, in the range illustrated in FIG. 41E, the second terminals of the capacitors 5083 in the pixels 5080_i, j+1 and 5080_i+1,j+1 are electrically connected to the wiring 5085_j. By electrically connecting the second terminal of the capacitor 5083 in the pixel 5080 and the wiring 5085 in the previous row in such a manner, the wiring 5086 can be eliminated, so that the aperture ratio of the pixel can be increased. Note that the second terminal of the capacitor 5083 may be connected to the wiring 5085 in another row instead of in the previous row. Note that the pixel structure in FIG. 41E can be driven by a driving method which is similar to that in the pixel structure in FIG. 41C.

Note that a voltage applied to the wiring 5084 used as a signal line can be made lower by using the capacitor 5083 and the wiring electrically connected to the second terminal of the capacitor 5083. A pixel structure and a driving method in that case will be described with reference to FIGS. 41F and 41G. Compared to the pixel structure in FIG. 41A, a feature of the pixel structure in FIG. 41F is that two wirings 5086 are provided per pixel row, and in adjacent pixels, one wiring is electrically connected to every other second terminal of the capacitors 5083 and the other wiring is electrically connected to the remaining every other second terminal of the capacitors 5083. Note that two wirings 5086 are referred to as a wiring 5086-1 and a wiring 5086-2. Specifically, in the range illustrated in FIG. 41F, the second terminal of the capacitor 5083 in the pixel 5080i,j is electrically connected to a wiring 5086-1_j; the second terminal of the capacitor 5083 in the pixel 5080_i+1,j is electrically connected to a wiring 5086-2_j; the second terminal of the capacitor 5083 in the pixel 5080i,j+1 is electrically connected to a wiring 5086-2_j+1; and the second terminal of the capacitor 5083 in the pixel 5080_i+1,j+1 is electrically connected to a wiring 5086-1_j+1.

For example, when a positive signal voltage is written to the pixel 5080_i,j in the kth frame as illustrated in FIG. 41G, the wiring 5086-1_j becomes low level, and is changed to high level after the jth gate selection period. Then, the wiring 5086-1_j is kept at high level in one frame period, and after a negative signal voltage is written in the jth gate selection period in the (k+1)th frame, the wiring 5086-1_j is changed to low level. In such a manner, a voltage of the wiring which is electrically connected to the second terminal of the capacitor 5083 is changed to the positive direction after a positive signal voltage is written to the pixel, whereby a voltage applied to the liquid crystal element can be changed to the positive direction by a predetermined amount. That is, a signal voltage written to the pixel can be reduced, so that power consumed by signal writing can be reduced. Note that when a negative signal voltage is written in the jth gate selection period, the voltage of the wiring which is electrically connected to the second terminal of the capacitor 5083 is changed to the negative direction after a negative signal voltage is written to the pixel. Accordingly, a voltage applied to the liquid crystal element can be changed to the negative direction by a predetermined amount, and the signal voltage written to the pixel can be reduced as in the case of the positive polarity. In other words, as for the wiring which is electrically connected to the second terminal of the capacitor 5083, different wirings are preferably used for a pixel to which a positive signal voltage is applied and a pixel to which a negative signal voltage is applied in the same row in one frame. FIG. 41F illustrates the example in which the wiring 5086-1 is electrically connected to the pixel to which a positive signal voltage is applied in the kth frame, and the wiring 5086-2 is electrically connected to the pixel to which a negative signal voltage is applied in the kth frame. Note that this is just an example, and for example, in the case of using a driving method in which pixels to which a positive signal voltage is applied and pixels to which a negative signal voltage is applied are arranged every two pixels, the wirings 5086-1 and 5086-2 are preferably electrically connected to every alternate two pixels accordingly. Furthermore, in the case where signal voltages of the same polarity are written in all the pixels in one row (gate line inversion), one wiring 5086 may be provided per row. In other words, in the pixel structure in FIG. 41C, the driving method where a signal voltage written to a pixel is reduced as described with reference to FIGS. 41F and 41G can be used.

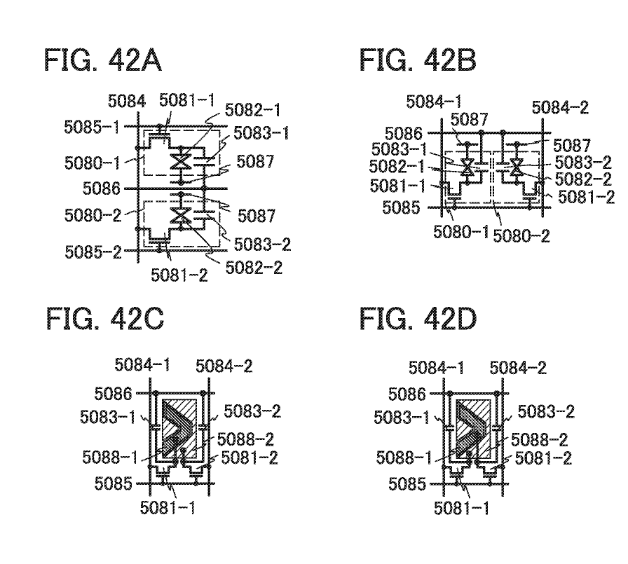

Next, a pixel structure and a driving method which are preferably employed particularly in the case where a liquid crystal element employs a vertical alignment (VA) mode typified by an MVA mode and a PVA mode. The VA mode has advantages that a rubbing process is not necessary in manufacturing, the amount of light leakage is small in displaying black images, and the level of drive voltage is low; however, the VA mode has a problem in that the quality of images deteriorates when a screen is viewed from an angle (the viewing angle is narrow). In order to widen the viewing angle in the VA mode, a pixel structure where one pixel includes a plurality of subpixels as illustrated in FIGS. 42A and 42B is effective. Pixel structures illustrated in FIGS. 42A and 42B are examples of the case where the pixel 5080 includes two subpixels (a subpixel 5080-1 and a subpixel 5080-2). Note that the number of subpixels in one pixel is not limited to two and can be other numbers. As the number of subpixels becomes larger, the viewing angle can be further broadened. A plurality of subpixels can have the same circuit configuration; here, all the subpixels have the circuit configuration illustrated in FIG. 41A. Note that the first subpixel 5080-1 includes a transistor 5081-1, a liquid crystal element 5082-1, and a capacitor 5083-1. The connection relation of each element is the same as that in the circuit configuration in FIG. 41A. In a similar manner, the second subpixel 5080-2 includes a transistor 5081-2, a liquid crystal element 5082-2, and a capacitor 5083-2. The connection relation of each element is the same as that in the circuit structure in FIG. 41A.

The pixel configuration in FIG. 42A includes, for two subpixels forming one pixel, two wirings 5085 (a wiring 5085-1 and a wiring 5085-2) used as scan lines, one wiring 5084 used as a signal line, and one wiring 5086 used as a capacitor line. When the signal line and the capacitor line are shared between two subpixels in such a manner, the aperture ratio can be increased. Further, since a signal line driver circuit can be simplified, manufacturing costs can be reduced. Moreover, since the number of connections between a liquid crystal panel and a driver circuit IC can be reduced, the yield can be increased. The pixel structure in FIG. 42B includes, for two subpixels forming one pixel, one wiring 5085 used as a scan line, two wirings 5084 (the wiring 5084-1 and the wiring 5084-2) used as signal lines, and one wiring 5086 used as a capacitor line. When the scan line and the capacitor line are shared between two subpixels in such a manner, the aperture ratio can be increased. Further, since the total number of scan lines can be reduced, one gate line selection period can be sufficiently long even in a high-definition liquid crystal panel, and an appropriate signal voltage can be written in each pixel.

FIGS. 42C and 42D illustrate an example in which the liquid crystal element in the pixel structure in FIG. 42B is replaced with the shape of a pixel electrode and electrical connections of each element are schematically shown. In FIGS. 42C and 42D, an electrode 5088-1 represents a first pixel electrode, and an electrode 5088-2 represents a second pixel electrode. In FIG. 42C, the first pixel electrode 5088-1 corresponds to a first terminal of the liquid crystal element 5082-1 in FIG. 42B, and the second pixel electrode 5088-2 corresponds to a first terminal of the liquid crystal element 5082-2 in FIG. 42B. That is, the first pixel electrode 5088-1 is electrically connected to one of a source and a drain of the transistor 5081-1, and the second pixel electrode 5088-2 is electrically connected to one of a source and a drain of the transistor 5081-2. On the other hand, in FIG. 42D, the connection relation between the pixel electrode and the transistor is opposite to that in FIG. 42C. That is, the first pixel electrode 5088-1 is electrically connected to one of the source and the drain of the transistor 5081-2, and the second pixel electrode 5088-2 is electrically connected to one of the source and the drain of the transistor 5081-1.

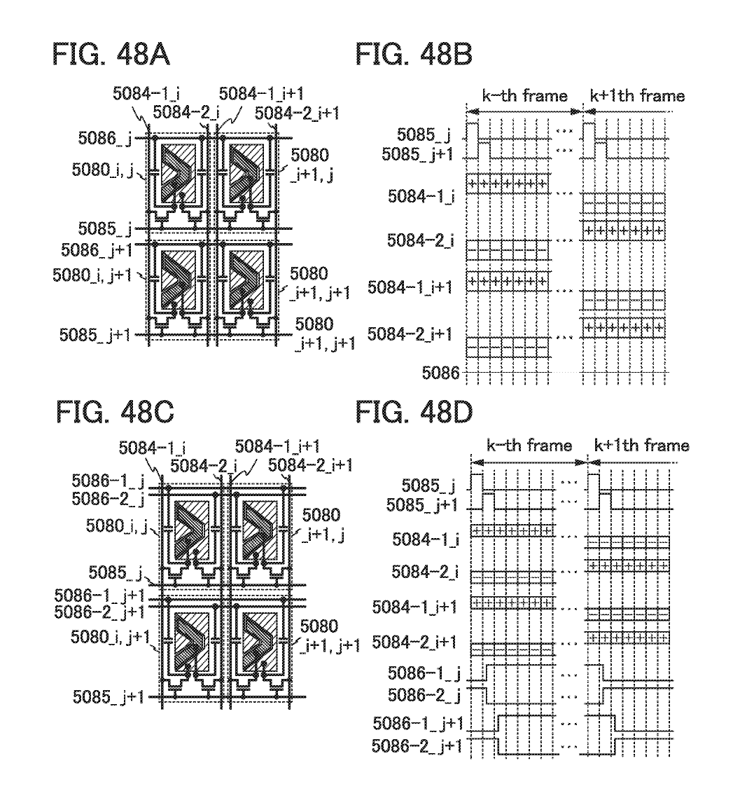

By arranging a plurality of pixel configurations as illustrated in FIG. 42C or FIG. 42D in a matrix, an extraordinary effect can be obtained. FIGS. 48A and 48B illustrate an example of such a pixel configuration and driving method. In the pixel structure in FIG. 48A, portions corresponding to the pixels 5080_i,j and 5080_i+1,j+1 have the structure illustrated in FIG. 42C, and portions corresponding to the pixels 5080_i+1,j and 5080_i,j+1 have the structure illustrated in FIG. 42D. In this structure, by performing driving as the timing chart illustrated in FIG. 48B, in the jth gate selection period in the kth frame, positive signal voltage is written to the first pixel electrode in the pixel 5080_i,j and the second pixel electrode in the pixel 5080_i+1,j, and negative signal voltage is written to the second pixel electrode in the pixel 5080_i,j and the first pixel electrode in the pixel 5080_i+1,j. Then, in the (j+1)th gate selection period in the kth frame, a positive signal voltage is written to the second pixel electrode in the pixel 5080_i,j+1 and the first pixel electrode in the pixel 5080_i+1,j+1, and a negative signal voltage is written to the first pixel electrode in the pixel 5080_i,j+1 and the second pixel electrode in the pixel 5080_i+1,j+1. In the (k+1)th frame, the polarity of the signal voltage is reversed in each pixel. Accordingly, the polarity of the voltage applied to the signal line can be the same in one frame period while driving corresponding to dot inversion driving is realized in the pixel structure including subpixels, whereby power consumed by writing the signal voltages to the pixels can be drastically reduced. Note that voltages applied to all the wirings 5086 including the wirings 5086_j and 5086_j+1 can be a fixed voltage.

Further, by a pixel structure and a driving method illustrated in FIGS. 48C and 48D, the level of the signal voltage written to a pixel can be reduced. In the structure, a plurality of subpixels included in each pixel are electrically connected to respective capacitor lines. That is, according to the pixel structure and the driving method illustrated in FIGS. 48A and 48B, one capacitor line is shared between subpixels in one row, to which signal voltages of the same polarity are written in one frame; and subpixels to which signal voltages of the different polarities are written in one frame use different capacitor lines in one row. Then, when writing in each row is finished, voltages of the capacitor lines are changed to the positive direction in the subpixels to which a positive signal voltage is written, and changed to the negative direction in the subpixels to which a negative signal voltage is written; thus, the level of the signal voltage written to the pixel can be reduced. Specifically, two wirings 5086 (the wirings 5086-1 and 5086-2) used as capacitor lines are provided per row. The first pixel electrode in the pixel 5080_i,j and the wiring 5086-1_j are electrically connected to each other through the capacitor. The second pixel electrode in the pixel 5080_i,j and the wiring 5086-2_j are electrically connected to each other through the capacitor. The first pixel electrode in the pixel 5080_i+1,j and the wiring 5086-2_j are electrically connected to each other through the capacitor. The second pixel electrode in the pixel 5080_i+1,j and the wiring 5086-1_j are electrically connected to each other through the capacitor. The first pixel electrode in the pixel 5080_i,j+1 and the wiring 5086-2_j+1 are electrically connected to each other through the capacitor. The second pixel electrode in the pixel 5080_i,j+1 and the wiring 5086-1_j+1 are electrically connected to each other through the capacitor. The first pixel electrode in the pixel 5080_i+1,j+1 and the wiring 5086-1_j+1 are electrically connected to each other through the capacitor. The second pixel electrode in the pixel 5080_i+1,j+1 and the wiring 5086-2_j+1 are electrically connected to each other through the capacitor. Note that this is just an example, and for example, in the case of using a driving method in which pixels to which a positive signal voltage is applied and pixels to which a negative signal voltage is applied are arranged every two pixels, the wirings 5086-1 and 5086-2 are preferably electrically connected to every alternate two pixels accordingly. Furthermore, in the case where signal voltages of the same polarity are written in all the pixels in one row (gate line inversion), one wiring 5086 may be provided per row. In other words, in the pixel structure in FIG. 48A, the driving method where a signal voltage written to a pixel is reduced as described with reference to FIGS. 48C and 48D can be used.

### Embodiment 11

Next, another structure example and a driving method of a display device will be described. In this embodiment, the case of using a display device including a display element whose luminance response with respect to signal writing is slow (the response time is long) will be described. In this embodiment, a liquid crystal element is described as an example of the display element with long response time; however, a display element in this embodiment is not limited thereto, and a variety of display elements in which luminance response with respect to signal writing is slow can be used.

In a general liquid crystal display device, luminance response with respect to signal writing is slow, and it sometimes takes more than one frame period to complete the response even when a signal voltage continues to be applied to a liquid crystal element. Moving images cannot be precisely displayed by such a display element. Further, in the case of employing active matrix driving, the time for signal writing to one liquid crystal element is only a period (one scan line selection period) obtained by dividing a signal writing cycle (one frame period or one subframe period) by the number of scan lines, and the liquid crystal element cannot respond in such a short time in many cases. Therefore, most of the response of the liquid crystal element is performed in a period during which signal writing is not performed. Here, the dielectric constant of the liquid crystal element is changed in accordance with the transmittance of the liquid crystal element, and the response of the liquid crystal element in a period during which signal writing is not performed means that the dielectric constant of the liquid crystal element is changed in a state where electric charge is not exchanged with the outside of the liquid crystal element (in a constant charge state). In other words, in the formula where charge=(capacitance)·(voltage), the capacitance is changed in a state where the charge is constant. Accordingly, a voltage applied to the liquid crystal element is changed from a voltage at the time of signal writing, in accordance with the response of the liquid crystal element. Therefore, when the liquid crystal element whose luminance response with respect to signal writing is slow is driven by an active matrix mode, a voltage applied to the liquid crystal element cannot theoretically reach the voltage at the time of signal writing.

In a display device in this embodiment, the signal level at the time of signal writing is corrected in advance (a correction signal is used) so that a display element can reach desired luminance within a signal writing cycle, whereby the above problem can be solved. Further, since the response time of the liquid crystal element is shorter as the signal level becomes higher, the response time of the liquid crystal element can also be shorter by writing a correction signal. A driving method in which such a correction signal is added is referred to as overdriving. By overdriving in this embodiment, even when a signal writing cycle is shorter than a cycle for an image signal input to the display device (an input image signal cycle Tᵢₙ), the signal level is corrected in accordance with the signal writing cycle, whereby the display element can reach desired luminance within the signal writing cycle. The case where the signal writing cycle is shorter than the input image signal cycle Tᵢₙ is, for example, the case where one original image is divided into a plurality of subimages and the plurality of subimages are sequentially displayed in one frame period.

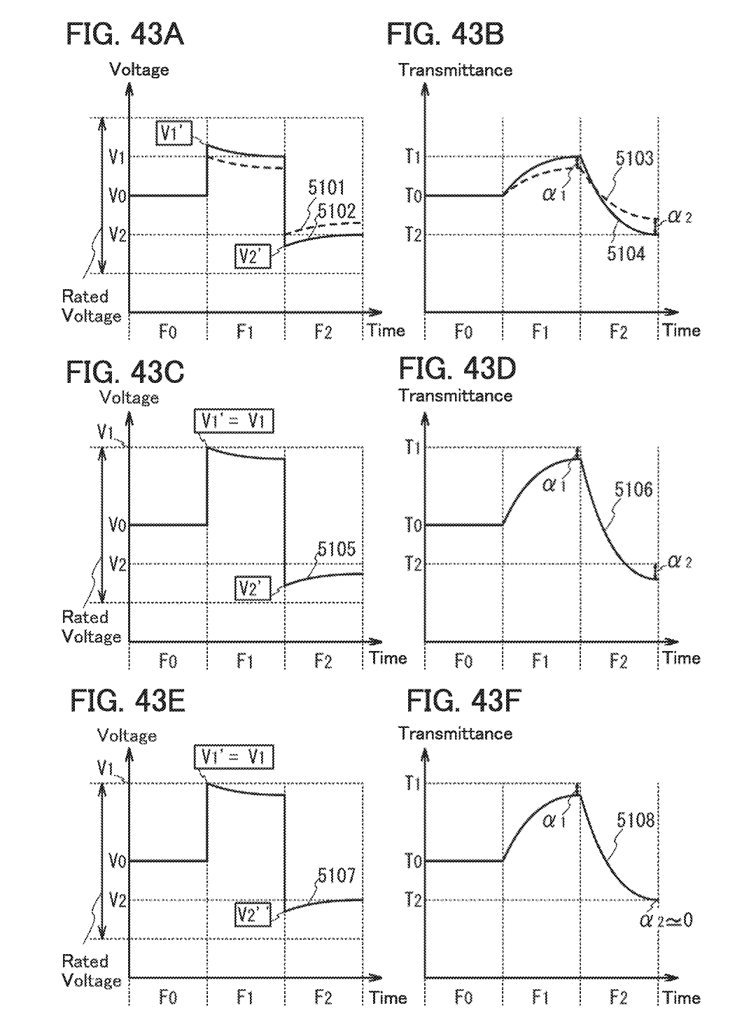

Next, an example of correcting the signal level at the time of signal writing in an active matrix display device will be described with reference to FIGS. 43A and 43B. FIG. 43A is a graph schematically illustrating a time change in luminance of signal level in signal writing in one display element, with the time as the horizontal axis and the signal level in signal writing as the vertical axis. FIG. 43B is a graph schematically illustrating change over time in display level, with the time as the horizontal axis and the display level as the vertical axis. Note that when the display element is a liquid crystal element, the signal level at the time of signal writing can be the voltage, and the display level can be the transmittance of the liquid crystal element. In the following description, the vertical axis in FIG. 43A is regarded as the voltage, and the vertical axis in FIG. 43B is regarded as the transmittance. Note that in the overdriving in this embodiment, the signal level may be other than the voltage (may be the duty ratio or current, for example). Moreover, in the overdriving in this embodiment, the display level may be other than the transmittance (may be luminance or current, for example). Liquid crystal elements are classified into two modes: a normally black mode in which black is displayed when a voltage is 0 (e.g., a VA mode and an IPS mode), and a normally white mode in which white is displayed when a voltage is 0 (e.g., a TN mode and an OCB mode). The graph illustrated in FIG. 43B can correspond to both modes; the transmittance increases in the upper part of the graph in the normally black mode, and the transmittance increases in the lower part of the graph in the normally white mode. That is, a liquid crystal mode in this embodiment may be a normally black mode or a normally white mode. Note that the timing of signal writing is represented on the time axis by dotted lines, and a period after signal writing is performed until the next signal writing is performed is referred to as a retention period Fᵢ. In this embodiment, i is an integer and an index for representing each retention period. In FIGS. 43A and 43B, i is 0 to 2; however, i can be an integer other than 0 to 2 (only the case where i is 0 to 2 is illustrated). Note that in the retention period Fᵢ, the transmittance for realizing luminance corresponding to an image signal is denoted by Tᵢ and the voltage for providing the transmittance Tᵢ in a constant state is denoted by Vᵢ. In FIG. 43A, a dashed line 5101 represents a time change in voltage applied to the liquid crystal element in the case where overdrive is not performed, and a solid line 5102 represents a time change in voltage applied to the liquid crystal element in the case where the overdrive in this embodiment is performed. In a similar manner, in FIG. 43B, a dashed line 5103 represents a time change in transmittance of the liquid crystal element in the case where overdrive is not performed, and a solid line 5104 represents a time change in transmittance of the liquid crystal element in the case where the overdrive in this embodiment is performed. Note that the difference between the desired transmittance Tᵢ and the actual transmittance at the end of the retention period Fᵢ is referred to as an error αᵢ.

It is assumed that, in the graph illustrated in FIG. 43A, both of the dashed line 5101 and the solid line 5102 represent the case where desired voltage V₀ is applied in a retention period F₀; and in the graph illustrated in FIG. 43B, both of the dashed line 5103 and the solid line 5104 represent the case where desired transmittance T₀ is obtained. When overdriving is not performed, a desired voltage V₁ is applied at the beginning of a retention period F₁ as shown by the dashed line 5101. As has been described above, a period for signal writing is extremely shorter than a retention period, and the liquid crystal element is in a constant charge state in most of the retention period. Accordingly, a voltage applied to the liquid crystal element in the retention period F₁ is changed along with change in transmittance and becomes greatly different from the desired voltage V₁ at the end of the retention period F₁. In this case, the dashed line 5103 in the graph of FIG. 43B is greatly different from desired transmittance T₁. Accordingly, accurate display of an image signal cannot be performed, and thus the image quality is degraded. On the other hand, when the overdriving in this embodiment is performed, a voltage V₁′ which is higher than the desired voltage V₁ is applied to the liquid crystal element at the beginning of the retention period F₁ as shown by the solid line 5102. That is, the voltage V₁′ which is corrected from the desired voltage V₁ is applied to the liquid crystal element at the beginning of the retention period F₁ so that the voltage applied to the liquid crystal element at the end of the retention period F₁ is close to the desired voltage V₁ in anticipation of gradual change in voltage applied to the liquid crystal element in the retention period F₁. Accordingly, the desired voltage V₁ can be accurately applied to the liquid crystal element. At this time, as shown by the solid line 5104 in the graph of FIG. 43B, the desired transmittance T₁ can be obtained at the end of the retention period F₁. In other words, the response of the liquid crystal element within the signal writing cycle can be realized, despite the fact that the liquid crystal element is in a constant charge state in most of the retention period. Then, in a retention period F₂, the case where a desired voltage V₂ is lower than V₁ is shown. In that case also, as in the retention period F₁, a voltage V₂′ which is corrected from the desired voltage V₂ may be applied to the liquid crystal element at the beginning of the retention period F₂ so that the voltage applied to the liquid crystal element at the end of the retention period F₂ is close to the desired voltage V₂ in anticipation of gradual change in voltage applied to the liquid crystal element in the retention period F₂. Thus, as shown by the solid line 5104 in the graph of FIG. 43B, desired transmittance T₂ can be obtained at the end of the retention period F₂. Note that when V, is higher than Vᵢ₋₁, like in the retention period F₁, the corrected voltage Vᵢ′ is preferably corrected to be higher than a desired voltage Vᵢ. Further, when Vᵢ is lower than Vᵢ₋₁, like in the retention period F₂, the corrected voltage Vᵢ′ is preferably corrected to be lower than the desired voltage Vᵢ. A specific correction value can be derived by measuring response characteristics of the liquid crystal element in advance. As a method of realizing the overdriving in the device, a method in which a correction formula is formulated and included in a logic circuit, a method in which a correction value is stored in a memory as a lookup table and read as necessary, or the like can be used.

Note that there are several limitations on the actual realization of the overdriving in this embodiment as a device. For example, voltage correction has to be performed in the range of the rated voltage of a source driver. That is, if a desired voltage is originally high and an ideal correction voltage exceeds the rated voltage of the source driver, not all correction can be performed. Problems in such a case will be described with reference to FIGS. 43C and 43D. As in FIG. 43A, FIG. 43C is a graph in which change over time in voltage in one liquid crystal element is schematically illustrated as a solid line 5105 with the time as the horizontal axis and the voltage as the vertical axis. As in FIG. 43B, FIG. 43D is a graph in which change over time in transmittance of one liquid crystal element is schematically illustrated as a solid line 5106 with the time as the horizontal axis and the transmittance as the vertical axis. Note that other references are similar to those in FIGS. 43A and 43B; therefore, the description is not repeated. FIGS. 43C and 43D illustrate a state where sufficient correction is not performed because the correction voltage V for realizing the desired transmittance T₁ in the retention period F₁ exceeds the rated voltage of the source driver, and thus V₁′=V₁ has to be given. At this time, the transmittance at the end of the retention period F₁ is deviated from the desired transmittance T₁ by the error α₁. Note that the error α₁ is increased only when the desired voltage is originally high; therefore, degradation of image quality due to occurrence of the error α₁ is often in the allowable range. However, as the error α₁ is increased, an error in the algorithm for voltage correction is also increased. In other words, in the algorithm for voltage correction, when it is assumed that the desired transmittance is obtained at the end of the retention period, even though the error α₁ is increased, the voltage correction is performed on the basis that the error α₁ is small. Accordingly, the error is included in the correction in the next retention period F₂, and thus, an error α₂ is also increased. Moreover, when the error α₂ is increased, the following error α₃ is further increased, for example, and the error is increased in a chain reaction manner, resulting in significant degradation of image quality. In the overdriving in this embodiment, in order to prevent increase of errors in such a chain reaction manner, when the correction voltage Vᵢ′ exceeds the rated voltage of the source driver in the retention period Fᵢ, an error α at the end of the retention period Fᵢ is assumed, and the correction voltage in a retention period Fᵢ₊₁ can be adjusted in consideration of the amount of the error αᵢ. Accordingly, even when the error αᵢ is increased, the effect of the error α on the error αᵢ₊₁ can be minimized, whereby increase of errors in a chain reaction manner can be prevented. An example where the error α₂ is minimized in the overdriving in this embodiment will be described with reference to FIGS. 43E and 43F. In a graph of FIG. 43E, a solid line 5107 represents change over time in voltage in the case where the correction voltage V₂′ in the graph of FIG. 43C is further adjusted to be a correction voltage V₂″. A graph of FIG. 43F illustrates change over time in transmittance in the case where a voltage is corrected in accordance with the graph of FIG. 43E. The solid line 5106 in the graph of FIG. 43D indicates that excessive correction is caused by the correction voltage V₂′. On the other hand, the solid line 5108 in the graph of FIG. 43F indicates that excessive correction is suppressed by the correction voltage V₂″ which is adjusted in consideration of the error α₁ and the error α₂ is minimized. A specific correction value can be derived by measuring response characteristics of the liquid crystal element in advance. As a method of realizing the overdriving in the device, a method in which a correction formula is formulated and included in a logic circuit, a method in which a correction value is stored in a memory as a lookup table and read as necessary, or the like can be used. Moreover, such a method can be added separately from a portion for calculating a correction voltage Vᵢ′ or included in the portion for calculating a correction voltage Vᵢ′. Note that the amount of correction of a correction voltage Vᵢ″ which is adjusted in consideration of an error αᵢ₋₁ (the difference with the desired voltage V) is preferably smaller than that of Vᵢ′. That is, |Vᵢ″−Vᵢ|<|Vᵢ′−Vᵢ| is preferable.

Note that the error αᵢ which is caused because an ideal correction voltage exceeds the rated voltage of the source driver is increased as a signal writing cycle is shorter. This is because the response time of the liquid crystal element needs to be shorter as the signal writing cycle is shorter, and thus, the higher correction voltage is necessary. Further, as a result of increasing the correction voltage needed, the correction voltage exceeds the rated voltage of the source driver more frequently, whereby the large error α, occurs more frequently. Therefore, the overdriving in this embodiment is more effective as the signal writing cycle is shorter. Specifically, the overdriving in this embodiment is significantly effective in the case of performing the following driving methods, for example, the case where one original image is divided into a plurality of subimages and the plurality of subimages is sequentially displayed in one frame period, the case where motion of an image is detected from a plurality of images and an intermediate image of the plurality of images is generated and inserted between the plurality of images (so-called motion compensation double-frame rate driving), and the case where such driving methods are combined.

Note that a rated voltage of the source driver has the lower limit in addition to the upper limit described above. An example of the lower limit is the case where a voltage lower than the voltage 0 cannot be applied. In this case, since ideal correction voltage cannot be applied as in the case of the upper limit described above, the error α, is increased. However, in that case also, the error αᵢ at the end of the retention period Fᵢ is assumed, and the correction voltage in the retention period Fᵢ₊₁ can be adjusted in consideration of the amount of the error α, in a similar manner as the above method. Note that when a voltage lower than the voltage 0 (a negative voltage) can be applied as a rated voltage of the source driver, the negative voltage may be applied to the liquid crystal element as a correction voltage. Accordingly, the voltage applied to the liquid crystal element at the end of retention period Fᵢ can be adjusted to be close to the desired voltage V, in anticipation of change in potential due to a constant charge state.

In addition, in order to suppress degradation of the liquid crystal element, so-called inversion driving in which the polarity of a voltage applied to the liquid crystal element is periodically reversed can be performed in combination with the overdriving. That is, the overdriving in this embodiment includes, in its category, the case where the overdriving is performed at the same time as the inversion driving. For example, in the case where the length of the signal writing cycle is ½ of that of the input image signal cycle Tᵢₙ, when the length of a cycle for reversing the polarity is approximately the same as that of the input image signal cycle Tᵢₙ, two sets of writing of a positive signal and two sets of writing of a negative signal are alternately performed. The length of the cycle for reversing the polarity is made larger than that of the signal writing cycle in such a manner, whereby the frequency of charge and discharge of a pixel can be reduced, and thus power consumption can be reduced. Note that when the cycle for reversing the polarity is made too long, a defect sometimes occurs in which luminance difference due to the difference of polarity is recognized as a flicker; therefore, it is preferable that the length of the cycle for reversing the polarity is substantially the same as or smaller than that of the input image signal cycle Tᵢₙ.

### Embodiment 12

Next, another structure example and a driving method of a display device will be described. In this embodiment, a method will be described in which an image that compensates motion of an image (an input image) which is input from the outside of a display device is generated inside the display device based on a plurality of input images and the generated image (the generation image) and the input image are sequentially displayed. Note that an image for interpolating motion of an input image serves as a generation image, motion of moving images can be smooth, and degradation of quality of moving images because of afterimages or the like due to hold driving can be suppressed. Here, moving image interpolation will be described below. Ideally, display of moving images is realized by controlling the luminance of each pixel in real time; however, individual control of pixels in real time has problems such as the enormous number of control circuits, space for wirings, and the enormous amount of data of input images, and thus is difficult to be realized. Therefore, for display of moving images by a display device, a plurality of still images are sequentially displayed in a certain cycle so that display appears to be moving images. The cycle (in this embodiment, referred to as an input image signal cycle and represented by Tᵢₙ) is standardized, and for example, 1/60 second in NTSC and 1/50 second in PAL. Such a cycle does not cause a problem of moving image display in a CRT which is an impulse-type display device. However, in a hold-type display device, when moving images conforming to these standards are displayed as they are, a defect (hold blur) in which display is blurred because of afterimages or the like due to hold driving occurs. Hold blur is recognized by the discrepancy between unconscious motion interpolation due to human eye tracking and hold-type display, and thus can be reduced by making the input image signal cycle shorter than that in the conventional standards (by making the control closer to individual control of pixels in real time). However, it is difficult to reduce the length of the input image signal cycle because the standard needs to be changed and the amount of data is further increased. Note that an image for interpolating motion of an input image is generated inside the display device based on a standardized input image signal, and display is performed while the generation image interpolates the input image, whereby hold blur can be reduced without change of the standard or increase of the amount of data. An operation such that an image signal is generated inside the display device based on an input image signal to interpolate motion of the input image is referred to as moving image interpolation.

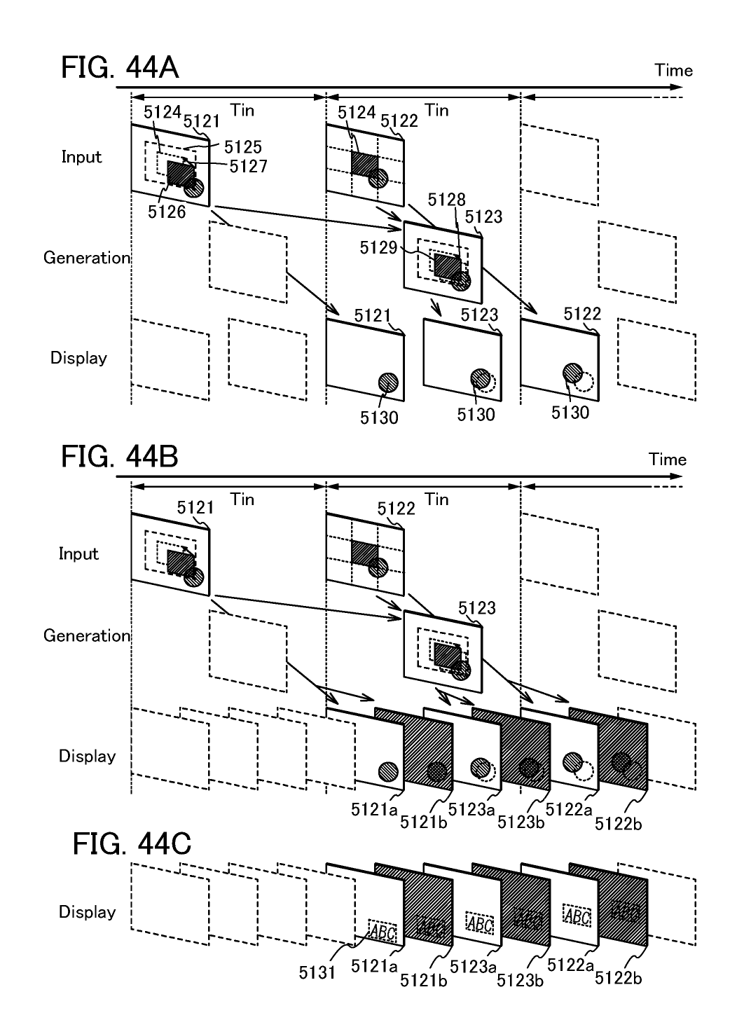

By a method for interpolating moving images in this embodiment, motion blur can be reduced. The method for interpolating moving images in this embodiment can include an image generation method and an image display method. Moreover, by using another image generation method and/or image display method for motion with a specific pattern, motion blur can be effectively reduced. FIGS. 44A and 44B are schematic diagrams each illustrating an example of a method for interpolating moving images in this embodiment. FIGS. 44A and 44B each illustrate the timing of treating each image using the position of the horizontal direction, with the time as the horizontal axis. A portion represented as “input” indicates the timing when an input image signal is input. Here, an image 5121 and 5122 are focused as two images that are temporally adjacent. An input image is input at an interval of the cycle Tᵢₙ. Note that the length of one cycle Tᵢₙ is sometimes referred to as one frame or one frame period. A portion represented as “generation” indicates the timing when a new image is generated from the input image signal. Here, an image 5123 which is a generation image generated based on the images 5121 and 5122 is focused. A portion represented as “display” indicates the timing when an image is displayed in the display device. Note that images other than the focused images are only represented by dashed lines, and by treating such images in a manner similar to that of the focused image, the example of the method for interpolating moving images in this embodiment can be realized.

In the example of the method for interpolating moving images in this embodiment, as illustrated in FIG. 44A, a generation image which is generated based on two input images that are temporally adjacent is displayed in a period after one image is displayed until the other image is displayed, whereby moving image interpolation can be performed. At this time, a display cycle of the display image is preferably ½ of an input cycle of the input image. Note that the display cycle is not limited thereto and can be a variety of display cycles. For example, when the length of the display cycle is smaller than ½ of that of the input cycle, moving images can be displayed more smoothly. Alternatively, when the length of the display cycle is larger than ½ of that of the input cycle, power consumption can be reduced. Note that here, an image is generated based on two input images that are temporally adjacent; however, the number of input images serving as a basis is not limited to two and can be other numbers. For example, when an image is generated based on three (may be more than three) input images that are temporally adjacent, a generation image with higher accuracy can be obtained as compared to the case where an image is generated based on two input images. Note that the display timing of the image 5121 is the same time as the input timing of the image 5122, that is, the display timing is one frame later than the input timing. However, the display timing in the method for interpolating moving images in this embodiment is not limited thereto and can be a variety of display timings. For example, the display timing can be delayed with respect to the input timing by more than one frame. Accordingly, the display timing of the image 5123 which is the generation image can be delayed, which allows enough time to generate the image 5123 and leads to reduction in power consumption and manufacturing costs. Note that when the display timing is delayed for a long time as compared to the input timing, a period for holding an input image is longer, and the memory capacity necessary for holding the input image is increased. Therefore, the display timing is preferably delayed with respect to the input timing by approximately one to two frames.

Here, an example of a specific generation method of the image 5123 which is generated based on the images 5121 and 5122 is described. It is necessary to detect motion in an input image in order to interpolate moving images. In this embodiment, a method called a block matching method can be used in order to detect motion in an input image. Note that this embodiment is not limited thereto, and a variety of methods (e.g., a method of obtaining the difference of image data or a method of using Fourier transformation) can be used. In the block matching method, first, image data for one input image (here, image data of the image 5121) is stored in a data storage means (e.g., a memory circuit such as a semiconductor memory or a RAM). Then, an image in the next frame (here, the image 5122) is divided into a plurality of regions. Note that the divided regions can have the same rectangular shape as illustrated in FIG. 44A; however, they are not limited thereto and can have a variety of shapes (e.g., the shape or size varies depending on images). After that, in each divided region, the data is compared with the image data in the previous frame (here, the image data of the image 5121), which is stored in the data storage means, so as to search for a region where the image data is similar thereto. The example of FIG. 44A illustrates that the image 5121 is searched for a region where data is similar to that of a region 5124 in the image 5122, and a region 5126 is found. Note that a search range is preferably limited when the image 5121 is searched. In the example of FIG. 44A, a region 5125 which is approximately four times larger than the region 5124 is set as the search range. By making the search range larger than this, detection accuracy can be increased even in a moving image with high-speed motion. Note that search in an excessively wide range needs an enormous amount of time, which makes it difficult to realize detection of motion. Accordingly, the region 5125 has preferably approximately two to six times larger than the area of the region 5124. After that, the difference of the position between the searched region 5126 and the region 5124 in the image 5122 is obtained as a motion vector 5127. The motion vector 5127 represents motion of image data in the region 5124 in one frame period. Then, in order to generate an image showing an intermediate state of motion, an image generation vector 5128 obtained by changing the size of the motion vector without changing the direction thereof is generated, and image data included in the region 5126 of the image 5121 is moved in accordance with the image generation vector 5128, whereby image data in a region 5129 of the image 5123 is generated. By performing a series of processings on the entire region of the image 5122, the image 5123 can be generated. Then, by sequentially displaying the input image 5121, the generation image 5123, and the input image 5122, moving images can be interpolated. Note that the position of an object 5130 in the image is different (i.e., the object is moved) in the images 5121 and 5122. In the generated image 5123, the object is located at the midpoint between the images 5121 and 5122. By displaying such images, motion of moving images can be smooth, and blur of moving images due to afterimages or the like can be reduced.

Note that the size of the image generation vector 5128 can be determined in accordance with the display timing of the image 5123. In the example of FIG. 44A, since the display timing of the image 5123 is the midpoint (½) between the display timings of the images 5121 and 5122, the size of the image generation vector 5128 is ½ of that of the motion vector 5127. Alternatively, for example, when the display timing is at the first ⅓ of the cycle Tᵢₙ, the size of the image generation vector 5128 can be ⅓; and when the display timing is at the latter ⅔ of the cycle Tᵢₙ, the size can be ⅔.

Note that when a new image is generated by moving a plurality of regions having different motion vectors in such a manner, a portion where one region is already moved to a region that is a destination for another region or a portion to which any region is not moved sometimes occur (i.e., overlap or blank sometimes occurs). For such portions, data can be compensated. As a method for compensating an overlap portion, a method where overlap data are averaged; a method where data is arranged in order of priority according to the direction of motion vectors or the like, and high-priority data is used as data in a generation image; or a method where one of color and brightness is arranged in order of priority and the other is averaged can be used, for example. As a method for compensating a blank portion, a method where image data for the portion of the image 5121 or the image 5122 is used as data in a generation image without modification, a method where image data for the portion of the image 5121 or the image 5122 is averaged, or the like can be used. Then, the generated image 5123 is displayed in accordance with the size of the image generation vector 5128, whereby motion of moving images can be smooth, and degradation of quality of moving images because of afterimages or the like due to hold driving can be suppressed.

In another example of the method for interpolating moving images in this embodiment, as illustrated in FIG. 44B, when a generation image which is generated based on two input images that are temporally adjacent is displayed in a period after one image is displayed until the other image is displayed, each display image is divided into a plurality of subimages to be displayed, whereby moving image can be interpolated. This case can have advantages of displaying a dark image at regular intervals (advantages when a display method comes closer to impulse-type display) in addition to advantages of a shorter image display cycle. That is, blur of moving images due to afterimages or the like can further be reduced as compared to the case where the length of the image display cycle is just made to ½ of that of the image input cycle. In the example of FIG. 44B, “input” and “generation” can be similar to the processings in the example of FIG. 44A; therefore, the description is not repeated. For “display” in the example of FIG. 44B, one input image and/or one generation image can be divided into a plurality of subimages to be displayed. Specifically, as illustrated in FIG. 44B, the image 5121 is divided into subimages 5121a and 5121b and the subimages 5121a and 5121b are sequentially displayed so as to make human eyes perceive that the image 5121 is displayed; the image 5123 is divided into subimages 5123a and 5123b and the subimages 5123a and 5123b are sequentially displayed so as to make human eyes perceive that the image 5123 is displayed; and the image 5122 is divided into subimages 5122a and 5122b and the subimages 5122a and 5122b are sequentially displayed so as to make human eyes perceive that the image 5122 is displayed. That is, a display method can be closer to impulse-type display while the image perceived by the human eye is similar to that in the example of FIG. 44A, whereby blur of moving images due to afterimages or the like can further be reduced. Note that the number of division of subimages is two in FIG. 44B; however, it is not limited thereto and can be other numbers. Note that subimages are displayed at regular intervals (½) in FIG. 44B; however, timing of displaying subimages is not limited to this and can be a variety of timings. For example, when the timing of displaying dark subimages (5121b, 5122b, and 5123b) is made earlier (specifically, the timing at ¼ to ½), a display method can be much closer to impulse-type display, whereby blur of moving images due to afterimages or the like can further be reduced. Alternatively, when the timing of displaying dark subimages is delayed (specifically, the timing at ½ to ¾), the length of a period for displaying a bright image can be increased, whereby display efficiency can be increased, and power consumption can be reduced.

Another example of the method for interpolating moving images in this embodiment is an example in which the shape of an object moved in an image is detected and different processings are performed depending on the shape of the moving object. FIG. 44C illustrates the display timing as in the example of FIG. 44B and the case where moving characters (also referred to as scrolling texts, subtitles, captions, or the like) are displayed. Note that since “input” and “generation” may be similar to those in FIG. 44B, they are not shown in FIG. 44C. The amount of blur of moving images by hold driving sometimes varies depending on properties of a moving object. In particular, blur is often recognized remarkably when characters are moved. This is because the eye follows moving characters to read the characters, and thus hold blur is likely to occur. Further, since characters often have clear outlines, blur due to hold blur is further emphasized in some cases. That is, to determine whether an object moved in an image is a character and to perform a special processing when the object is the character are effective in reducing in hold blur. Specifically, when edge detection, pattern detection, and/or the like is/are performed on an object moved in an image and the object is determined to be a character, motion compensation is performed even on subimages generated by dividing one image so that an intermediate state of motion is displayed, whereby motion can be smooth. In the case where the object is determined not to be a character, when subimages are generated by division of one image as illustrated in FIG. 44B, the subimages can be displayed without a change in the position of the moving object. The example of FIG. 44C illustrates the case where a region 5131 determined to be characters is moved upward, and the position of the region 5131 is different between the images 5121a and 5121b. Similarly, the position of the region 5131 is different between the images 5123a and 5123b, and between the images 5122a and 5122b. Accordingly, motion of characters for which hold blur is particularly likely to be recognized can be smoother than that by normal motion compensation double-frame rate driving, whereby blur of moving images due to afterimages or the like can further be reduced.

### Embodiment 13

A semiconductor device can be applied to a variety of electronic devices (including a game machine). Examples of electronic devices are a television device (also referred to as a television or a television receiver), a monitor of a computer or the like, a camera such as a digital camera or a digital video camera, a digital photo frame, a mobile phone handset (also referred to as a mobile phone or a mobile phone device), a portable game console, a portable information terminal, an audio reproducing device, a large-sized game machine such as a pachinko machine, and the like.

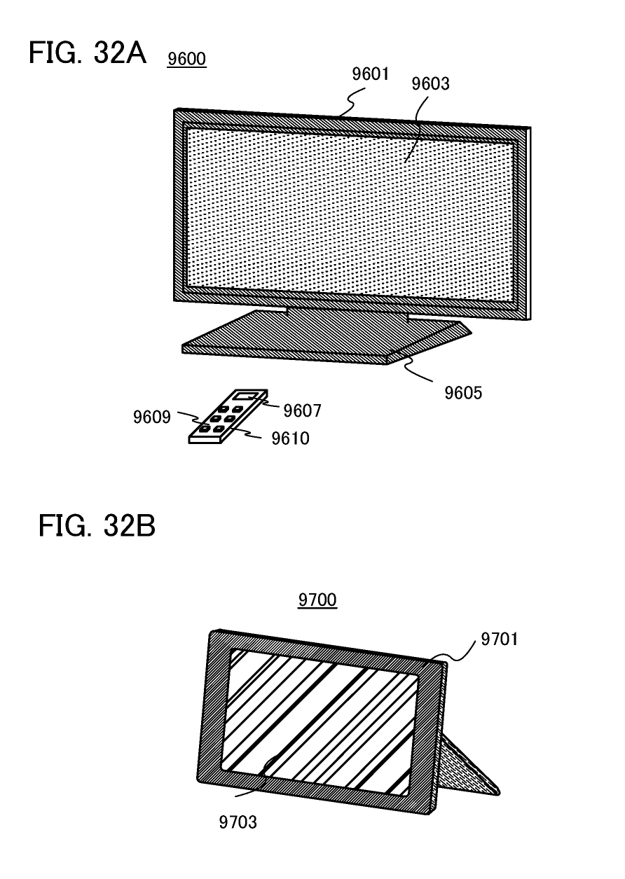

FIG. 32A illustrates an example of a television device 9600. In the television device 9600, a display portion 9603 is incorporated in a housing 9601. The display portion 9603 can display images. Here, the housing 9601 is supported by a stand 9605.

The television device 9600 can be operated with an operation switch of the housing 9601 or a separate remote controller 9610. Channels and volume can be controlled with an operation key 9609 of the remote controller 9610 so that an image displayed on the display portion 9603 can be controlled. Furthermore, the remote controller 9610 may be provided with a display portion 9607 for displaying data output from the remote controller 9610.

Note that the television device 9600 is provided with a receiver, a modem, and the like. With the use of the receiver, general television broadcasting can be received. Moreover, when the display device is connected to a communication network with or without wires via the modem, one-way (from a sender to a receiver) or two-way (between a sender and a receiver or between receivers) information communication can be performed.

FIG. 32B illustrates an example of a digital photo frame 9700. For example, in the digital photo frame 9700, a display portion 9703 is incorporated in a housing 9701. The display portion 9703 can display a variety of images. For example, the display portion 9703 can display data of an image taken with a digital camera or the like and function as a normal photo frame

Note that the digital photo frame 9700 is provided with an operation portion, an external connection portion (a USB terminal, a terminal that can be connected to various cables such as a USB cable, or the like), a recording medium insertion portion, and the like. Although these components may be provided on the surface on which the display portion is provided, it is preferable to provide them on the side surface or the back surface for the design of the digital photo frame 9700. For example, a memory storing data of an image taken with a digital camera is inserted in the recording medium insertion portion of the digital photo frame, whereby the image data can be transferred and then displayed on the display portion 9703.

The digital photo frame 9700 may be configured to transmit and receive data wirelessly. The structure may be employed in which desired image data is transferred wirelessly to be displayed.

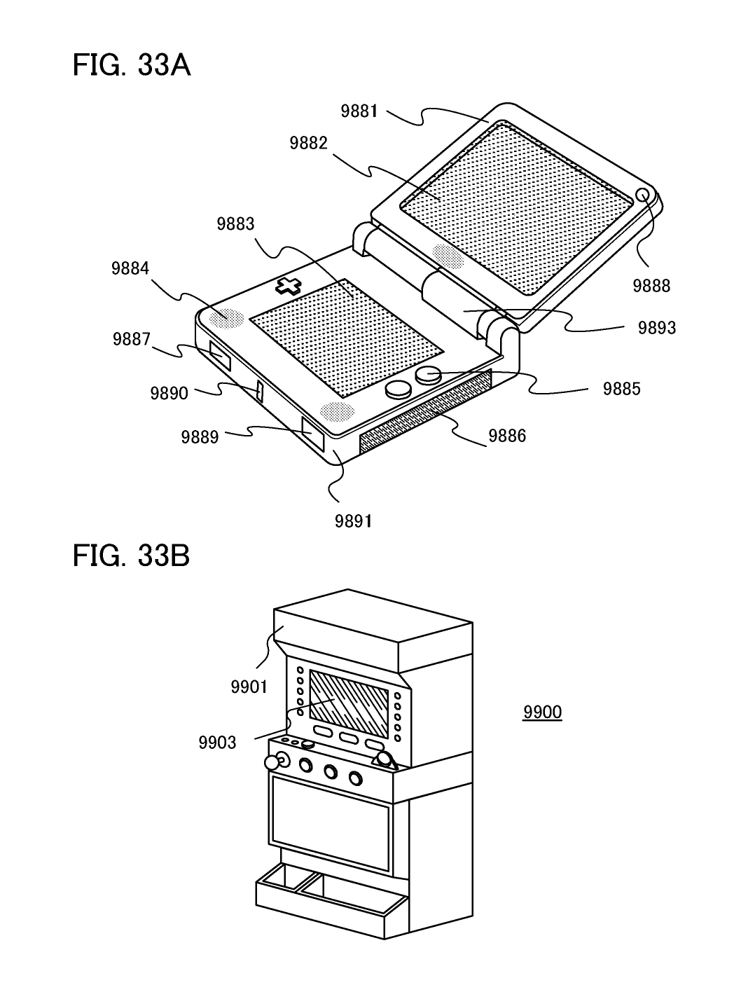

FIG. 33A illustrates a portable game machine including a housing 9881 and a housing 9891 which are jointed with a connector 9893 so as to be able to open and close. A display portion 9882 and a display portion 9883 are incorporated in the housing 9881 and the housing 9891, respectively. The portable game machine illustrated in FIG. 33A additionally includes a speaker portion 9884, a storage medium inserting portion 9886, an LED lamp 9890, an input means (operation keys 9885, a connection terminal 9887, a sensor 9888 (including a function of measuring force, displacement, position, speed, acceleration, angular speed, the number of rotations, distance, light, liquid, magnetism, temperature, chemical substance, sound, time, hardness, electric field, current, voltage, electric power, radiation, flow rate, humidity, tilt angle, vibration, smell, or infrared ray), a microphone 9889, and the like). It is needless to say that the structure of the portable game machine is not limited to the above and other structures provided with at least a semiconductor device may be employed. The portable game machine may include other accessory equipment, as appropriate. The portable game machine illustrated in FIG. 33A has a function of reading out a program or data stored in a storage medium to display it on the display portion and a function of sharing information with another portable game machine by wireless communication. The portable game machine illustrated in FIG. 33A can have various functions without limitation to the above.

FIG. 33B illustrates an example of a slot machine 9900 which is a large-sized game machine. In the slot machine 9900, a display portion 9903 is incorporated in a housing 9901. In addition, the slot machine 9900 includes an operation means such as a start lever or a stop switch, a coin slot, a speaker, and the like. It is needless to say that the structure of the slot machine 9900 is not limited to the above and other structures provided with at least a semiconductor device may be employed. The slot machine 9900 may include other accessory equipment, as appropriate.

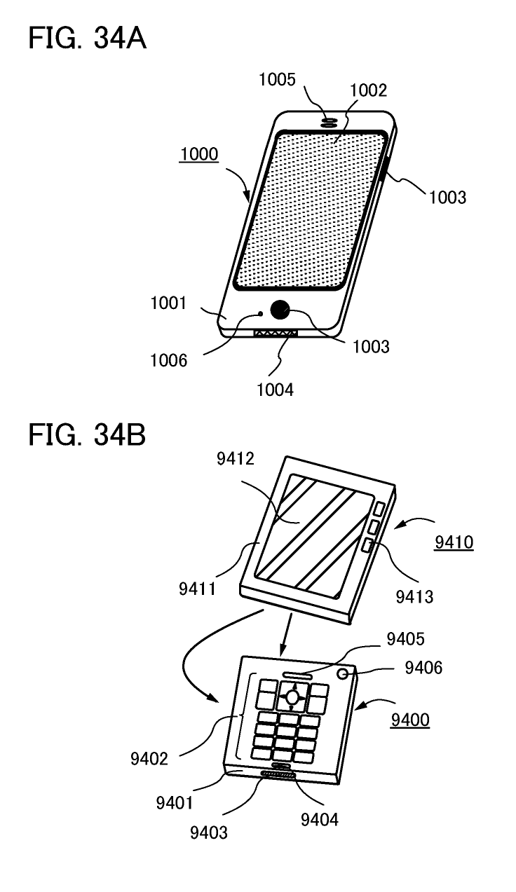

FIG. 34A illustrates an example of a mobile phone 1000. The mobile phone 1000 includes a display portion 1002 incorporated in a housing 1001, an operation button 1003, an external connection port 1004, a speaker 1005, a microphone 1006 and the like.

When the display portion 1002 of the mobile phone 1000 illustrated in FIG. 34A is touched with a finger or the like, data can be input into the mobile phone 1000. Furthermore, operations such as making calls and composing mails can be performed by touching the display portion 1002 with a finger or the like.

There are mainly three screen modes of the display portion 1002. The first mode is a display mode mainly for displaying images. The second mode is an input mode mainly for inputting data such as text. The third mode is a display-and-input mode in which two modes of the display mode and the input mode are combined.

For example, in a case of making a call or composing a mail, a text input mode mainly for inputting text is selected for the display portion 1002 so that text displayed on a screen can be input. In that case, it is preferable to display a keyboard or number buttons on almost all area of the screen of the display portion 1002.

When a detection device including a sensor for detecting inclination, such as a gyroscope or an acceleration sensor, is provided inside the mobile phone 1000, display in the screen of the display portion 1002 can be automatically switched by determining the installation direction of the mobile phone 1000 (whether the mobile phone 1000 is placed horizontally or vertically for a landscape mode or a portrait mode).

The screen modes are switched by touching the display portion 1002 or operating the operation button 1003 of the housing 1001. Alternatively, the screen modes may be switched depending on the kind of the image displayed on the display portion 1002. For example, when a signal of an image displayed on the display portion is a signal of moving image data, the screen mode is switched to the display mode. When the signal is a signal of text data, the screen mode is switched to the input mode.

Further, in the input mode, when input by touching the display portion 1002 is not performed for a certain period while a signal detected by the optical sensor in the display portion 1002 is detected, the screen mode may be controlled so as to be switched from the input mode to the display mode.

The display portion 1002 may function as an image sensor. For example, an image of a palm print, a fingerprint, or the like is taken when the display portion 1002 is touched with a palm or a finger, whereby personal identification can be performed. Further, by providing a backlight or a sensing light source which emits a near-infrared light in the display portion, an image of a finger vein, a palm vein, or the like can be taken.

FIG. 34B illustrates another example of a mobile phone. The mobile phone in FIG. 34B has a display device 9410 in a housing 9411, which includes a display portion 9412 and operation buttons 9413, and a communication device 9400 in a housing 9401, which includes operation buttons 9402, an external input terminal 9403, a microphone 9404, a speaker 9405, and a light-emitting portion 9406 that emits light when a phone call is received. The display device 9410 which has a display function can be detached from or attached to the communication device 9400 which has a phone function, in two directions represented by the allows. Therefore, the display device 9410 and the communication device 9400 can be attached to each other along either of respective short axes or long axes. In addition, when only the display function is needed, the display device 9410 can be detached from the communication device 9400 and used alone. Images or input information can be transmitted or received by wireless or wire communication between the communication device 9400 and the display device 9410, each of which has a rechargeable battery.

This application is based on Japanese Patent Application serial no. 2009-051779 filed with Japan Patent Office on Mar. 5, 2009, the entire contents of which are hereby incorporated by reference.

1. (canceled)

2. A display device comprising:
a pixel portion and a driver circuit provided over a substrate,
wherein the pixel portion comprises a first transistor and a storage capacitor portion,
wherein the driver circuit comprises a second transistor,
wherein the storage capacitor portion comprises a first metal oxide layer and a first conductive layer overlapping with the first metal oxide layer,
wherein a second conductive layer with an island-shape is provided between the first metal oxide layer and the first conductive layer,
wherein the first transistor comprises a second metal oxide layer provided in the same layer as the first metal oxide layer,
wherein a gate wiring of the first transistor is provided in the same layer as the second conductive layer,
wherein the second transistor comprises a third conductive layer provided in the same layer as the second conductive layer and the gate wiring,
wherein each of the first metal oxide layer, the second metal oxide layer, and the first conductive layer has a light-transmitting property,
wherein each of the second conductive layer, the third conductive layer, and the gate wiring has a light-shielding property,
wherein the first metal oxide layer comprises a region functioning as an electrode of the storage capacitor portion,
wherein the first conductive layer comprises a region functioning as a pixel electrode, and
wherein the third conductive layer comprises a region functioning as a gate electrode of the second transistor.

3. A display device comprising:
a pixel portion and a driver circuit provided over a substrate,
wherein the pixel portion comprises a first transistor and a storage capacitor portion,
wherein the driver circuit comprises a second transistor,
wherein the storage capacitor portion comprises a first metal oxide layer and a first conductive layer overlapping with the first metal oxide layer,
wherein a fourth conductive layer is provided between the first metal oxide layer and the first conductive layer,
wherein the first transistor comprises a second metal oxide layer provided in the same layer as the first metal oxide layer,
wherein a source wiring of the first transistor is provided in the same layer as the fourth conductive layer,
wherein the second transistor comprises a fifth conductive layer provided in the same layer as the fourth conductive layer and the source wiring,
wherein each of the first metal oxide layer, the second metal oxide layer, and the first conductive layer has a light-transmitting property,
wherein each of the fourth conductive layer, the fifth conductive layer, and the source wiring has light-shielding property,
wherein the first metal oxide layer comprises a region functioning as an electrode of the storage capacitor portion,
wherein the first conductive layer comprises a region functioning as a pixel electrode, and
wherein the fifth conductive layer comprises a region functioning as one of a source electrode and a drain electrode of the second transistor.

4. A display device comprising:
a pixel portion and a driver circuit provided over a substrate,
wherein the pixel portion comprises a first transistor and a storage capacitor portion,
wherein the driver circuit comprises a second transistor,
wherein the storage capacitor portion comprises a first metal oxide layer and a first conductive layer overlapping with the first metal oxide layer,
wherein a second conductive layer with an island-shape is provided between the first metal oxide layer and the first conductive layer,
wherein a fourth conductive layer is provided between the second conductive layer and the first conductive layer,
wherein the first transistor comprises a second metal oxide layer provided in the same layer as the first metal oxide layer,
wherein a gate wiring of the first transistor is provided in the same layer as the second conductive layer,
wherein a source wiring of the first transistor is provided in the same layer as the fourth conductive layer,
wherein the second transistor comprises a third conductive layer provided in the same layer as the second conductive layer and the gate wiring, and a fifth conductive layer provided in the same layer as the fourth conductive layer and the source wiring,
wherein each of the first metal oxide layer, the second metal oxide layer, and the first conductive layer has a light-transmitting property,
wherein each of the second conductive layer, the third conductive layer, the fourth conductive layer, the fifth conductive layer, the gate wiring, and the source wiring has light-shielding property,
wherein the first metal oxide layer comprises a region functioning as an electrode of the storage capacitor portion,
wherein the first conductive layer comprises a region functioning as a pixel electrode,
wherein the third conductive layer comprises a region functioning as a gate electrode of the second transistor, and
wherein the fifth conductive layer comprises a region functioning as one of a source electrode and a drain electrode of the second transistor.
